(19) United States
(12) Patent Application Publication
(10) Pub. No.: US 2019/0369175 A1
(43) Pub. Date: Dec. 5, 2019

(54) OPTICAL HYPERPOLARIZATION USING A SOLID CATALYST

(71) Applicant: NVision Imaging Technologies GmbH, Blaustein (DE)

(72) Inventors: Ilai SCHWARTZ, Ulm (DE); Christoph MUELLER, Ulm (DE)

(73) Assignee: NVision Imaging Technologies GmbH, Blaustein (DE)

(21) Appl. No.: 16/427,390

(22) Filed: May 31, 2019

Related U.S. Application Data
(60) Provisional application No. 62/679,269, filed on Jun. 1, 2018.

(51) Int. Cl. G01R 33/28; G01R 33/38; B01J 27/20; B01J 35/00; B01J 35/04

(52) U.S. Cl. CPC G01R 33/282; G01R 33/3804; B01J 35/04; B01J 35/0033; B01J 27/20

(57) ABSTRACT

Embodiments of the present disclosure include a hyperpolarizing system, comprising a hyperpolarization reaction chamber having a location therein for supporting a solid catalyst with a sample in contact therewith, a cooler configured to lower a temperature of the sample and the solid catalyst to a temperature in a range of about 70K and about 250K, and an optical light source configured to direct light energy toward the solid catalyst to thereby hyperpolarize electrons in the solid catalyst and facilitate transfer of hyperpolarization to nuclei of the sample.

### CROSS-REFERENCE TO RELATED APPLICATIONS

This application claims priority from U.S. Provisional Patent Application No. 62/679,269, filed Jun. 1, 2018, which is hereby incorporated by reference in its entirety in the present application.

### FIELD OF THE INVENTION

The embodiments of the present disclosure relate in general to systems, devices, and methods for optically hyperpolarizing a polarization structure. More specifically, the embodiments of the present disclosure relate to systems, devices, and methods for optically hyperpolarizing a polarization structure to thereby hyperpolarize a target material or sample outside of the polarization structure.

### BACKGROUND

In a diamond, electron spins in a particular kind of color center, for example a nitrogen vacancy (NV) center, can be polarized optically independent of ambient temperature. T Staudacher et al. in “Nuclear Magnetic Resonance Spectroscopy on a (5 nanometre)³ Sample Volume”, Science (2013) demonstrate a scheme for sensing nuclear spin ensembles 5 nm from the diamond surface using shallow NV centers that are close to the surface of the diamond. The authors note that a scheme for polarizing the external nuclear spins can be developed, and might operate probably on a similar timescale to the detection. However, the authors have not provided any details as to how such a scheme could be achieved. Moreover, it appears that no clear scheme was thought of because it appears that producing such a high polarization rate with the proposed setup is not feasible, especially for small molecules, where the effect of molecular movement needs to be taken into account. In addition, the authors have only considered molecules in a (5 nm)³ radius.

In “Dynamic Nuclear Spin Polarization of Liquids and Gases in Contact with Nanostructured Diamond”, Nano Letters (2014), D Abrams et al. show simulative results of polarization of nuclear spins in a liquid in contact with a diamond surface filled with shallow nitrogen vacancy centers. The scheme uses direct polarization of nuclear spins adsorbed on the surface of the diamond via the nitrogen vacancy (NV) centers and report a 0.2% to 2% polarization of the external nuclear spins in a very small volume in a few seconds; the volume is a liquid layer of 0.5 μm thickness and 50 μm in length and width. Yet, the polarization rate achieved is too low for polarizing substantial volumes with reasonable optical intensity (even in optimized configurations)−over 10,000 seconds for polarizing a microliter of fluid. Additionally, the presented scheme does not involve a coherent transfer of the polarization from the NV centers to the nuclear spins—the main reason for the slow polarization rate achieved.

The above analysis is also discussed in WO 2014/165845 A1. Three classes of motifs for the transfer of polarization from a diamond to target nuclei external to the diamond are contemplated. Transfers governed by direct interactions between NV centers and external nuclei, transfers that utilize ¹³C nuclei hyperpolarization within optically pumped diamond, and transfers mediated by other paramagnetic centers near the diamond's surfaces.

In “Dressed-State Polarization Transfer between Bright & Dark Spins in Diamond”, Physical Review Letters (2013), C Belthangady et al. report the polarization of electron spins in a nitrogen vacancy center of a diamond by optical pumping. The polarization of the nitrogen center electron spins can then be transferred to substitutional nitrogen electron spins by applying electromagnetic fields analogous to the Hartmann-Hahn matching condition. In this publication, only electron spins inside the diamond are polarized.

In “Sensitive magnetic control of ensemble nuclear spin hyperpolarization in diamond”, Nature Communication (2013), H-J Wang et al. show polarization of nuclear spins in contact interaction with a nitrogen vacancy color center in a diamond using the ground state level anti-crossing of the center. The method shown was only relevant for nuclear spins inside the diamond, and not to external molecules.

In magnetic resonance applications, it is desirable to reach a higher degree of polarization of the nuclear spins in the external molecules, in a higher volume and more quickly, than has hitherto been accomplished.

Therefore, there is a need for an improved, system, device, and method for hyperpolarizing nuclear spins by means of transferring the polarization of electron spins to the nuclear spins. In addition, there is a need for an improved, system, device, and method for hyperpolarizing nuclear spins in one or more particle(s) moving relative to a polarization structure, in which polarization of electron spins in the polarization structure is resonantly transferred to the nuclear spins in the particle(s). Moreover, in addition, there is a need for an improved, system, device, and method for hyperpolarizing nuclear spins in a target material outside the polarization structure, such as a solid target material or a liquid target material, wherein the polarization of electron spins in the polarization structure is transferred to the nuclear spins.

### SUMMARY

The embodiments of the present disclosure include systems, devices, and methods of optically hyperpolarizing a solid catalyst. Advantageously, the exemplary embodiments provide a system for optically hyperpolarizing a solid catalyst and transferring hyperpolarization of electrons in the solid catalyst to nuclei of a sample. Various embodiments of the disclosure may include one or more of the following aspects.

In accordance with an embodiment of the present disclosure, a hyperpolarizing system is provided. The hyperpolarizing system may comprise a hyperpolarization reaction chamber having a location therein for supporting a solid catalyst with a sample in contact therewith, a cooler configured to lower a temperature of the sample and the solid catalyst to a temperature in a range of about 70K and about 250K, and an optical light source configured to direct light energy toward the solid catalyst to thereby hyperpolarize electrons in the solid catalyst and facilitate transfer of hyperpolarization to nuclei of the sample. In some embodiments, the sample may be a flowable sample. In other embodiments, the sample may include particles. In some embodiments, the sample may be a flowable sample and may become a solid sample by lowering the temperature of the sample. In some embodiments, the sample may be frozen or in a glassy state in the temperature configured by the cooler.

In some embodiments, the cooler may be configured to lower the temperature of the sample and the solid catalyst to a temperature in a range of about 70K and about 220K, a temperature in a range of about 70K and about 200K, or a temperature in a range of about 70K and about 120K. In a preferred embodiment, the cooling of the sample leads to it being frozen or in a glass phase while in contact with the solid catalyst, thereby facilitating the polarization transfer from the solid catalyst to the sample. In some embodiments, the optical light source may be configured to emit at least one of non-collimated light or green light. In other embodiments, the optical light source may include at least one of a laser configured to direct light at about 538 nm or a light emitting diode (LED).

In some embodiments, the hyperpolarizing system may comprise at least one processor configured to control at least one of the optical light source, the cooler, or a flow of the sample in order to facilitate the transfer of hyperpolarization to the nuclei of the flowable sample. In other embodiments, the hyperpolarizing system may comprise at least one microwave source.

In some embodiments, the solid catalyst may include a plurality of nanostructured diamond substrates with nanoscopic three-dimensional structures across a surface thereof, each substrate hosting defects with optically polarizable electron spins. The plurality of nanostructured substrates may be arranged in a stack, and the stack may have a plurality of channels therethrough. The channels may be configured to permit a polarizable fluidic agent to flow through the nanoscopic three-dimensional structures of the plurality of nanostructured diamond substrates in the stack. In some embodiments, each substrate may be associated with its own holder. In some embodiments, the nanoscopic three-dimensional structures may each have a size range of about 50 nm to about 5000 nm. In other embodiments, the channels may include pathways through at least one membrane surface, pathways between adjacent membranes, or both. In yet another embodiment, the plurality of nanostructured substrates may include at least 5 stacked nanostructured diamond substrates, at least 50 stacked nanostructured diamond substrates, or at least 100 stacked nanostructured diamond substrates. In some embodiments, the plurality of nanostructured diamond substrates may be coated with endogenous molecules having polarizable nuclear spin. In other embodiments, each substrate may have a thickness between about 1 μm and about 100 μm. In other embodiments, each substrate may include at least one honeycomb-shaped cut.

In accordance with another embodiment of the present disclosure, a hyperpolarizing catalyst is provided. The hyperpolarizing catalyst may comprise a plurality of nanostructured diamond substrates with nanoscopic three-dimensional structures across a surface thereof, each substrate hosting defects with optically polarizable electron spins. The plurality of nanostructured substrates may be arranged in a stack, and the stack may have a plurality of channels therethrough. The channels may be configured to permit a polarizable fluidic agent to flow through the nanoscopic three-dimensional structures of the plurality of nanostructured diamond substrates in the stack.

Additional objects and advantages of the embodiments will be set forth in part in the description that follows, and in part will be obvious from the description or may be learned by practice of the embodiments. The objects and advantages of the embodiments will be realized and attained by means of the elements and combinations particularly pointed out in the appended claims.

It is to be understood that both the foregoing general description and the following detailed description are exemplary and explanatory only and are not restrictive of the claims.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIG. 1 illustrates an exemplary experimental setup with a microfluidic polarization structure, in accordance with the embodiments of the present disclosure;

FIG. 2 illustrates an exemplary nitrogen vacancy center in a diamond lattice with the relevant energy levels for initialization and polarization, in accordance with the embodiments of the present disclosure;

FIG. 3 illustrates an exemplary schematic diagram of an interface between the polarization structure and the particles with the nuclear spins, in accordance with the embodiments of the present disclosure;

FIG. 4 illustrates an image of an exemplary microfluidic channel etched in a diamond containing NV centers, in accordance with the embodiments of the present disclosure;

FIG. 5 illustrates an exemplary microfluidic channel enclosed with a PMMA covering, in accordance with the embodiments of the present disclosure;

FIG. 6A illustrates an exemplary configuration of a polarization structure, in accordance with the embodiments of the present disclosure;

FIG. 6B illustrates another exemplary configuration of the polarization structure of FIG. 6A, in accordance with the embodiments of the present disclosure;

FIG. 6C illustrates another exemplary configuration of the polarization structure of FIGS. 6A and 6B, in accordance with the embodiments of the present disclosure

FIG. 7 illustrates a graph depicting an exemplary nuclear polarization achieved in a bulk diamond, in accordance with the embodiments of the present disclosure;

FIG. 8 illustrates a graph depicting an exemplary polarization transfer per unit volume achieved per time, in accordance with the embodiments of the present disclosure;

FIG. 9 illustrates an exemplary sequence of polarization, in accordance with the embodiments of the present disclosure;

FIG. 10 illustrates an exemplary experimental setup with a polarization structure composed of nanoparticles in a suspension, in accordance with the embodiments of the present disclosure;

FIG. 11A illustrates an exemplary concept of overcoming random orientation of color centers, in accordance with the embodiments of the present disclosure;

FIG. 11B illustrates another exemplary concept of overcoming random orientation of color centers, in accordance with the embodiments of the present disclosure;

FIG. 11C illustrates another exemplary concept of overcoming random orientation of color centers, in accordance with the embodiments of the present disclosure;

FIG. 12 illustrates graphs depicting exemplary polarization transfer for different orientations in nanodiamonds, in accordance with the embodiments of the present disclosure;

FIG. 13 illustrates exemplary graphs depicting the dependence on the angle to the external magnetic field in the high magnetic field regime of the zero field splitting and second order corrections to the energy levels, in accordance with the embodiments of the present disclosure;

FIG. 14 illustrates a three-dimensional plot depicting the efficiency of the polarization transfer with a detuned driving and the integrated solid effects, with dependence on the total coupling strength and the frequency sweep velocity, in accordance with the embodiments of the present disclosure;

FIG. 15A illustrates a conceptual representation of an exemplary experimental setup, in accordance with the embodiments of the present disclosure;

FIG. 15B illustrates another conceptual representation of the exemplary experimental setup of FIG. 15A, in accordance with the embodiments of the present disclosure;

FIG. 16 illustrates an exemplary optical microscope picture of a fabricated structure on glass used in magnetic resonance experiments and an exemplary holder with a strip line structure, in accordance with the embodiments of the present disclosure;

FIG. 17 illustrates an exemplary confocal map of a single NV center adjusted to a microwave strip line, in accordance with the embodiments of the present disclosure;

FIG. 18 illustrates an exemplary diagram of a magnet stage with a cylindrical magnet attached, in accordance with the embodiments of the present disclosure;

FIG. 19 illustrates an exemplary graphical representation of the polarization transfer protocol, using the solid state effect, in accordance with the embodiments of the present disclosure;

FIG. 20A illustrates an exemplary graphical representation of a difference in nuclear polarization build-up depending on the ESR line width compared to the Larmor frequency, in accordance with the embodiments of the present disclosure;

FIG. 20B illustrates another exemplary graphical representation of a difference in nuclear polarization build-up depending on the ESR line width compared to the Larmor frequency, in accordance with the embodiments of the present disclosure;

FIG. 21 illustrates an exemplary process of microwave-driven polarization transfer based on the cross effect, in accordance with the embodiments of the present disclosure;

FIG. 22 illustrates an exemplary pulse sequence used to polarize nuclear spins and the low frequency components in the spin-locking signal on the x-axis for various microwave driving fields with the corresponding Rabi frequency on the y-axis, in accordance with the embodiments of the present disclosure;

FIG. 23 illustrates a schematic diagram of an exemplary method for changing the conditions for optimal polarization and polarization transfer, in accordance with the embodiments of the present disclosure;

FIG. 24 illustrates an exemplary nanostructured substrate and an exemplary ensemble of micro- or nano-particles, in accordance with the embodiments of the present disclosure;

FIG. 25 illustrates an exemplary schematic diagram for producing a semiconductor structure, in accordance with the embodiments of the present disclosure;

FIG. 26 illustrates another exemplary schematic diagram for producing a semiconductor structure, in accordance with the embodiments of the present disclosure;

FIG. 27 illustrates another exemplary schematic diagram for producing a semiconductor structure, in accordance with the embodiments of the present disclosure;

FIG. 28 illustrates an exemplary semiconductor structure, in accordance with the embodiments of the present disclosure;

FIG. 29 illustrates another exemplary schematic diagram for producing a semiconductor structure, in accordance with the embodiments of the present disclosure;

FIG. 30 illustrates an exemplary graph of a relaxation time of urea, in accordance with the embodiments of the present disclosure;

FIG. 31 illustrates an exemplary scanning electron microscope (SEM) image of an area between micropillars filled with urea, in accordance with the embodiments of the present disclosure;

FIG. 32 illustrates an exemplary anatomical MRI image overlaid with metabolic rate of hyperpolarized pyruvate, in accordance with the embodiments of the present disclosure;

FIG. 33 illustrates an exemplary NMR spectroscopy of hyperpolarized pyruvate, in accordance with the embodiments of the present disclosure;

FIG. 34 illustrates an exemplary graph of a relationship between a conversation rate between pyruvate and lactate and signal noise level, in accordance with the embodiments of the present disclosure;

FIG. 35 illustrates a schematic diagram of an exemplary hyperpolarization system in accordance with the embodiments of the present disclosure;

FIG. 36 illustrates an exemplary schematic diagram of a system for providing metabolic information, in accordance with the embodiments of the present disclosure;

FIG. 37 illustrates an exemplary non-uniform distribution used as a prior for conversion rate, in accordance with the embodiments of the present disclosure; and

FIG. 38 illustrates an exemplary pyruvate and lactate signal, as well as an exemplary heatmap of a conversion rate from a Bayesian model for a 2D slice of an orthotropic tumor model in a mouse, in accordance with the embodiments of the present disclosure.

### DETAILED DESCRIPTION OF EMBODIMENTS

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions, or modifications may be made to the components and steps illustrated in the drawings, and the illustrative methods described herein may be modified by substituting, reordering, removing, or adding steps to the disclosed methods. Accordingly, the following detailed description is not limited to the disclosed embodiments and examples. Instead, the proper scope of the invention is defined by the appended claims.

Embodiments of the present disclosure relate to systems, devices, and methods for optically hyperpolarizing a target material (e.g., a sample). While the present disclosure provides examples of hyperpolarizing a target material by hyperpolarizing a solid catalyst, such as a diamond material, it should be noted that aspects of the disclosure in their broadest sense, are not limited to a diamond material. Rather, it is contemplated that the foregoing principles may be applied to other types of solid catalysts as well.

Molecular motion can play an instrumental role in the polarization of particles, for example if the particles are dissolved or suspended in a solvent or a suspension agent. Thus, polarization of particles exhibiting molecular motion by electron spins is typically performed with non-resonant transfer, for example, the Overhauser effect, with a strong limitation on the transfer efficiency given by the molecular motion correlation time.

The embodiments of the present disclosure provide a method that may reduce a negative effect of diffusion on the polarization of the particles' nuclear spins. The correlation time of the interaction between the electron spins and the nuclear spins may be defined as the mean time in which the correlation of the interaction decays to 1/e of its initial value (i.e. <g(t)g(t+τ_{c})>=<g²+1/e, with g denoting the interaction).

The embodiments of the present disclosure may exploit that if the motion of the particles in proximity to the polarization structure occurs on a timescale slower than the nuclear spin Larmor frequency (i.e. ωτ_{c}>1, with w indicating the nuclear Larmor frequency and to the correlation time of the interaction with the nearest polarization structure electron spin due to the molecular motion), resonant transfer becomes achievable. Moreover, the polarization transfer rate increases with τ_{c}.

In the context of the present disclosure, “in proximity to the polarization structure” may be defined as a distance shorter than 100 nm from a surface of the polarization structure. In some embodiments, “in proximity to the polarization structure” may be defined as a distance shorter than 10 nm from the surface of the polarization structure.

The term polarization may be defined as the number of polarizable nuclear spins polarized in the preferred direction minus the number in the opposite direction, divided by the total number of polarizable nuclear spins. “Hyperpolarization” may refer to polarization well above the thermal equilibrium. “Polarization structure” may refer to a material in which electron spins can be hyperpolarized, which polarization can be transferred to the particles' nuclear spins. For example, polarization structure may refer to a catalyst material, a solid catalyst, a diamond material, or a semiconductor structure. The polarization structure may be a nanoscopic three-dimensional structure or a microscopic three-dimensional structure. In the context of the present disclosure, electron spins in the polarization structure may refer to electron spins which can be hyperpolarized, except when used in the context of mediating electron spins. In other words, in the nomenclature applied here electron spins in the polarization structure which are not hyperpolarized may not constitute “polarizing electron spins”. This is with the exception of mediating electron spins, which are discussed further below. As explained in more detail below, the “transfer” may occur directly from the polarization structure to the particles or indirectly with the help of a mediator. In the context of the present disclosure, polarizable nuclear spins may be defined as any species of nuclei with nonzero spin, such as ¹H, ¹³C, ¹⁵N, ¹⁹F, ²⁹Si, ³¹P, etc.

In addition, a “particle” in the present disclosure may refer to a structure, the nucleus or one or more nuclei of which can be polarized by means of transferring a polarization from the polarization structure to the particle. The particle may either have a different composition or a different inner structure, e. g. a different crystalline structure, than the polarization material, or it may have the same composition and structure but may be separate from the polarization material. The particle can, for example, be an atom or a molecule. In other embodiments, the particle can also be a larger structure, for example a crystal or an amorphous structure.

In the context of the present disclosure, “resonant transfer” may refer to a transfer of spin polarization that is mediated by a distance dependent interaction between electron spin and nuclear spins where, in a suitable frame of reference, the difference in transition energies between the electronic and nuclear polarization states is smaller than the total interaction of the electron spin with all target nuclear spins. Thus, a resonant transfer may achieve a transfer of spin polarization even without the molecular motion of the particles.

Advantageously, the polarization process of the present disclosure may not need to rely on specific chemical processes. As such, the polarization process of the present disclosure may be suitable for the hyperpolarization of a very wide range of particles, including, for example, proteins, nucleic acids and other molecules that play an important role in the human or animal body.

In accordance with another aspect of the present disclosure, the transfer of spin polarization from the electron spins in the polarization structure to the nuclear spins in the particles may be accelerated. In particular, it can be exploited that, at a given distance, the coupling between the electron spins may be stronger, for example, by a factor in the range of more than 100 or more than 1000 than between an electron spin and a nuclear spin. Moreover, it can be exploited that the electron, due to its location on the surface or distance from the polarization structure, may be closer to the nuclear spins, to which the polarization is to be transferred, thereby facilitating polarization transfer. The synergetic cooperation of these effects can lead to a substantial increase of the speed of polarization of the nuclear spins in the particles. In the context of the present disclosure, “outside” may mean that the mediator electrons are electrons on the surface of the polarization structure or electrons external to the polarization structure.

According to an embodiment of the present disclosure, one or more particle(s) may move relative to a polarization structure and relative to each other. The polarization of electron spins in the polarization structure may be transferred to the nuclear spins in the particle(s). The particle(s) may perform a diffusional motion. For one or more of the moving particles, the characteristic correlation time of the interaction with the nearest polarization structure's electron spin, due to the molecular motion (τ_{c}) may be smaller than the inverse Larmor frequency of the nuclear spins. Molecular motion to can be increased either by a smaller diffusion coefficient in proximity to the polarization structure or by using a deeper electron spin in the polarization structure than what the particle needs to cover a larger distance in order to significantly change the interaction strength. As a large correlation time improves the efficiency of the resonant polarization transfer, the product of the correlation time and the total coupling strength of the nuclear spins in the particles to the electron spin may be larger than 0.01, larger than 0.1, or larger than 1.

For at least 10% of the particles within 10 nm, or within 100 nm, of the polarization structure, the interaction correlation time may be smaller than the nuclear Larmor frequency. In some embodiments, for at least 20%, 50%, or 90% of the particles within 10 nm or 100 nm of the polarization structure, the interaction correlation time may be smaller than the nuclear Larmor frequency.

The diffusion coefficient D of the particles in proximity to the polarization structure may be lower than 10⁻¹⁰ m²/s, lower than 10⁻¹² m²/s, or lower than 10⁻¹³ m²/s. A low diffusion coefficient D can contribute to a small characteristic diffusion length. The diffusion coefficient D of the moving particle(s) may be greater than 10⁻²⁰ m²/s, greater than 10⁻¹⁷ m²/s, or greater than 10⁻¹⁴ m²/s. A large diffusion coefficient D can expedite the polarization of a larger volume containing the particles.

In an embodiment of the present disclosure, the diffusion coefficient D of the moving particle(s) which are not in proximity to the polarization structure may be greater than 10⁻¹² m²/s. Advantageously, by means of diffusion of particles to and from the vicinity of the polarization structure, particles in a large volume containing these particles can be polarized. In particular, diffusion can cause hyperpolarized particles to move away from the vicinity of the polarization structure and polarize a larger volume containing the particles, while at the same time allowing new unpolarized particles to take the place of already hyperpolarized particles in the vicinity of the polarization structure. Thus, the efficiency of the polarization transfer may be maintained. More specifically, by choosing a diffusion coefficient D of the moving particles of greater than 10⁻¹⁴ m²/s, a cubical volume of over 1 μm³ may be polarized within only a few minutes by each electron spin in the polarization structure. Thus, a significant volume of polarized particles per second may be achievable via all the electron spin in the polarization structure.

Preferably, the particles are part of a liquid. More preferably, the particles are part of a solution, either as a material dissolved in a liquid solvent or as part of the solvent itself, or the particles are part of a liquid suspension, either as part of a material suspended in a suspensory agent or as part of the suspensory agent itself. If the particles are part of a solution or suspension, the particles' diffusion can for example be lowered by changing the concentration of the particles in a solution or a suspension, by changing the composition of the solvent or the suspension agent, by lowering the temperature of the solution or suspension or by using larger particles to be polarized. Changes to the composition of the solution or suspension can result in a dramatically lower molecular diffusion coefficient. There are many biocompatible molecules which when added in high concentration to a solution or suspension, greatly reduce the molecular motion and diffusion coefficients. For examples, in He, Xiaoming, Alex Fowler, and Mehmet Toner. “Water activity and mobility in solutions of glycerol and small molecular weight sugars: Implication for cryo- and lyopreservation.” Journal of Applied Physics 100.7 (2006): 074702, He et al show the effect of mixing water with glycerol, fructose, sucrose and trehalose, and the dramatic decrease in the water diffusion coefficient with the increase in the concentration of the added molecules. The disclosure in the publication of He at al is incorporated into the present disclosure by way of reference.

Yet, the present disclosure also encompasses embodiments in which the particles are simply stacked-up in a gas or a vacuum. Moreover, in some embodiments of the present disclosure, there is only a single particle which in some embodiments is moving and in other embodiments is stationary relatively to a polarization structure. The particle or particles preferably are solid, in particular in the case of the particles being suspended or stacked up or in cases where there is only a single particle. It is an achievable advantage of a solid that the motion (typically the molecular motion) inside the solid is sufficiently limited as to not adversely affect the polarization transfer.

In accordance with an embodiment of the present disclosure, the polarization structure may comprise a diamond. A diamond may be a synthetic diamond or a naturally occurring diamond. Electron spins in the diamond that may be particularly suitable for polarization and polarization transfer may be color centers, such as nitrogen vacancy (NV) centers (see for example Jelezko, Fedor, et al “Observation of coherent oscillations in a single electron spin.” Physical review letters 92.7 (2004): 076401; the disclosure of which is incorporated into the present disclosure by reference.) Synthetic diamonds may be produced, for example, by chemical vapor deposition (CVD).

In another embodiment, the polarization structure may comprise silicon carbide, such as 4H—SiC or 6H—SiC. Electron spins in silicon carbide that may be particularly suitable for polarization and polarization transfer may be di-vacancies, which are common defects in semiconductors comprising neighboring isolated vacancies. Other lattice defects in silicon carbide may be suitable as well, for example, silicon vacancies (SiV), carbon vacancies (VC) (see for example Kraus, H., et al (2014) Room-temperature quantum microwave emitters based on spin defects in silicon carbide, Nat Phys 10, 157-162; the disclosure of which is incorporated into the present disclosure by way of reference.) In some embodiments, the electron spins to be polarized in the silicon carbide may be those of silicon oxide vacancy centers.

In another embodiment, the polarization structure may comprise zinc oxide (ZnO). Electron spins in zinc oxide that may be particularly suitable for polarization and polarization transfer may be oxygen vacancies (see for example Rodnyi, P A, and Khodyuk, I. V. (2011) Optical and luminescence properties of zinc oxide (Review), Opt Spectrosc+ 111, 776-785; the disclosure of which is incorporated into the present disclosure by way of reference).

Other potential material with suitable color centers may include crystalline quartz (see for example Hayes, W et al (1984) ODMR of Recombination Centers in Crystalline Quartz, J Phys C Solid State 17, 2943-2951; the disclosure of which is incorporated into the present disclosure by way of reference) and silicon oxide.

The electron spins of the polarization structure may be located within less than about 30 nm of at least one surface of the polarization structure, less than about 10 nm of at least one surface of the polarization structure, or less than about 5 nm of at least one surface of the polarization structure. The polarization structure can be of any shape that enables the particles or the mediators to come into proximity of the polarization structure's electron spins, the polarization of which is to be transferred to the particles. Moreover, the polarization structure may allow laser, radio frequency and/or microwave irradiation of the electron spins in order to polarize the electron spins. For example, walls of the polarization structure can act as interfaces at which polarization transfer may occur. The polarization structure may be coated with a different material, for example, in order to prevent the polarization structure from reacting chemically with the particles or a solvent or suspension agent in which the particles are suspended or dissolved.

In some embodiments, the polarization structure may be combined with one or more microfluidic structures. For example, the polarization structure may comprise microfluidic channel through which the particles, dissolved or suspended in a solution or a suspension of the particles, can flow. The polarization structure may contain one or more holes through which the particles, a solution or a suspension of the particles, can flow. Other possible geometries of the polarization structure may comprise nano-pillars, thin sheets, nanocrystals arrayed in a packed-bed-type geometry, or nanocrystals suspended in a solution or suspension in which the particles may be dissolved or suspended.

In some embodiments, the polarization structure may be arranged in a configuration that enables the solution to flow past the polarization structure at a constant velocity. As there may exist a trade-off between the polarization achieved and the rate at which the particles are polarized, the velocity may be optimized to fit the requirements of the specific geometry and application.

In some embodiments, the “polarization surface area” may be defined as the surface area of the polarization structure in which polarization is transferred to nearby particles. In this area, the electron spins in the polarization structure may be hyperpolarized, and need to be close to the surface. The “polarization rate per color center” may be defined as the number of nuclear spins polarized on average by each color center involved in the polarization per unit time. The “solution polarization rate” may be defined as the number of hyperpolarized particles per unit time, and may depend on the polarization rate per color center, on the polarization surface area, and on the density of color centers per surface area.

In some embodiments, the polarization surface area may be enlarged to increase the ratio of polarized particles to unpolarized particles. This may be achieved by choosing structure configurations with a large surface to volume ratio. In some embodiments, the optical polarization area may be increased by creating optical cavities which may enable a larger number of the electron spins to be hyperpolarized, thus potentially increasing the polarization surface area.

In some embodiments, the polarization rate per color center may be at least about 10 Hz, at least about 1 KHz, at least about 10 KHz, or at least about 100 KHz. In some embodiments, the color center concentration in the polarization surface area may be at least about 10¹² per m², at least about 10¹⁴ per m², or at least about 10¹⁶ per m². The solution polarization rate may be at least about 10⁴ particles per second, about 10⁷ particles per second, about 10¹¹ particles per second, or about 10¹⁴ particles per second.

In some embodiments, the electron spins in the polarization structure may be polarized above thermal equilibrium. The electron spins to be polarized in the polarization structure may be color centers. A “color center” may refer to a point defect in a crystal lattice, in which a vacancy may be filled by one or more electrons. The electron spins at a suitable color center can be polarized by optical pumping. Optically polarized color center electron spins can be transferred to proximal nuclear spins to create nuclear polarization. A color center may be a nitrogen vacancy (NV) center in a diamond. An NV center may be well-suited for the optical pumping of its electron spins. In other embodiments, atom substitutes other than nitrogen may also be possible for forming a color center, for example silicon (Si). In silicon carbide, the electron spins to be polarized can for example be those of silicon oxide vacancy centers, silicon vacancy (SiV) centers, carbon vacancy (VC) centers, or di-vacancy centers. In zinc oxide, the electron spins to be polarized may be oxygen vacancies.

The electron spin polarization can be optically induced not only in the ground state. For example, in oxygen vacancy defects in diamond, the spin polarization may be induced in an excited triplet state (see for example Hiromitsu, I, J Westra, and M Glasbeek. “Cross-relaxation effects in the 2.818-eV zero-phonon emission in brown diamond.” Physical Review B 46.9 (1992): 5303). The subject matter of which is incorporated into the present disclosure by reference. In some embodiments, electron spins in the polarization structure may be polarized by means of optical pumping. Electron spins in the polarization structure can be initialized optically to a certain spin state. This is for example demonstrated by optically detected magnetic resonance (ODMR). After the initialization, the color center spin states may be polarized to a much higher degree than the thermodynamic polarization. For example, NV centers may exhibit polarization up to 95% after optical polarization. In the context of the present disclosure, “optical pumping” may be defined as the irreversible transfer of the quantum state of the electron spin to a specific state thanks to the combination of laser irradiation and spontaneous emission of the absorbed laser light. The optical pumping may be achieved by irradiating the electron spins inside the polarization structure with monochromatic light. Light sources for optical pumping may include, but are not limited to, lasers, such as a 538 nm laser, one or more light emitting diodes (LEDs), or other light sources with a suitable wavelength (e.g. green light for NV centers in diamond, infrared and red for silicon vacancy in silicon carbide). In some embodiments, the light source may be configured to generate non-collimated light. In other embodiments, the light source may be configured to emit green light. In some embodiments, using LEDs or an array of LEDs as the light source for hyperpolarization may reduce the overall cost since LEDs are less costly than laser optics, while providing more optical power at the same cost. In addition, for NV centers in diamonds, LEDs configured to emit green light may be used to optically polarize the NV centers. As the optical excitation band of the NV is broad, LED sources may be used even if their optical wavelength spectrum is not very narrow. The LED source may be configured to direct at least about 1 Watt, at least about 2 Watt, or at least about 10 Watt of light energy. In some embodiments, a processor may control one or more LEDs such that the LEDs direct pulses of light energy toward the solid catalyst or continuous light energy toward the solid catalyst. In some embodiments, once an electron spin in the polarization structure is polarized by means of optical pumping, the polarization may be transferred either to one or more nuclear spin or to one or more mediator electron spins.

In order to facilitate the transfer of polarization from the electron spins of the polarization structure to the nuclei (directly or indirectly via mediators), an external microwave field or radio frequency (RF) field may be applied. The external microwave field or radio frequency (RF) field may be continuous or pulsed. The application of the microwave field may serve to tune the coupling between the nuclear spins and the electron spins of the polarization structure or the mediator electrons. The microwave field may also narrow the line width of the electron and thus make the transfer of the polarization of the electron spins to the nuclear spins more efficient. By applying the microwave field in this manner, it may be achievable to completely polarize the nuclei in a particle. In some embodiments, the polarization transfer from the electron spins to the nuclear spins can be accelerated. Many dynamic nuclear polarization protocols as discussed below may involve the application of an external microwave field or a radio frequency (RF) field.

In some embodiments, the magnetic flux density of the external magnetic field may be smaller than about 3 T. The embodiments of the present disclosure may allow for the use of external magnetic fields with a low magnetic flux density, such as below about 2 T, below about 1 T, or below about 0.5 T. Advantageously, these magnetic flux densities can be achieved by a permanent magnet or an electromagnet, which does not rely on liquid cooling. Accordingly, the hyperpolarized particles may be produced inexpensively, on a large scale and in a relatively simple setup. Such simple setups can be incorporated into a hospital environment more easily, which may lead to a reduction in implementation costs.

The transfer may involve a resonant transfer of the polarization. According to some embodiments, the polarization may be transferred by a standard dynamic nuclear polarization (DNP) protocol for using dipolar interactions to transfer electron polarization to nuclear spins. In the present disclosure, “DNP protocols” may be defined as protocols for transferring the polarization from an electron spin to the nuclear spins by microwave or RF irradiation of the sample. Advantageously, by means of a DNP transfer of the polarization from the electron spins to the surrounding, the hyperpolarization nuclear spins can be accelerated.

By way of example, suitable DNP protocols may include single-electron/single-nuclei methods, such as the solid effect, and pulsed DNP methods, such as the NOVEL sequence, the integrated solid effect, or dressed-state solid effect. Suitable DNP protocols may further include multiple-electron, single nuclei methods, such as the cross effect, thermal mixing, using mediator electron spins. A review of many current DNP protocols can be found in Maly, Thorsten, et al “Dynamic nuclear polarization at high magnetic fields.” J Chem Phys 2008; 128(5): 052211 (see section II “Polarizing mechanisms in DNP experiments”). The disclosure of which is incorporated into the present disclosure by way of reference. Most DNP protocols involve either interactions between electron spins or are based on two underlying physical mechanisms: fulfilling the Hartmann-Hahn condition and excitation of selective transitions (i.e. irradiation at a frequency matching the energy gap between two quantum states). However, the DNP protocols differ in the configurations for achieving these conditions and by the usage of microwave pulses or continuous microwave radiation.

According to the embodiments of the present disclosure, the DNP protocols can be used for fulfilling the Hartmann-Hahn condition between the color center spin of the polarization structure or the mediator electron and the nuclear spins or for excitation of selective transitions caused by the dipolar interaction of nuclear spin states with the electron spins of the polarization structure or the mediator electron. The general concept of Hartmann-Hahn double resonance as described in Hartmann, S R and Hahn, E L, “Nuclear Double Resonance in the Rotating Frame”, Physical Review, 1962, vol. 128, Issue 5, pp. 2042-2053, the subject matter of which is incorporated into the present disclosure by way of reference. According to some DNP protocols, the Hartmann-Hahn condition may be achieved. This condition may require that the Rabi frequency of the electron spin be equal to the Larmor frequency of the nuclear spin in some reference frame (both the Rabi frequency and Larmor frequency can be between dressed or bare eigenstates). In this case, mutual spin flip-flops are allowed and the high electron spin polarization can be transferred to the nuclear spins. Thus, transferring of the polarization of the electron spins to the nuclear spins can be achieved.

In some embodiments, the DNP method termed NOVEL may be used to transfer spins from the electrons to the nuclear spins. In NOVEL, a π/2 rotation may be carried out, followed by spin locking for an adequate time for the transfer of the electron spin to the nuclear spin to occur. In some embodiments, the Hartmann-Hahn condition may be achieved by a microwave field or a radio frequency field, the intensity of the field which may be chosen to match the energy difference between dressed electron spin eigenstates and the nuclear spins in an external magnetic field.

In other embodiments, a method for using the interaction between electron spins of the polarization structure or the mediator electron and nuclear spins may involve excitation of selective transitions caused by the dipolar interaction of nuclear spin states with the electron spin. Focusing on a two particle system of an electron spin and a nuclear spin, the dipolar interaction may cause a shift in the energy level of the combined two-spin quantum system. This shift may induce different energy gaps between the two spin system states, meaning that each transition between states may have a unique energy gap. This may allow for external excitation of only one selected transition using pulses or continuous waves in a specific frequency tuned to the energy gap of that particular transition. Excitation of the transition between the state where the electron spin is polarized and the nuclear spin is not polarized to the opposite state (polarized nuclear spin, non-polarized electron spin) may induce a polarization transfer, used in the solid effect DNP protocol.

In another embodiment, the polarization may be transferred by matching the color center excited or ground state level anti-crossing to the nuclear spin energy gap. In “Sensitive magnetic control of ensemble nuclear spin hyperpolarization in diamond”, Nat Comm 4, 1940 (2013), Wang et al show that by tuning the ground state level anti crossing of NV-centers, nearby ¹³C nuclear spins inside the diamond can be polarized efficiently. The same has been shown in “Bulk Nuclear Polarization Enhanced at Room-Temperature by Optical Pumping”, Phys Rev Lett 111, 057601 (2013) by Fischer et al for the excited state level anti-crossing of the NV center. The disclosure of which is incorporated into the present disclosure by way of reference. In some embodiments, the transfer step may be performed by an interaction involving at least two electron spins of the polarization structure and one nuclear spin of a particle. This mechanism (for example when used in the cross effect and thermal mixing DNP protocols) may be based on allowed transitions of several electron spins and a nuclear spin involving a homogeneously or inhomogeneously broadened EPR line. The broadening of the EPR line may allow a simultaneous flip of two or more electron spins and a nuclear spin to be energy conserving and enables transfer of the electron spins' polarization to the nuclear spins with the correct microwave irradiation.

In some embodiments, electron spins of mediator electrons may be used for enhancing the interaction between the color center and nuclear spin. The mediator electrons may be located outside the polarization structure. A mediator electron spin may refer to any free electron spin, for which the distance to the nuclear spin is comparable or shorter than the distance of the color center to the nuclear spin. In some embodiments, the mediator electron spins may be defects inside the polarization structure. Diamond lattices, for example, typically contain electron spin impurities, mainly substitutional Nitrogen (P1) defect centers. These P1 centers can be more densely packed and closer to the diamond surface compared to color centers. However other defects with long spin lifetime can be present, such as phosphor and vacancy aggregates.

In other embodiments, the mediator electron spins may be free electron spins located outside the polarization structure on the structure's surface. The surface of a diamond, for example, may contain many dangling chemical bonds which contain free electrons. Additionally, free radicals can be attached to the polarization structure such as a diamond, including but not limited to mono- or biradicals or metal ions. A partial list may include: Gadolinium, TRITYL, TEMPO, BDPA, BTnE, TOTAPOL. Such spins may be photostable. In yet other embodiments, the mediator electron spins may not be attached to the polarization structure. In such embodiments, the mediator electron spins can, for example, be part of a solution or suspension in which the particles are dissolved or suspended. The mediator electron spins can, for example, be free radicals in the solution or free electron spins which are part of the particles. The mediator electron spins may or may not be polarized in the interaction, depending on the specific method.

In some embodiments, the mediator electron spins may be driven at a non-resonant frequency compared to the polarization structure's electron spins and nuclear spins. Taking as an example the NOVEL DNP protocol for polarization transfer from the electron spins of the polarization structure to nuclear spins, the electron spins of the polarization structure and the nuclear spins may be driven by microwave and/or RF fields so that their Rabi and Larmor frequency match. The mediator electron spins may be driven so that their effective Rabi frequency will be detuned from the frequency of the matching electron spins of the polarization structure and the nuclear spins. This detuning may turn the polarization transfer from electron spins of the polarization structure to the electron spin of the mediator into a virtual transition. This virtual transition, combined with the virtual polarization transfer from the electron spin of the mediator to the nuclear spin, may induce an effective interaction between the electron spins of the polarization structure and the nuclear spins. This effective interaction may be equal to the smaller of the dipolar interaction of the polarization structure of the electron spin with the mediator electron spin and the interaction of the mediator electron spin with the nuclear spin, minus approximately one order of magnitude. In many configurations, this may increase the interaction between the color center and nuclear spin by two orders of magnitude or even more. In some embodiments, the mediating electron spins may not be polarized by the polarization process.

In another embodiment, the polarization transfer from an electron spin of the polarization structure to a nuclear spin of the particle may occur in two steps, such that first the mediator electron spin is polarized by the electron spin of the polarization structure and then the nuclear spin is polarized by the mediator electron spin. This method can be very effective in cases where the interaction between the color center and electron spin is significantly larger than the interaction between the electron spin and nuclear spins, and the electron spin relaxation time is longer than the transfer time to the nuclear spins. This method can be especially effective in polarization of a solid.

In another embodiment, an electron spin of the polarization structure and a mediator electron spin may be brought into resonance with a nuclear spin of the particle, thus achieving a “triple Hartmann Hahn” condition. In this case, the polarization can be transferred to both the mediator electron spin and the nuclear spin, thereby significantly enhancing the overall polarization transfer rate. As the mediator electron spin and the nuclear spin are strongly coupled, the transferred polarization can alternate between them. However, because the polarization of the nuclear spin can diffuse on a timescale faster than the polarization transfer, whenever a polarization is transferred to the nuclear spin, the polarization may have a high probability of leaving the immediate vicinity of the mediator electron spin and the electron spin of the polarization structure from which the polarization originated, and therefore, may not transfer back the polarization.

In some embodiments, the cross effect may be performed between an electron spin of the polarization structure, a mediator electron spin and a nuclear spin in a particle. In some embodiments, the spin of the mediator electron may be driven in a way such that its effective Rabi frequency is detuned from the effective Rabi frequency of the electron spin of the polarization structure by the average Larmor frequency of the nuclear spin. This may allow a simultaneous flip of all three spins while conserving energy, and a more efficient polarization.

In some embodiments, the mediating electron spins may be decoupled from all other electron spins (including other mediating electron spins). Flip-flop interactions between close mediator electron spins can decrease the effective interactions between the color centers and the nuclear spin induced by the mediating electron spins. In one embodiment, the interaction between electron spins may be reduced by a Lee-Goldburg decoupling (see Lee, Moses, and Walter I Goldburg “Nuclear-magnetic-resonance line narrowing by a rotating rf field.” Physical Review 140.4A (1965): A1261): the microwave electromagnetic field used for driving the electron spins is applied at a detuned frequency from the electron spin bare Rabi frequency). The subject matter of which is incorporated into the present disclosure by way of reference. Matching this detuning with the microwave amplitude times square root of two effectively may decouple between the electron spins, with the condition that the microwave amplitude is one order of magnitude larger than the electron spin dipolar interaction. In certain embodiments, a second microwave or RF field is added to tune the effective Rabi frequency of the electron spins.

Many color center may exhibit a ground and excited state splitting between some of the energy levels even in zero magnetic field (“zero-field splitting”). Due to the large zero-field splitting inherent in the color centers (and the large magnetic moment of the electron in a low magnetic field), the energy levels of the color center spin may be distributed over a large range of possible values, depending on the angle of the color center axis from the magnetic field orientation. The range of variation of the energy levels may be of the order of several Gigahertz (GHz). Thus, applying an external microwave field may resonantly couple only an exceedingly small fraction of the color center spins to the nuclear spins. Tuning the magnetic field to a specific value corresponding to the energy gaps between the NV spin levels may also not be feasible. Moreover, in an external magnetic field, additional limitations may concern the optical polarization of most color center spins, such as the NV spin in diamond. In particular, in a high external magnetic field, the NV spins may be initialized to different states depending on their angle with the external magnetic field, thereby resulting in a small net polarization. An additional problem posed in the case of a low magnetic field may be that the external microwave field is randomly oriented in regards to the crystal lattice orientation, thereby causing a large deviation in the color center's effective Rabi frequency.

The two regimes of the magnetic field strength may include the high magnetic field regime and low magnetic field regime. The high magnetic field regime may be defined as the regime where the color center Larmor frequency is larger than the zero-field splitting. For NV centers, this may correspond to magnetic fields larger than about 0.1 T, larger than about 0.2 T, or larger than about 0.4 T. The low magnetic field regime may be defined in the opposite fashion (zero field splitting of the color centers is larger than the Larmor frequency). For NV centers, this may correspond to magnetic fields smaller than about 0.1 T, or smaller than about 0.05 T.

A first solution to the problem of polarization transfer with random orientation may include having a suitably designed microwave frequency sweep, thereby enabling the involvement of multiple color center orientation in the polarization transfer. A microwave frequency sweep may be defined as a change in time of the microwave frequency across a given range. This change can be continuous, with a constant or varying speed, or alternatively using discrete frequencies, with a constant or varying gap between the discrete frequencies. Additionally or alternatively, the microwave frequency can remain constant, while varying the strength of the external magnetic field. As a variation of the microwave frequency or the external magnetic field may be interchangeable, both may be addressed as a microwave frequency sweep. The insignificant differences between microwave and external magnetic field sweeps, such as the change in the nuclear Larmor frequency, will be noted and explained in the text.

For a frequency sweep to be effective, four conditions have to be met:

1. A large percentage of color center orientations have to be included in the frequency sweep.

2. It should be possible to efficiently optically polarize most, if not all, the color centers involved in the frequency sweep.

3. The frequency sweep should enable effective polarization transfer from the involved color centers to the surrounding nuclear spins. This may require the frequency range in the sweep to be sufficiently small and/or the sweep velocity to be large, while allowing effective transfer.

4. The duration of the frequency sweep should be less than about 1 ms, less than about 100 μs, or less than about 10 μs, to allow numerous cyclic repetitions of optical pumping and polarization transfer steps within the polarization lifetime of the nuclei.

Condition 1 may require the frequency sweep to cover a wide range of color center orientations, while conditions 3 and 4 may require the frequency range to be narrow. Therefore, the polarization sweep may need to include a small frequency range, which includes a wide range of color center orientations that can also be efficiently optically polarized.

In the high magnetic field regime, the principal quantization axes of the color centers may be determined by the external magnetic field orientation. The energy gap between the color centers' energy levels may be determined by the angle between the crystal orientation and the magnetic field orientation. This angle may determine the zero field splitting value along the magnetic field quantization axis, which may be defined as the misaligned zero field splitting. In some embodiments, the microwave frequency sweep may be performed in frequency ranges where the misaligned zero field splitting varies slowly. This may correspond to angles near 0 degrees (crystal axis along or opposite the magnetic field orientation) or 90 degrees (crystal axis perpendicular to the magnetic field orientation). The 0 degrees angle will be termed as parallel crystal axis and the 90 degree will be termed as perpendicular crystal axis. In some embodiments, the frequency sweep may encompass angles no larger than 20 degrees deviation from parallel or perpendicular respectively, or maximally 10 degrees deviation, or 5 degrees deviation. Due to the quadratic nature of the zero-field splitting in NV centers, there is no difference if the crystal axis is aligned along or opposite the magnetic field orientation. For NV centers, the zero field splitting for parallel crystal axis may be about 2880 MHz. The variation in the misaligned zero field splitting may be about 130 MHz for 10 degrees deviation and about 600 MHz for 20 degrees. For perpendicular crystal axis, the misaligned zero field splitting may be −1440 MHz. The variation in the misaligned zero field splitting may be about 130 MHz for 10 degrees deviation and about 500 MHz for 20 degrees. Remarkably, both the parallel crystal axis and perpendicular crystal axis may allow efficient optical pumping of the NV center spin. For the parallel crystal axis, the NV center spin may be pumped into the mₛ=0 state, which corresponds to a polarization of 100%. For the perpendicular crystal axis, the NV center spin may be pumped into the {mₛ=+1,−1} subspace. As the polarization is performed between the mₛ=0 and mₛ=+1 or mₛ=−1 states, this may correspond to an average of 50% polarization. In both cases, for 10 degrees deviation, the optical polarization may need to be multiplied by 0.94 (average 0.97 for 0-10 deviation range), and for 20 degrees by 0.77 (average 0.88 for 0-20 deviation range). Thus, the achieved optical polarization may be 2-3 orders of magnitude larger than the electron polarization at room temperature and similar magnetic field strengths.

In the low magnetic field regime, the quantization axis of the color center may be given by its zero field splitting orientation (crystal orientation). As discussed above, the energy gap between the color center's energy levels may be determined by the angle between the crystal orientation and the magnetic field orientation. This angle may determine the magnetic field value along the magnetic field quantization axis, which may be defined as the misaligned Larmor frequency. In this regime, the misaligned Larmor frequency value range can be much smaller than the misaligned zero field splitting range in the high magnetic field regime. Thus, a larger angle deviation can be included in the microwave frequency sweep. Optical initialization in the low magnetic field regime may be efficient for all crystal axis orientations, as long as the magnetic field value does not correspond to the excited state level avoided crossing value of about 0.05 T. In order to overcome the random angle between the applied microwave field and the crystal orientation, the microwave field may be applied in parallel to the external magnetic field. Thus, all color centers with the same angle from the magnetic field (and same misaligned Larmor frequency) may have the same angle from the driving microwave field, and could be tuned to the same Rabi frequency.

The microwave frequency sweep can be achieved by changing (1) the external magnetic field (2) sweeping the microwave frequency while using low Q-factor resonators (3) sweeping the microwave frequency while tuning the coupling to a high Q-factor resonator to lower the effective Q-factor, and/or (4) changing the position of the nanodiamond ensemble in relation to the magnet, such that the magnetic field at the nanodiamond ensemble position changes.

A second solution to the random color center orientation may include the use of a detuned microwave driving in the high magnetic field regime, thereby efficiently narrowing the energy gap differences between color centers of different orientations. A detuned microwave driving may be defined as a microwave driving with a frequency which differs from the energy gap of between any of the energy levels of the color center by at least 50 MHz, but is no greater than 50 MHz from half the energy difference between the mₛ=+1,−1 states. This arrangement can be used to produce interaction between the mₛ=+1,−1 states of the color centers without populating significantly the mₛ=0 state resulting in a much weaker dependence of the scheme on the orientation of the diamond.

In the high magnetic field regime, a detuned microwave driving may be applied. The frequency of the detuned microwave driving may be chosen to match the Larmor frequency of the color centers, plus corrections from the misaligned zero field splitting. In some embodiments, this value may be no greater than about 100 MHz from half the energy splitting between the mₛ=+1,−1 levels, no greater than about 50 MHz, no greater than about 10 MHz, or no greater than the Rabi frequency squared divided by the detuning from the mₛ=0 to mₛ=+1 transition. The corrections from the misaligned zero field splitting (second order corrections) may be on the order of only tens of MHz for all orientations, compared with several GHz for the energy gap dependence on the misaligned zero field splitting itself. Thus, with detuned microwave driving, many more orientations may be involved in polarization transfer for a specific microwave frequency, and the sweep range for involving large angle deviation may be reduced considerably. For 10 degree deviation from the perpendicular/parallel crystal axis, the frequency range may be only about 10 MHz, compared with about 130 MHz for non-detuned driving. For 20 degree deviation, the frequency range may be only about 45 MHz instead of 500 about MHz. The detuned microwave driving may create an interaction between the mₛ=+1,−1 states of the color center, through virtual transitions to the mₛ=0 state. Thus, in the detuned driving case, the polarization transfer may involve transitions between the mₛ=+1 and mₛ=−1 states of the color center. In some embodiments, the microwave detuned driving may correspond to a Rabi frequency of at least about 20 MHz for the color center, at least about 40 MHz, at least about 60 MHz, or at least about 80 MHz.

In some embodiments, the optical pumping step and the transfer step may be repeated cyclically. After the optical pumping of the electron spins of the polarization structure, the obtained polarization can be transferred to the nearby nuclear spins of the particles. By repeating the optical pumping step and the transfer step, it may be achievable to polarize most, if not all nuclear spins in close proximity to the polarization structure.

In some embodiments, a pause after each cycle may allow for some of the particles to diffuse away from the polarization structure, and unpolarized nuclear spins to take their place. Advantageously, the diffusion of particles away from the polarization surface may occur spontaneously, and no application of alternating electromagnetic fields may be required during the diffusion of the particles. By cyclically repeating the optical pumping step, transfer step and pause, most, if not all, of the particles may be polarized. In some embodiments, the polarization of the hyperpolarized particles may be greater than about 1%. For example, 100 particles, each with one nuclear spin, with 51 spins in one direction and 49 in the opposite direction may have a polarization of about 2%. In some embodiments, the nuclear spin polarization may be greater than about 0.1%, greater than about 1%, greater than about 10%, greater than about 30%, or greater than about 50%.

In some embodiments, especially when the diffusion coefficient is extremely small (e.g. in polarizing solid particles in air), the polarization may be propagated between nuclei in the particle via dipolar interactions. In other embodiments, the polarization may be propagated between nuclei of separate particles.

In some embodiments, it may be possible to produce a wide range of hyperpolarized particles at temperatures higher than about 70 K, higher than about 270 K, or at room temperature. Advantageously, such temperatures may not require expensive cooling systems involving liquid helium, but can be achieved with liquid nitrogen, or even with simple non-cryogenic cooling. In some embodiments, such temperatures may not require cooling at all. Advantageously, since the polarization may be produced not by thermodynamic electron spin equilibrium, this substantial increase in temperature may not correspond to a loss of maximal polarization obtained.

In some embodiments, the particle(s) may have a temperature higher than about 273 K, or at room temperature. Accordingly, the particles may not need to be melted after the polarization. Therefore, it can be avoided that a melting performed after the hyperpolarization entail a significant polarization loss before the particles can be put to a use, for example, in NMR. In some embodiments, hyperpolarized particles after partial or complete loss of their polarization may be re-hyperpolarized, for example, to be re-used. Such re-hyperpolarization can be particularly convenient if it is performed at room temperature.

In some embodiments, one or more particles hyperpolarized may be used in a nuclear magnetic imaging (NMR) or magnetic resonance imaging (MRI) applications. Hyperpolarized particles can, for example, contribute to achieving a better resolution in NMR imaging of e. g. crystal structures and proteins. For example, even small amounts of the hyperpolarized particles can be detected by NMR imaging. In some embodiments, if used for NMR, the molecules may first be hyperpolarized and then imaged in an NMR or magnetic resonance imaging system. In certain embodiments, the hyperpolarized molecules may be used to increase the signal in an NMR application. In certain embodiments, the hyperpolarized molecules can be added to a subject in vivo to enhance the contrast of an MRI image and highlighting specific processes. In certain embodiments, the hyperpolarized molecules may include molecules which have a sufficiently long hyperpolarization time and are involved in metabolic processes, including but not limit to [1-¹³C]pyruvate, ¹³C-Enriched Bicarbonate, [1,4-¹³C₂]fumarate, [1-¹³C]lactate, [5-¹³C]glutamine, [1-¹³C]acetate, [2-¹³C]-fructose, [1-¹³C]succinate, [1-¹³C]-α-ketoisocaproate, ¹³C-choline/¹⁵N-choline and glucose derivatives ([1-¹³C]glucose and [6,6-²H₂]glucose). In certain embodiments, the hyperpolarized molecules may include non-metabolic molecules under investigation for hyperpolarized imaging, such as the reporter probe 3,5-Difluorobenzoyl-L-glutamic acid. In certain embodiments, the hyperpolarized molecules may include nanoparticles, which exhibit very long relaxation times.

### Microfluidic Channel

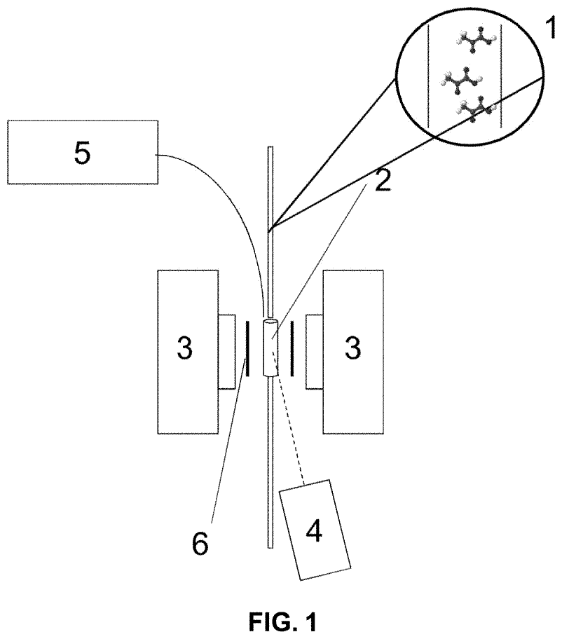

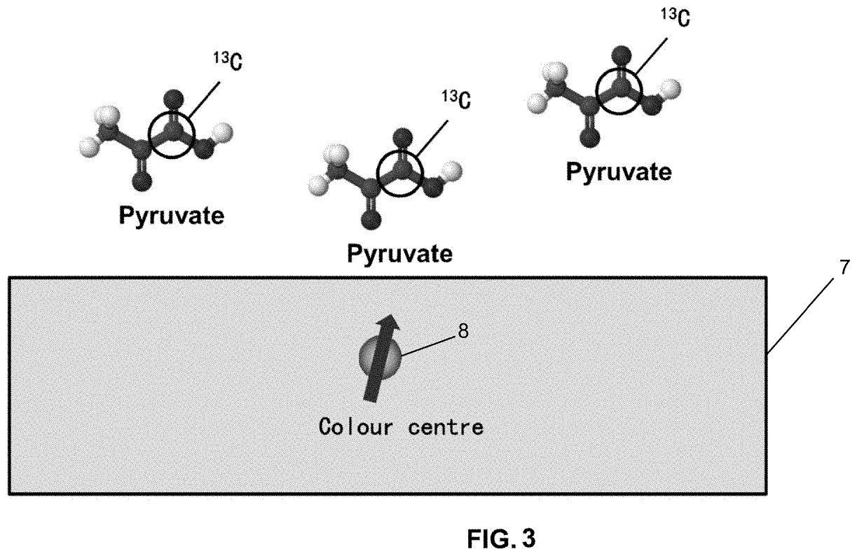

Referring to FIG. 1, an exemplary experimental setup with a solution of pyruvate particles 1 flowing through a microfluidic channel 2, placed in the magnetic field of an electromagnet 3, is shown. The microfluidic channel 2 may contain multiple color centers. A laser 4 may be configured to excite the color center electrons. A microwave source 5 and amplifier, in combination with a resonator 6, may allow facilitation of polarization transfer from the color center spins to the ¹³C nuclei in the pyruvate molecules. For example, FIG. 3 illustrates an exemplary schematic diagram of an interface between a polarization structure 7 comprising a color center 8 and ¹³C nuclei in the pyruvate particles 1.

The polarization structure, such as polarization structure 7, can be composed of different materials containing color centers 8. While the experimental details below will be given for NV centers in a diamond substrate, the setup and polarization transfer for other materials and color centers may be similar. For example, for divacancies and silicon vacancies in silicon carbide or optically active defects in zinc-oxide or other wideband gap materials, the setup and polarization transfer may be similar. The differences may only be in the wavelength of the optical irradiation, the zero-field splitting and relaxation rates of the color center, and the rate of polarization achieved. Similar protocols can be adapted with different parameters for optimizing polarization depending on the color center and material.

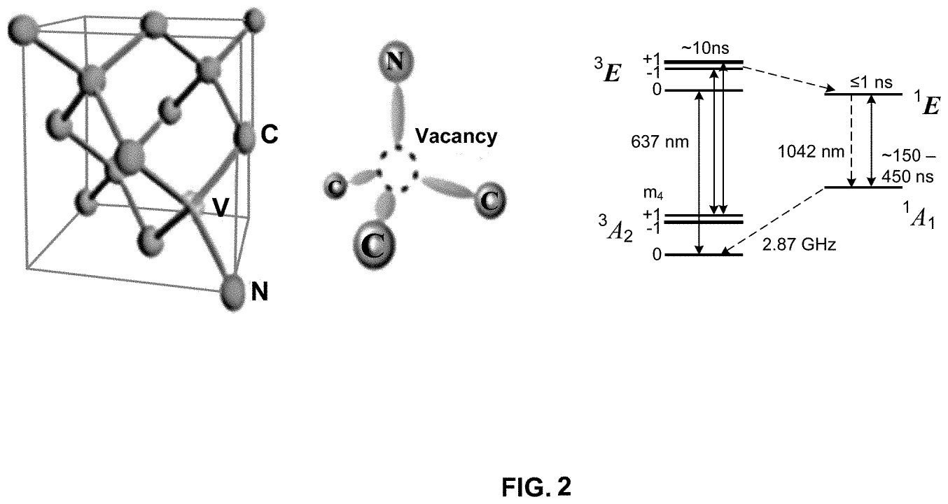

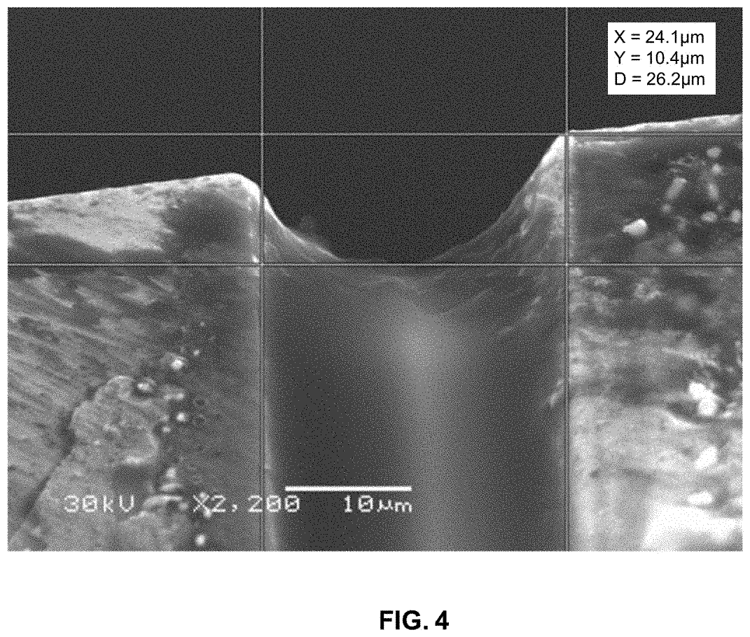

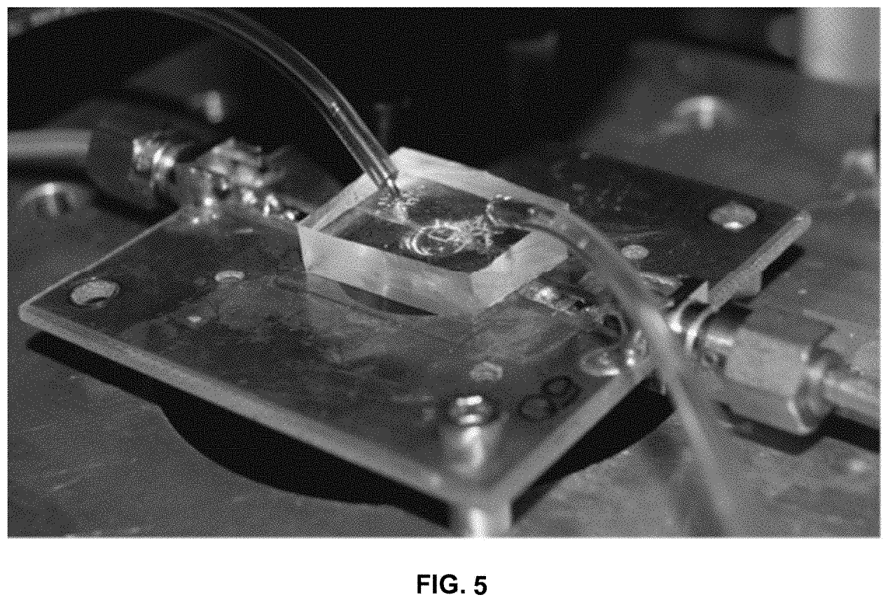

FIG. 2 illustrates an exemplary interaction interface between the color center spin and the particles in the solution containing nuclear spins. Diamond material for this protocol may contain NV centers close to the diamond surface. Material itself may be grown using CVD technique or HPHT method. NV centers close to the diamond surface may be introduced by injection of nitrogen gas during CVD growth or by implantation of nitrogen after the growth. In the latter case, post-irradiation of sample can be employed to increase the formation yield of NV centers. Inside the diamond layer approximately 20 nm from the surface, denoting the z axis as perpendicular to the diamond surface, the diamond may ideally contain one NV center for every 100 nm² in the x,y dimensions. FIG. 2 illustrates an NV center in a diamond lattice, and the corresponding level structure. FIG. 4 illustrates an image of a microfluidic channel in a diamond. The microfluidic channel may then be covered by a layer, such as a Poly(methyl methacrylate) (PMMA) layer, to create a closed structure, as seen in FIG. 5. For silicon-carbide, the crystal can be grown by sublimation techniques. The color centers can be generated by irradiation with neutrons or electron (see for example Kraus, H et al (2014) Room-temperature quantum microwave emitters based on spin defects in silicon carbide, Nat Phys 10, 157-162; the subject matter of which is incorporated into the present disclosure by way of reference.)

Many different solvents can be used in the solution. For example, pyruvate may be dissolved in a mixture of water and glycerol, and the concentration of the two solvents may determine the pyruvate self-diffusion coefficient.

Electron spins associated with NV centers may be polarized either by the application of short laser pulses emitted by laser 4, or by continuous irradiation. Optical pumping may be achieved by excitation of the NV center into an excited electronic state. The decay of this state may occur predominantly into the mₛ=0 level of the ground state. Several cycles of excitation and decay may produce a polarization of the NV center that is greater than 95%.

A similar spin-selective recombination by optical excitation and decay through a metastable state may happen for color centers in silicon-carbide (e.g. to the mₛ=0 state in divacancies) and in the other host materials mentioned above.

A proposed experimental realization of a DNP protocol for the polarization transfer may be achieved by establishing a Hartmann-Hahn condition between the electron and nuclear spin. This may be achieved by driving the electron spin transitions between mₛ=0 and mₛ=−1 state by means of a microwave field whose intensity may be chosen to match the energy difference between dressed electronic spin eigenstates and the nuclear spins in an external magnetic field.

The dynamics of the NV electronic spin and an additional nuclear spin, in the presence of a continuous driving microwave field, have been theoretically analyzed in Cai, J M et al, “Diamond based single molecule magnetic resonance spectroscopy”, New Journal of Physics, 2013, 15, 013020, and the article's supplementary information; the subject matter of which is incorporated into the present disclosure by way of reference. The Hamiltonian describing the NV center electronic mₛ=0, −1 states and an additional ¹³C nuclear spin, in the presence of an external magnetic field B and a resonant microwave field is

H=Ωσ_{z}⊗1+γ_{N}1⊗|B_{eff}|σ_{z}+γ_{N}A_{hyp}σₓ⊗(sin θσₓ+cos θσ_{z}) (1)

where Ω is the Rabi frequency of the driving field and a are the spin-½ operators, defined in the microwave-dressed basis

$$\vert \pm 〉 = \frac{1}{\sqrt{2}} ( \vert 0 〉 \pm \vert - 1 〉 )$$

for the electronic basis, and in the (|↑_{z′} [symbol] , |↓_{z′} [symbol] basis for the nuclear spins, where z′ is defined along the direction of B_{eff}. B_{eff} is an effective magnetic field and is given by B_{eff}=B−(½) A_{hyp}, where A_{hyp} is the hyperfine vector which characterises the coupling between the two spins. In equation (1), γ_{N} is the gyromagnetic ratio of the nuclear spin and cos θ=ĥ·\hat{b} where ĥ and \hat{b} are the directions of the hyperfine vector A_{hyp} and the effective magnetic field B_{eff}, respectively. The first two terms in the Hamiltonian form the energy ladder of the system (Ω for the dressed NV spin, and γ_{N}|B_{eff}| for the Larmor frequency of the nuclear spin), whereas the last two terms are responsible for electron-nuclear spin interaction.

Here, the former may represent mutual spin-flips, or coherent evolution of the electron-nuclear pair, and the latter may be the nuclear spin dephasing caused by electron flips. When the driving field is adjusted properly, an energy matching condition (known as the “Hartmann-Hahn condition”) given by

Ω=γ_{N}|B_{eff}|=γ_{N}|B−(½)A_{hyp}|, (2)

may be engineered, thereby equalizing the first two terms in Hamiltonian (1). Then, the coupling term in the Hamiltonian may become dominant, and the time evolution of the system may be a coherent joint evolution of the electron nuclear pair. For instance, starting in the |+, ↓ [symbol] state, the system evolves according to |Ψ [symbol] =|+, ↓ [symbol] cos (Jt)⁺|−, ↑ [symbol] sin (Jt), with J given by

J=¼γ_{N}|A_{hyp}| sin θ. (3)

Thus, at time t=π/2J, the two spins may become maximally entangled, and after a t=π/J, a full population transfer may occur and the states of the two spins may be in effect ‘swapped’.

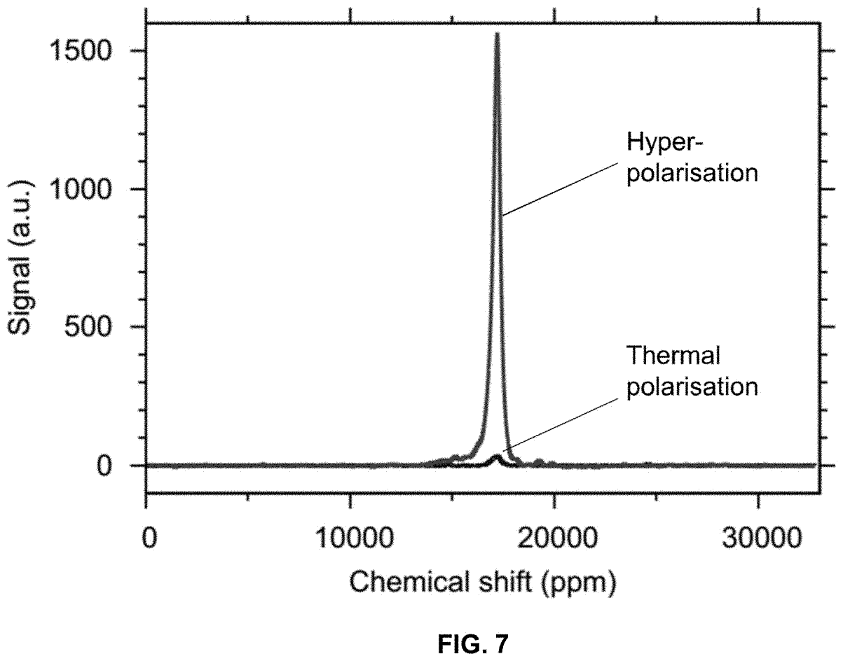

In the NOVEL sequence, a short microwave pulse at the electron spin frequency may be first applied in order to rotate the spin to the X-Y plane (e.g. to the |+F> state), termed a “π/2 pulse”. The resonant microwave frequency described above may, then, be applied, with a π/2 phase shift from the π/2 pulse. This resonant microwave pulse may be termed as the “spin locking pulse”. A spin locking pulse of length 10-100 μs may efficiently transfer the polarization to the nuclear spins in the ensemble. FIG. 7 shows the hyperpolarization of ¹³C nuclear spins inside the diamond achieved via the NOVEL sequence, compared to the thermal polarization.

However, for polarizing nuclear spins in a solution, the molecular motion may need to be taken into account, thereby causing time-varying terms in the Hamiltonian. In a change of notation, the time-varying Hamiltonian used to describe the coupled spin system in the secular approximation, similar to equation (1) may be given by

H(t)=Ωσ_{z}^{e}+γ_{N}B_{eff}(t)·σ^{N}−σₓ^{e}[A(t)·σ^{N}] (4)

where A(t) is the hyperfine vector, B_{eff}(t)=B−0.5/γ_{N} A(t) is the effective magnetic field and γ_{N} is the nuclear gyromagnetic ratio, S the NV center spin operator and a the nuclear spin operator vector. A(t) stems from the fluctuating position of the nuclear spin r(t) relative to the NV center. Specifically, A(t) and r(t) are related by

$$A ( r ) = - \frac{{ℏμ}_{0} {γ}_{e} {γ}_{N}}{4 π {\vert r \vert}^{3}} ( 3 {\hat{r}}_{x} {\hat{r}}_{z} , 3 {\hat{r}}_{y} {\hat{r}}_{z} , 3 {\hat{r}}_{z}^{2} - 1 ) ,$$

as usual.

To analyze the efficiency of the polarization transfer via resonant conditions in the presence of molecular motion, the Hamiltonian of equation (4) can be simulated by a Monte-Carlo simulation. The molecular motion of the particle may be calculated by the Ito equations (details of the method provided in C W Gardiner. Stochastic methods. Springer-Verlag, Berlin-Heidelberg-New York-Tokyo, 1985; the subject matter of which is incorporated into the present disclosure by way of reference.) The coupling of the nuclear spin in the particle to the NV may then be calculated at very small intervals (for example, under 10 nanoseconds). The solution to the Liouville-von Neumann equation,

$$i ℏ \frac{\partial ρ}{\partial t} = [ H , ρ ] ,$$

with the time-dependent Hamiltonian of equation (4) may be obtained via a Runge-Kutta method (see e.g. Press, W et al (2007), “Section 17.1 Runge-Kutta Method”, Numerical Recipes: The Art of Scientific Computing (3rd ed.), Cambridge University Press; the subject matter of which is incorporated into the present disclosure by way of reference.) As no coherent effects involving several spins are expected in the parameter range of interest, and the nuclear interaction of the moving particles is negligible, the polarization transfer rate can be extended to numerous particles with nuclear spins in the region of interest.

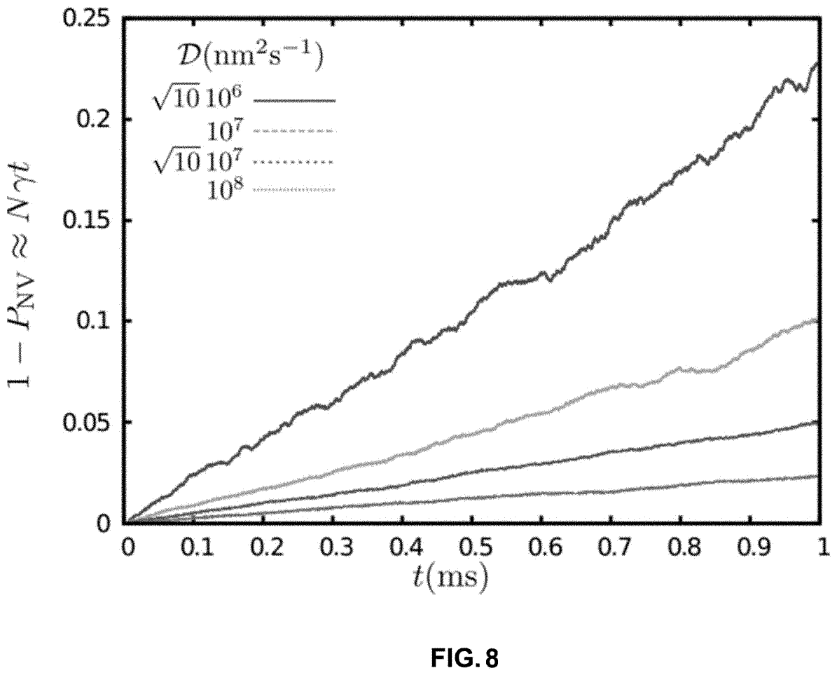

FIG. 8 illustrates the polarization transfer dependent on time for a NV center 5 nm from the diamond surface, interacting with the nuclear spins in a (5 nanometer)³ box external to the diamond. As seen in FIG. 8, the polarization transfer rate via resonant coupling may be dramatically increased for smaller diffusion coefficients.

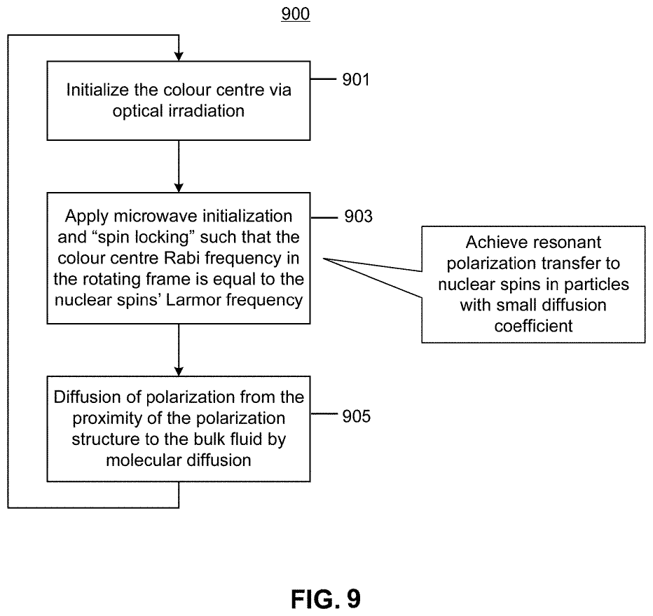

FIG. 9 illustrates an exemplary polarization method 900, in accordance with the embodiments of the present disclosure. Method 900 may begin at block 901. At block 901, the color center may be initialized via optical irradiation. When the color center has been initialized, method 900 may proceed to block 903, at which microwave initialization and “spin locking” such that the color center's Rabi frequency in the rotating frame may be equal to the nuclear spins' Larmor frequency. Accordingly, resonant polarization transfer to the nuclear spins in the particles with small diffusion coefficient may be achieved. Method 900 may further proceed to block 905, at which polarization may be diffused or transferred from the proximity of the polarization structure to the bulk fluid by molecular diffusion. As many other color centers in other materials (for example, silicon vacancies in silicon carbide) may exhibit the same or similar photodynamics and Hamiltonian, the polarization transfer may be achieved by similar protocols, after modifying the microwave drive frequency to the corresponding resonance (for example, due mainly to a different zero field splitting).

As mediating electron spins external to the polarization layer, the diamond layer can be coated with TEMPO, Trityl radicals or other paramagnetic species. Additionally or alternatively, dangling bonds already on the diamond surface can be used as the mediating electron spins. Additionally or alternatively, radicals can be added to the solution, to serve as mediating electron spins. For example, Trityl radicals may be typically used in dynamic nuclear polarization setups, and can be used for mediating the polarization transfer to further away nuclear spins.

### Nanoparticles Suspended in a Solution

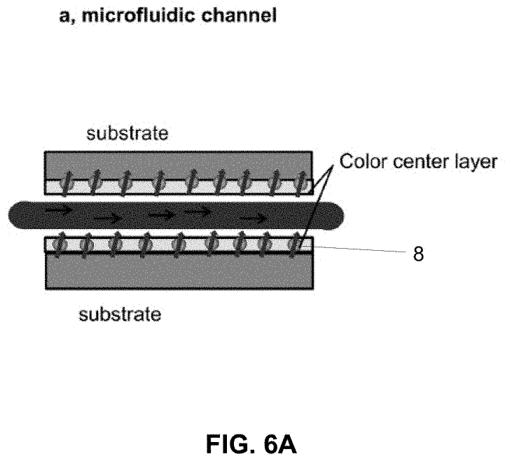

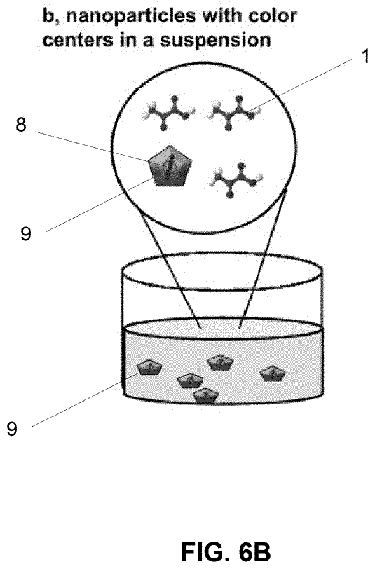

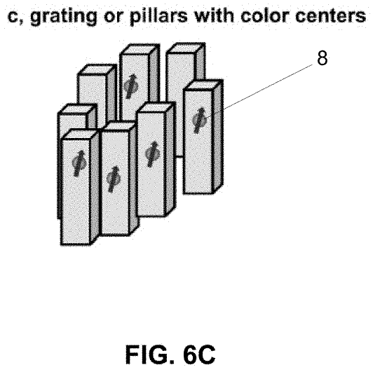

In some embodiments, as seen in FIG. 6A, a solution of pyruvate particles may be injected through a microfluidic channel comprising a plurality of color centers 8 in order to transfer polarization from the spins of the color centers 8 to the ¹³C nuclei in the pyruvate particles in the solution. While FIG. 6A illustrates plate-like substrates with a plurality of color centers 8, the substrates are not limited to plate-like shapes. For example, as seen in FIG. 6C, the substrates may be nanostructured and may comprise grating or pillars with color centers 8. By nanostructuring the substrates, the surface area may be increased, thereby allowing more efficient transfer of polarization from the spins of the color centers 8 to the ¹³C nuclei in the particles.

In another embodiment, the polarization structure may include the use of nanoparticles suspended in a solution. While many elements are similar to the microfluidic channel setup, key differences, mainly dealing with the random orientation of the nanoparticles, will be highlighted below. For example, FIG. 6B illustrates an exemplary experimental setup may comprise a solution of pyruvate particles 1 with a suspension of nanodiamonds 9 containing color centers 8, such as NV centers.

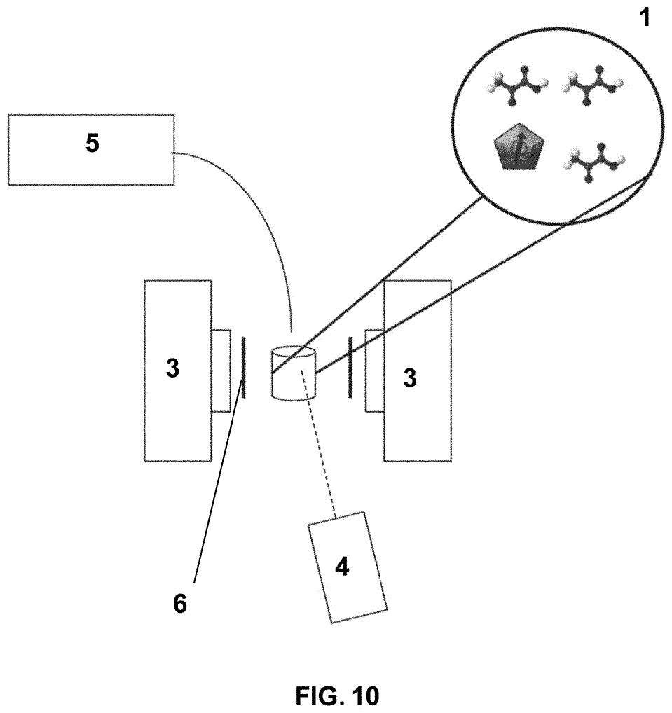

FIG. 10 illustrates the conceptual details of the exemplary experimental setup of FIG. 6B with a solution of pyruvate particles 1 with a suspension of nanodiamonds 9 containing NV centers 8. As seen in FIG. 10, the solution may be placed in the magnetic field of an electromagnet 3. A laser 4 may be configured to excite the color center electrons. A microwave source 5, in combination with a resonator 6, may allow facilitation of polarization transfer from NV center spins to the ¹³C nuclei in the pyruvate.

The nanodiamonds may be produced by high-pressure high temperature (HPHT) method. For the direct polarization of external spins via NV centers, ultra-small nanodiamonds, such as diamonds with volume between about 1 nm³ and about 1000 nm³, may be used, although nanodiamonds with diameter up to about 50 nm or more are also possible. Polarization transfer may be enabled by dipolar interactions between NV center spins and external nuclear spins.

Electron spins associated with NV centers can be polarized either by the application of short laser pulses, or by continuous irradiation. Optical pumping may be achieved by excitation of the NV center into an excited electronic state. For NV centers aligned in parallel to the magnetic field, the decay of this state may occur predominantly into the mₛ=0 level of the ground state. Several cycles of excitation and decay may produce a polarization of the NV center that is greater than about 95%.

For small deviations in the angle, the optical polarization may depend on the external magnetic field strength. For weak magnetic fields, γ_{E}B<<D, With γ_{E}B denoting the electron Larmur frequency, D the zero field splitting (D=2.87 GHz), the optical polarization may be very weakly affected by the angle between the NV crystal axis and the magnetic field. Thus, high fidelity optical polarization may be expected in this regime for all NV angles. For strong magnetic fields (γ_{E}B>>D), there may be a stronger dependence on the angle. For given spherical angles θ, φ, of the NV center crystal axis in relations to the external magnetic field, the NV may be initialized to the state

$${\vert 0 〉}_{θ , φ} = cos θ \vert 0 〉 + sin θ [ \frac{1}{\sqrt{2}} ( - {e}^{i φ} \vert + 1 〉 + {e}^{- i φ} \vert - 1 〉 ) ]$$

For angle variations up to Δθ=10° from θ=0, the optical polarization may work extremely well, | [symbol] 0|0 [symbol] _{θ,ϕ}|²>0.97. θ=π/2, one gets

$${\vert 0 〉}_{θ , φ} = [ \frac{1}{\sqrt{2}} ( - {e}^{i φ} \vert + 1 〉 + {e}^{- i φ} \vert - 1 〉 ) ] .$$

While the |±1> terms oscillate very quickly in the strong magnetic field, the amplitude of the |0> state may remain zero. Thus, on average, a strong average polarization P_{NV}=|<1|ψ(t)>|²−|<0|ψ(t)>|²≈0.5 may be achieved. Moreover, unlike the usual case where P_{NV}=0.5, as |<0|ψ(t)>|²=0, a 95% polarization with additional polarization cycles may be achieved.

Similar simulations and methods applied in the microfluidic channel setup may be applied in the suspended nanodiamonds setup as well. A key difference may include the method used for achieving a resonance condition (e.g. Hartmann Hahn condition) for performing the transfer, as will be explained in more detail below.

Exchange of polarization between optically pumped electron spin of NV center and nuclear spins can be performed using several established dynamic nuclear polarization protocols, in combination with our schemes based on microwave frequency sweeps. For example, the integrated solid effect can be used. Moreover, these protocols can be combined with the polarization sweep and the detuned driving scheme, for optimal polarization transfer. Most DNP protocols may either involve interactions between electron spins or may be based on two underlying physical mechanisms: (1) fulfilling the Hartmann-Hahn condition and (2) excitation of selective transitions. The DNP protocols may differ in the configurations for achieving these conditions and by the usage of pulses or continuous waves.

For the above DNP protocols, the experimental setup may be similar, with the differences being found in the specific choice of microwave frequency, the specific type of the frequency sweep (continuous or discrete), the specific choice of the pulse sequence, and/or magnetic field strength. Similar equipment can be used for all protocol examples detailed below, as they may be performed in similar regimes.

In the high magnetic field regime, the main challenge in performing the frequency sweep may be the very large deviations of the energy gap. Moreover, for many NV orientations, optical polarization may not be feasible. However, two angle ranges enable a short frequency sweep which includes a large portion of optically polarizable NV centers.

In the laboratory coordinate system, the z-axis may coincide with the applied magnetic field, and the NV to be placed at the origin of the coordinate system. In the laboratory frame the Hamiltonian of a single NV may then be

$${H}_{eff}^{″} = ( {γ}_{e} B + δ ( θ ) ) {S}_{z} + D ( θ ) {S}_{z}^{2} , \\ D ( θ ) = \frac{D ( 1 + 3 cos ( 2 θ ) ) + 3 E ( 1 - cos ( 2 θ ) )}{4} , \\ δ ( θ ) = \frac{{γ}_{e} {BG}_{1}^{2}}{{( {γ}_{e} B )}^{2} - {[ D ( θ ) ]}^{2}} + \frac{{G}_{2}^{2}}{2 {γ}_{e} B}$$

with

$${G}_{1} = \frac{( D - E ) sin θ cos θ {e}^{i φ}}{\sqrt{2}} , \\ {G}_{2} = \frac{D + 3 E + ( E - D ) cos 2 θ {e}^{2 i φ}}{4} .$$

with γ_{E}B denoting the electron Larmor frequency, D the zero field splitting (D=2.87 GHz), E the strain of the diamond (usually over 2 orders of magnitude smaller than D), and 8 is the angle between the NV crystal orientation and the external magnetic field orientation.

The range of the energy gap between the NV spin |0> level and |±1> may be approximately γ_{E}B+D(θ) (as δ(θ) is roughly 2 orders of magnitude smaller), which may contain a large uncertainty dependent on the angle as

D(θ)∈[−(2π)1.436 GHz,(2π)2.87 GHz].

The energy gap may vary slowly for θ=0 or θ=π/2. θ=π/2 (D(θ)=−D/2) may be a particularly interesting case, as a microwave sweep corresponding to θ=π/2 to θ=π/2−Δθ may correspond to a solid angle of 4π sin Δθ. For example, for Δθ=10°, this area may encompass over 17% of the possible NV orientations (when taking into account the symmetry between θ and π−θ).

For an NV in an orientation with angle θ from the external magnetic field, defining the x-axis so that the crystal orientation and magnetic field are on the x-z plane, the Hamiltonian of the NV center spin can be written as

H=⅔DS_{z}²−⅓DSₓ²−⅓DS_{y}²+γₑB cos(θ)S_{z}+γₑB sin(θ)Sₓ.

Of important note is the fact that the zero-field splitting term does not differentiate between m=+1, −1 states. Therefore, the splitting between these states may be determined solely by the magnetic field. While it seems that for θ>π/2, the energy gap between mₛ=+1,−1 changes sign, this is just a consequence of choice of the z direction. Denoting \hat{b} as the magnetic field direction, and defining z′=sign(\hat{b}·\hat{z})z, in this new orientation ΔE_{+1,-1}=2|γ_{E}B cos θ|>0.

For the {mₛ=0,+1} subspace, a microwave field may be applied perpendicular to the magnetic field √2Ω cos(wt), and get in the interaction picture (with the RWA approximation)

H′=(D+|γₑB cos(θ)|−ω)σ_{z′}+Ω cos(θ′)σₓ.

Unfortunately, different crystal orientations with the same value of θ may have different values of θ′ (the angle from the microwave field). Thus, NV orientations with the same value of θ, when choosing ω=D+|γₑB cos(θ)| may have different Rabi frequencies, depending on their angle from the MW field orientation. This challenge can be overcome by aligning the microwave field along the magnetic field axis. In this case, the Hamiltonian in the interaction picture becomes

H′=(D+|γₑB cos(θ)|−ω)σ_{z′}+Ω sin(θ)σₓ.

Now, all NV orientations with the angle θ from the magnetic field may also have the same Rabi frequency Ω sin(θ). The frequency sweep in this regime may need to be combined with a corresponding change in the microwave amplitude, as Ω sin(θ) may need to be kept at a relatively constant value. The frequency sweep can now be performed in any range θ∈[θₘᵢₙ, θₘₐₓ]. θₘᵢₙ may need to start at a value where sin θₘᵢₙ is not too small, which may require the microwave driving amplitude to be quite large. θₘᵢₙ>10° may be sufficient.

The integrated solid effect may be a modification to the solid effect scheme by combining it with a microwave sweep. It may be used for instances where the electron spin resonance (ESR) line is broad compared to the nuclear Larmor frequency, and thus cannot be captured with a single resonant frequency. A rigorous theoretical treatment is given in Henstra, A, and W Th Wenckebach. “Dynamic nuclear polarization via the integrated solid effect I: theory.” Molecular Physics 112.13 (2014): 1761-1772. The subject matter of which is incorporated into the present disclosure by way of reference.

At the first stage, the laser may polarize the NV center by optical pumping, as described above. Next, the microwave frequency may be swept across the NV center spin resonance point. In the tilted rotating frame of the nanodiamond relative to the external magnetic field, the Hamiltonian of the system may be

$${H}_{trans} = 2 {ω}_{eff} {\tilde{σ}}_{z} + {γ}_{n} {BI}_{{z}^{′}} + \frac{{a}_{{x}^{′}} sin ϕ}{2} ( {\tilde{σ}}_{+} {I}_{-}^{′} + h . c . ) .$$

with 2ω_{eff} denoting the NV center effective Rabi frequency, γ_{N}B denoting the nuclear Larmor frequency, aₓ, the dipolar hyperfine interaction, and sin φ the angle of the tilting.

At the beginning of the sweep, 2ω_{eff} may be negative, and an adiabatic frequency sweep across the Hartmann Hahn condition 2ω_{eff}=−γ_{N}B may polarize the nuclear spins in a given direction. Then, an adiabatic crossing of 2ω_{eff}=0 may flip the NV center electron spin. Thus, when later crossing the 2ω_{eff}=γ_{N}B H.H. condition, the polarization may again be performed in the same direction. It is important to note that if the NV center is not optically repolarized between the two H.H. conditions, the sweep frequency may need to maximize the probability of only one adiabatic (Landau-Zener) transition being performed in the two H.H. conditions. This is due to the fact that the second Lanau-Zener transition in the same sweep may cancel the polarization transfer effect of the first Landau-Zener transition. Thus, also a very slow sweep may not achieve efficient polarization.

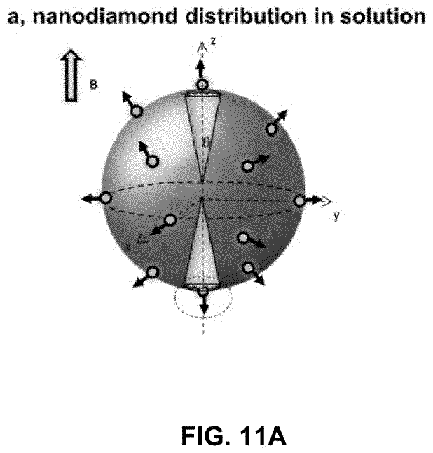

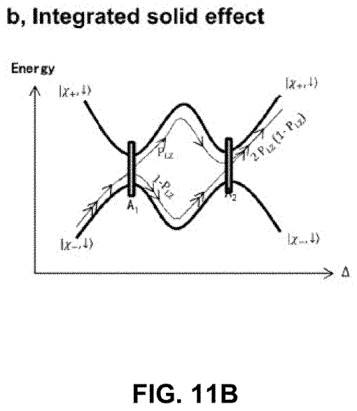

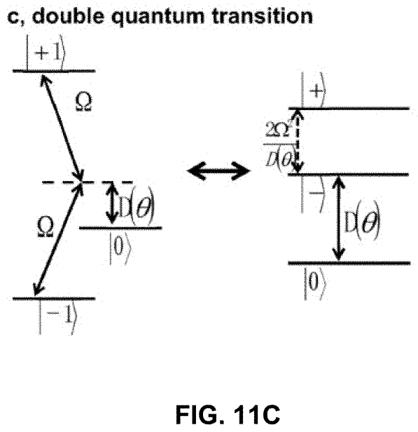

FIG. 11B illustrates the polarization transfer method with the integrated solid effect (ISE) technique. The resonance may occur twice during the ISE sweep, at points A1 and A2, where Landau-Zener transitions are possible. Polarization may be achieved when one, and only one, of the Landau-Zener transitions is crossed. An efficient polarization then may require a sweep velocity in an intermediate range.

Larmor frequencies of ¹³C nuclear spins were approximately 5 MHz for magnetic fields used in our experiments, though stronger magnetic fields can be used for larger Larmor frequencies. For an expected average total coupling between the NV center and external nuclear spins in particles of aₓ∈[0.01 MHz, 0.1 MHz], the frequency sweep velocity may need to be between 0.1-10 MHz/μs.

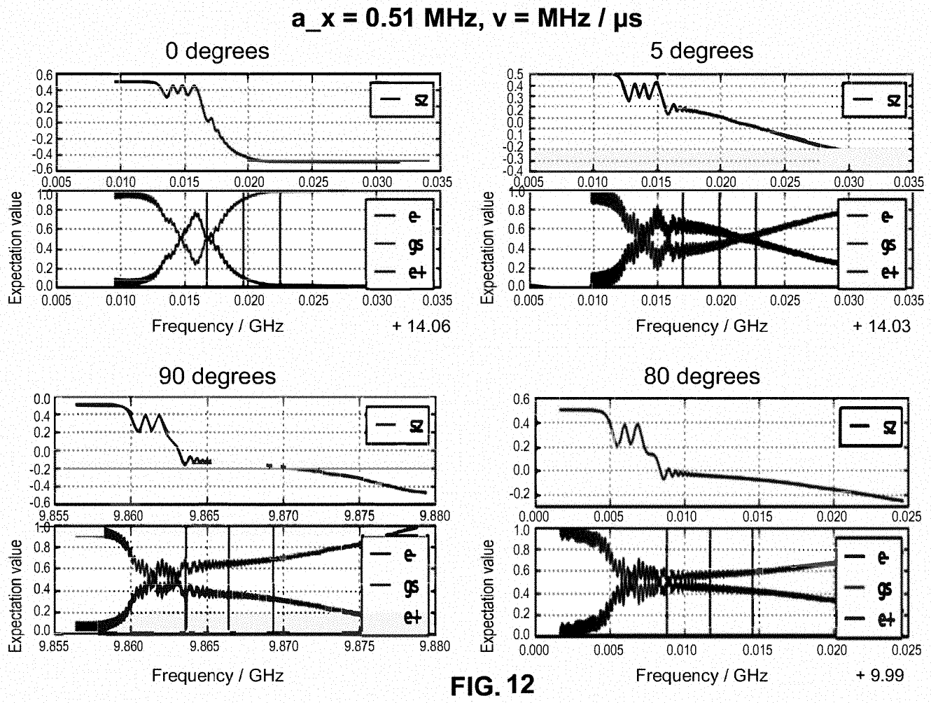

After a single polarization sweep, the NV centers may be repolarized by optical pumping. Polarization transfer may then be enabled by continuous laser optical pumping, by laser 4, combined with microwave frequency sweeps. FIG. 12 illustrates the efficient polarization transfer between an NV center and a nuclear spin for various angles in these two ranges using the integrated solid effect. Thus, for a 10 degree deviation, the polarization step can be performed in 130 microseconds. The solid angle given by the 10 degree deviation for θ=0 is shown in FIG. 11A.

The polarization transfer can be further greatly improved by using a detuned driving scheme. The polarization transfer from a NV center to coupled nuclear spins, aided by a detuned driving scheme has been theoretically analyzed in Chen Q et al, “Optical hyperpolarization of ¹³C nuclear spins in nanodiamond ensembles”, E-print arxiv 1504.02368 (2015); the subject matter of which is incorporated into the present disclosure by way of reference. As noted before, the random orientation of NV center spins in relations to the magnetic field may induce a significant variance of the energy levels, as the direction of the natural quantization axis associated with the crystal-field energy splitting is not controllable. Especially, the random orientations cause a large range of the zero-field splitting

D(θ)∈[−(2π)1.43 GHz,(2π)2.87 GHz)],

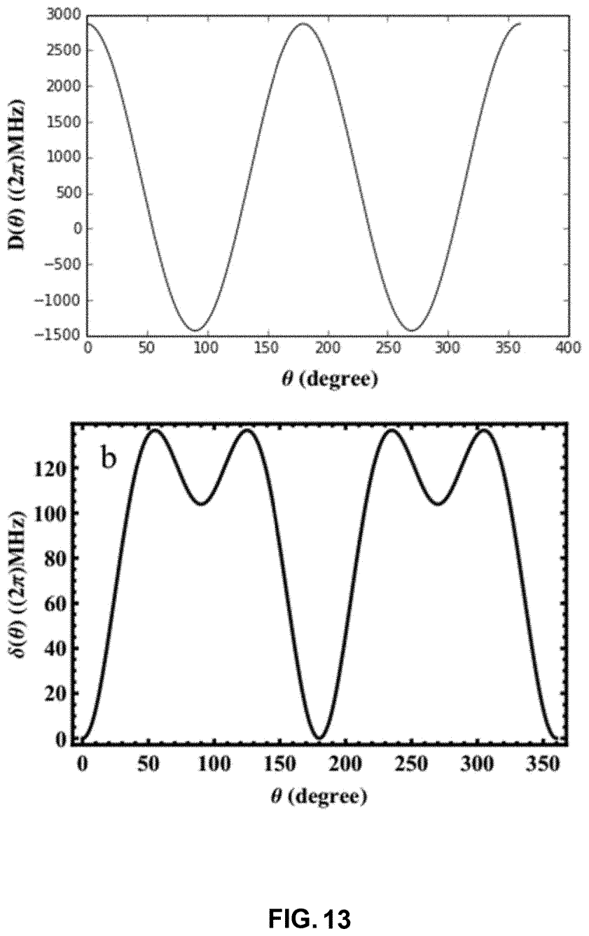

which makes it difficult for polarization transfer. Applying a circularly polarized microwave field, assuming a point-dipole interaction, and neglecting the contact term we obtain

$${H}_{e} ≃ {Ω}_{M} ( {S}_{x} cos {ω}_{M} t + {S}_{y} sin {ω}_{M} t ) + ( {γ}_{e} B + δ ( θ ) ) {S}_{z} + D ( θ ) {S}_{z}^{2} + {γ}_{u} {BI}_{z} - {gS}_{z} [ 3 {e}_{r}^{z} ( {e}_{r}^{x} {I}_{x} + {e}_{r}^{y} {I}_{y} ) + ( 3 {( {e}_{r}^{z} )}^{2} - 1 ) {I}_{z} ] .$$

where Ω_{M}=√2Ω is the Rabi frequency of the driving field and ω_{M} is its frequency, γₑB (γₙB) is the NV center (nuclear) spin coupling to the external magnetic field, and δ(θ) is a correction to the energy levels due to second-order corrections of the misaligned zero field splitting. Consider the off resonant case, ω_{M}=γₑB+δ(θ_{M}), with δ(θ) shown in FIG. 13b, where θ_{M} is the specific chosen angle, the driving is detuned from the |mₛ=−1 [symbol] ↔|mₛ=0 [symbol] and |mₛ=0 [symbol] ↔|mₛ=+1 [symbol] by the misaligned zero-field splitting D(θ). In the interaction picture, we get

$${H}^{″} = Ω ( \vert - 1 〉 〈 0 \vert + \vert 0 〉 〈 + 1 \vert + h . c . ) + D ( θ ) {S}_{z}^{2} + {γ}_{n} {BI}_{{z}^{′}} + {S}_{z} \cdot ( {a}_{{x}^{′}} {I}_{{x}^{′}} + {a}_{{z}^{′}} {I}_{{z}^{′}} ) .$$

Here, a_{z′} and a_{x′} are the elements of the secular and pseudosecular hyperfine interactions, respectively. We proceed with diagonalizing the NV spin Hamiltonian. In the basis {|+1 [symbol] , |0 [symbol] , |−1 [symbol] } for the electron spin, the Hamiltonian is

$${H}_{NV} = ( \begin{matrix}D ( θ ) & Ω & 0 \\ Ω & 0 & Ω \\ 0 & Ω & D ( θ )\end{matrix} ) ,$$

While the eigenvalues and eigenstates of the Hamiltonian can be solved exactly, we will provide here an approximate answer which provides more insight on the detuned driving concept. As D(θ)>>Ω, the eigenstates of this Hamiltonian are approximately

$$\vert \pm 〉 = \frac{1}{\sqrt{2}} ( \vert - 1 〉 \pm \vert + 1 〉 ) ,$$

and |0 [symbol] . The |+ [symbol] , |− [symbol] states have very similar energies, with an energy gap of

$$2 {ω}_{eff} = \frac{{Ω}^{2}}{D ( θ )} ≪ D ( θ ) , Ω .$$

The |0 [symbol] state is far detuned with an energy gap of roughly D(θ) from the {|+ [symbol] , |− [symbol] } states. Let's examine the dependence of 2ω_{eff} on θ.

$$\frac{\partial ( 2 {ω}_{eff} )}{\partial θ} = \frac{2 {ω}_{eff}}{D ( θ )} \frac{\partial D ( θ )}{\partial θ}$$

As D(θ)>>2ω_{eff}, this is a radical decrease in the dependence of the energy gap on the angle from the magnetic field. Thus, when tuning the driving microwave amplitude so that 2ω_{eff}=γₙB, almost all the angle dependence is due to δ(θ) (second order corrections to the energy levels), which adds an S_{z} detuning term to the Hamiltonian. As seen on FIG. 13, δ(θ) changes on the order of tens of MHz when varying the magnetic field, compared with several GHz for D(θ). FIG. 11C illustrates the concept of the detuned driving.

A potential polarization scheme can combine the detuned driving, optimal frequency sweep and the integrated solid effect. Focusing on 10 degrees deviation from the perpendicular crystal axis (90 degree deviation from magnetic field orientation), the polarization scheme may include:

1. Optically polarizing the NV centers to the {|+ [symbol] , |− [symbol] } subspace;

2. Applying a very fast frequency sweep of the |0 [symbol] ↔|− [symbol] transition (can be applied with strong driving amplitude (Sweep duration can be under 1 ρs for Ω>10 MHz. Thus, in the {|+ [symbol] , |− [symbol] } subspace, the NV centers are polarized to the |− [symbol] state);

3. Applying the integrated solid effect protocol with detuned driving for achieving polarization transfer. (The sweep should be performed from γₑB+91 MHz to γₑB+97 MHz.); and

4. Repeating steps 1-3.

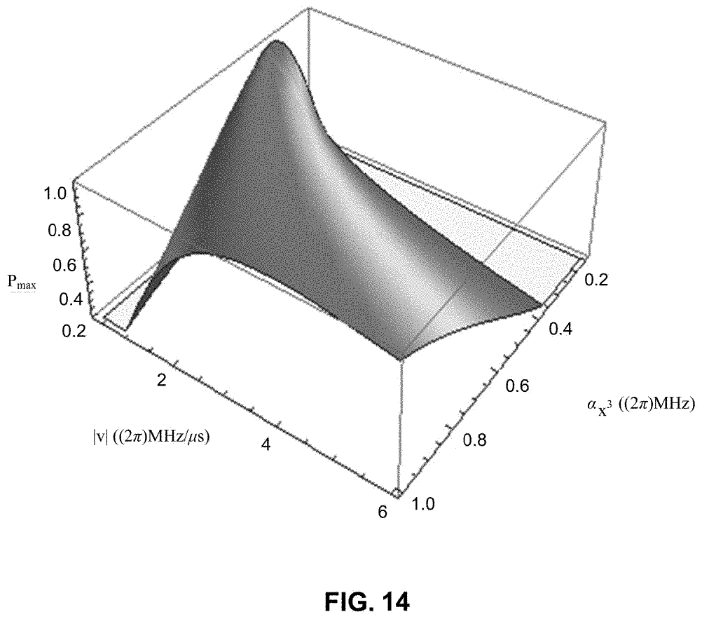

FIG. 14 illustrates the dependence of the polarization transfer based on the sweep velocity and total coupling to the NV center spin. The effect of molecular motion on a detuned driving scheme for achieving the Hartmann-Hahn resonance may be nearly identical to that seen for the NOVEL sequence above.

In accordance with another embodiment of the present disclosure, a method for hyperpolarizing ¹³C nuclear spin in a diamond and producing an imaging agent may be provided. Methods for the hyperpolarization of ¹³C nuclear spin in a diamond are known in the art. In “Optical polarization of nuclear ensembles in diamond”, arXiv:1202.1072v3 [quant-ph], R. Fischer et al. report the polarization of a dense nuclear spin ensemble in diamond. Their method is based on the transfer of electron spin polarization of negatively charged nitrogen vacancy color centers to the nuclear spins via the excited-state level anti-crossing of the center. Fischer et al. have adapted the method to polarize single nuclear spins in diamond based on optical pumping of a single nitrogen vacancy center defect, which had already been described by V. Jacques et al. in “Dynamic Polarization of Single Nuclear Spins by Optical Pumping of Nitrogen-Vacancy Color Centers in Diamond at Room Temperature”, Phys. Rev. Lett., volume 102, issue 5, pages 057403-1 to 057403-4. Both Fischer et al. and Jacques et al. use short-lived states of the color center spins, which are not suitable for directly polarising via long-range interactions nuclear spins far away from the color center.

In “Sensitive magnetic control of ensemble nuclear spin hyperpolarization in diamond”, Nature communication 4 (2013) Hai-Jing Wang et al. show polarization of nuclear spins in contact interaction with a nitrogen vacancy color center in a diamond using the ground state level anti-crossing of the center. While the color center state is long-lived, the experiment demonstrates polarization of nuclear spins only via then short range contact interaction, which does not diffuse to nuclei further away. Moreover, for the specific polarization method described in the text, the T₂ time of the color centers in the diamond used correspond to a very short coherence time and is too short for polarising nuclear spins via long ranged interactions.

Eduard C. Reynhardt et al. describe the polarization of ¹³C nuclei by means of nuclear orientation via electron spin-locking (Hartmann-Hahn cross-polarization between paramagnetic electrons and ¹³C nuclei) in a suite of natural diamonds in “Dynamic nuclear polarization of diamond. II. Nuclear orientation via electron spin-locking”, J. Chem. Phys. volume 109, number 10, pages 4100 to 4106. Reynhardt et al., however, do not exploit the electron spin of nitrogen vacancy centers and are thus not able to use optical polarization of the electron spin.

In magnetic resonance applications, it may be desirable to reach a higher degree of polarization of ¹³C nuclei throughout a diamond than has hitherto been accomplished. Therefore, there is a need for an improved method for the hyperpolarization of nuclear spin in a diamond, to supply a diamond with hyperpolarized ¹³C nuclei and create a use for such a diamond. In addition to this, an improved method for the nuclear spin hyperpolarization of ¹³C in a molecule and an improved method for the production of an imaging agent is sought.

Therefore, the embodiments of the present disclosure further provide a method for the hyperpolarization of ¹³C nuclear spin in a diamond, which comprises an optical pumping step and a transfer step. In the optical pumping step, color center electron spins in the diamond are optically pumped. In the transfer step, the polarization of a long-lived state of the color center electron spins is transferred to ¹³C nuclear spins in the diamond via a long-range interaction. A long-range interaction may be defined as an interaction which decays according to a power law with the distance of the ¹³C nuclear spins from the color center. Examples include, but are not limited to, a coherent dipolar interaction, which decays as the distance cubed, and the case of the incoherent dipolar interaction, which decays as the distance to the power of six. A long-lived color center spin state may be defined as a state in which the coupling strength of the color center spin and nuclear spins is larger than the decay rate of the color center spin state for nuclear spins at least about 0.5 nm distanced from the color center spin.

Furthermore, the embodiments of the present disclosure provide a method for the nuclear spin hyperpolarization of ¹³C nuclear spins in a molecule, wherein the molecule is brought near or into contact with a diamond and prior to, during or after that, the diamond is hyperpolarized. In this context, “near” may mean that the diamond and the molecule are close enough to each other to allow propagation of a nuclear spin's polarization from a ¹³C nucleus of the diamond to a nucleus of the molecule.

Moreover, embodiments of the present disclosure provide a method for the production of an imaging agent, wherein a diamond is coupled to a molecule and prior to or after the coupling, the diamond is hyperpolarized. A hyperpolarized diamond may be used in medical or cell based imaging, in a quantum information processor or a quantum sensor based on spin degrees of freedom. Moreover, a diamond with a volume of above about 1 nm³, in some embodiments of above about 1 μm³, in which diamond the ¹³C nuclear spins in the entire diamond are hyperpolarized to at least 0.001% polarization may be provided. In the present disclosure, polarization may be defined as the number of ¹³C nuclear spins in the preferred direction minus the number in the opposite direction, divided by the total number of ¹³C nuclear spins. In addition, point defects in a diamond lattice, in which a vacancy is filled by one or more electrons, may comprise color centers. The electron spins at a suitable color center can be polarized by optical pumping. Optically polarized color center electron spins can be transferred to surrounding ¹³C nuclear spins to create nuclear polarization.

A diamond, according to the embodiments of the present disclosure, can be a synthetic diamond or a naturally occurring diamond. The diamond may comprise at least one color center. Synthetic diamonds may be produced, for example, by chemical vapour deposition (CVD), using detonation or milling of large scale, high pressure, high temperature crystals. High ¹³C nuclear spin polarization densities can be achieved in diamond as the nuclear density of diamond is higher than in most other available materials. In CVD, advantageously, diamonds enriched for ¹³C can be produced such that an even higher ¹³C nuclear spin polarization density is achievable.

An imaging agent can be produced by coupling the diamond to a molecule and prior to, during, or after the coupling, hyperpolarizing the diamond. In some embodiments, the molecule may be a biological molecule, such as a protein, and/or a molecule with a high affinity to a biological molecule, such as a drug. In some embodiments, such imaging agents can bind to specific structures in individual cells or to defined sites in the body of an animal or human. The specific structures of defined sites can then be located by locating the hyperpolarized diamond using MRI. Advantageously, the imaging agent can aid the detection and tracking of specific structures in vivo.

The hyperpolarized diamond according to the present disclosure can be used in medical or cell based imaging. Even though diamond is a chemically inert material, biological molecules can be linked to the surface of diamonds. In particular, it has been demonstrated in “Dynamics of Diamond Nanoparticles in Solution and Cells”, Felix Neugart et al., Nano Letters, 2007, volume 7, issue 12, pages 3588 to 3591 (the subject matter of which is incorporated into the present disclosure by way of reference) that diamond nanoparticles can be conjugated with biotin, to which streptavidin is able to bind. As many streptavidin-linked biological molecules, in particular proteins, are already commercially available, biotinylated diamond nanoparticles can easily be conjugated to bind specifically to a variety of proteins and cells. As cryogenic temperatures can be avoided, the loss in polarization during the transfer of the hyperpolarized diamond from the site of polarization to the MRI scanner can be reduced. Due to the high density of ¹³C nuclei, a much higher signal density can be achieved in diamond than in other hyperpolarized materials.

A hyperpolarized diamond can be used in a quantum information processor or a quantum sensor based on spin degrees of freedom. Polarization of nuclear spin environments may reduce the noise that the nuclear environment exerts on the electronic spin degree of freedom. Thus, the embodiments of the present disclosure may improve the coherence times of quantum information processors and quantum sensors based on spin degrees of freedom.

The volume of the diamond may be greater than about 1 nm³, greater than about 10 nm³, greater than about 1000 nm³, greater than about 1 μm³, greater than about 10 μm, or greater than about 1000 μm³. In some embodiments, the diamond may have a volume of less than about 1000 nm³, or less than about 100 nm³. In principle, a diamond with an arbitrary size can be polarized as long as the concentration of the color centers is high enough. Advantageously, the embodiments of the present disclosure may operate at any magnetic field. The methods described in the prior art work only for a particular magnetic field, namely at the level anti-crossing of the NV center's spin levels.

The use of the dipolar long-range interactions between the color center and ¹³C nuclear spins can greatly increase the speed of the polarization process, as a much larger number of nuclear spins can be polarized directly by the color center spin, and the final bulk polarization achieved. Accordingly, the embodiments of the present disclosure may provide a method of hyperpolarizing nuclear spins in a diamond faster and/or to attaining higher overall polarization.

It may also be possible to produce diamond nanoparticles that are hyperpolarized through their entire volume. Such hyperpolarized diamond nanoparticles can lead to large signal to noise ratios in NMR and MRI and can thus increase resolutions, lower the detection threshold and permit faster and dynamic scans. Cells and processes in the body can be imaged with the aid of hyperpolarized diamonds attached to proteins. Advantageously, the method according to the embodiments of the present disclosure can be performed at room temperature; cryogenic temperatures may no longer be needed. Furthermore, the method may only require a relatively low magnetic field, which may enable the hyperpolarized diamonds to be produced inexpensively, on a large scale and in a relatively simple setup. Such simple setups can be incorporated into a hospital environment more easily, which may lead to a reduction in implementation costs. Additionally, the very long relaxation time of ¹³C nuclear spins in diamond nanoparticles can allow for a long period of time to pass between the polarization process and the imaging. The duration of this period of time may be greater than about 1 minute, greater than about 10 minutes, or greater than about 30 minutes. Thus, the polarization process can be performed in a different location from the imaging, potentially even in a central location for a few hospitals, and can be used for imaging processes in the body with a longer timescale.

Examples of long-lived color center spin states may include the ground state of an NV center spin in a diamond. The diamond may be of high purity, for example, at most about 200 ppm nitrogen nuclei (also referred to as “P1 centers”), or less than about 5 ppm nitrogen nuclei. In some embodiments, the method may be practiced at a low temperature, for example, at liquid nitrogen temperature (about 77 K).

In some embodiments, the polarization of a long-lived excited triplet state, for example in an oxygen-vacancy (2.818 eV), may be transferred to the ¹³C nuclear spins. In some embodiments, the long-lived color center spin state may be a state in which the coupling strength of the color center spin and nuclear spins is larger than the decay rate of the color center spin state for nuclear spins at least 3 nm, or 5 nm distanced from the color center spin. With such very long-lived color center spin states, a high hyperpolarization can be achieved particularly fast.

In some embodiments, an external microwave field or radio frequency (RF) field may be applied. The external microwave field or radio frequency (RF) field may be continuous or pulsed. The application of the microwave field may tune the coupling between the color center electron spins and the surrounding ¹³C nuclear spins. In addition, the microwave field may narrow the line width of the electron and thus make the transfer of the polarization of the electron spins to the nuclear spins more efficient. By applying the microwave field in this manner, the ¹³C nuclei close to the color center may be completely polarized. Moreover, the spin polarization transfer from the color centers to the ¹³C nuclear spins can be accelerated. Many DNP protocols as discussed below involve the application of an external microwave field or a radio frequency (RF)

### FIELD

According to some embodiments, the long range interaction may be achieved by using dipolar interaction between the color center electron spin and the ¹³C nuclear spins. According to some embodiments, the polarization may be transferred by a standard dynamic nuclear polarization (DNP) protocol for using dipolar interactions to transfer electron polarization to surrounding nuclear spins. DNP protocols may be defined as protocols for transferring the polarization from an electron spin is to the ¹³C nuclei by microwave or RF irradiation of the sample. Advantageously, by means of a DNP the transfer of the polarization from the electron spins to the surrounding nuclear spins can be accelerated. Examples for suitable DNP protocols may include the solid effect, the cross effect, thermal mixing, and pulsed DNP methods such as the NOVEL sequence or dressed-state solid effect. A review of many current DNP protocols can be found in Maly, Thorsten, et al. “Dynamic nuclear polarization at high magnetic fields.” J Chem Phys. 2008; 128(5): 052211 (see section II. “Polarizing mechanisms in DNP experiments”). Most DNP protocols involve either interactions between electron spins or are based on two underlying physical mechanisms: fulfilling the Hartmann-Hahn condition and excitation of selective transitions (i.e. irradiation at a frequency matching the energy gap between two quantum states). The DNP protocols may differ in the configurations for achieving these conditions and by the usage of microwave pulses or continuous microwave radiation.

In some embodiments, the DNP protocols can be used for fulfilling the Hartmann-Hahn condition between the color center spin and the ¹³C nuclear spins or for excitation of selective transitions caused by the dipolar interaction of ¹³C nuclear spin states with the color center spin. The general concept of Hartmann-Hahn double resonance as described in Hartmann, S. R. and Hahn, E. L., “Nuclear Double Resonance in the Rotating Frame”, Physical Review, 1962, vol. 128, Issue 5, pp. 2042-2053, the subject matter of which is incorporated into the present disclosure by way of reference. According to some DNP protocols, the Hartmann-Hahn condition may be achieved. This condition may require that the Rabi frequency of the electron spin be equal to the Larmor frequency of the ¹³C nuclear spins in some reference frame (both the Rabi frequency and Larmor frequency can be between dressed or bare eigenstates). In this case, mutual spin flip-flops may be allowed and the high electron spin polarization can be transferred to the nuclear spins. Thus, transferring of the polarization of the color center electron spins to the ¹³C nuclear spins can be achieved. In some embodiments, the DNP method termed NOVEL may be used to transfer spins from the color center electrons to the ¹³C nuclei. In NOVEL, a pi/2 rotation may be carried out, followed by spin locking for an adequate time for the transfer of the color center electron spin to the ¹³C nuclear spin to occur. After the Hartmann-Hahn condition has been achieved, it may also be possible to simply wait for a spin flip-flop between the electron and the nuclear spin to occur, instead of spin locking, which can also lead to the polarization transfer from the color center electrons to the surrounding ¹³C nuclei. In some embodiments, the Hartmann-Hahn condition may be achieved by a microwave field or a radio frequency field, the intensity of the field which may be chosen to match the energy difference between dressed color center electron spin eigenstates and the ¹³C nuclear spins in an external magnetic field.

In other embodiments, the Hartmann-Hahn condition between NV-center electron spin and external nuclear spins can also be achieved by means of optical Raman fields at low temperatures, such as below 10 K, which may couple the electronic spin states via an optically excited state obtained by tuning a magnetic field to an excited state anti-crossing to enable individual addressing. For other solid state based systems such as chromium in ruby, the use of optical Raman fields may be possible at room temperature.

The magnetic flux density of the external magnetic field may be smaller than about 3 T. In some embodiments, external magnetic fields with a low magnetic flux density may be used, such as magnetic field below about 2 T, below about 1 T, or below about 0.5 T. Advantageously, these magnetic flux densities can be achieved by a permanent magnet or an electromagnet, which does not rely on liquid cooling.

Another method for using the long-ranged interaction may involve excitation of selective transitions caused by the dipolar interaction of ¹³C nuclear spin states with the color center spin. Focusing on a two particle system of the color center spin and a ¹³C nuclear spin, the dipolar interaction may cause a shift in the energy level of the combined two-spin quantum system. This shift may induce different energy gaps between the two spin system states, meaning that each transition between states has a unique energy gap. This may allow for external excitation of only one selected transition using pulses or continuous waves in a specific frequency tuned to the energy gap of that particular transition. Excitation of the transition between the state where the color center spin is polarized and the ¹³C nuclear spin is not polarized to the opposite state (polarized ¹³C nuclear spin, non-polarized color center spin) may induce a polarization transfer, used in the solid effect DNP protocol.

In some embodiments, the transfer step may be performed by interaction involving at least two color center spins and a nuclear spin. This mechanism (used in the cross effect and thermal mixing DNP protocols) may be based on allowed transitions of several electron spins and a nuclear spin involving a homogeneously or inhomogeneously broadened EPR line. The broadening of the EPR lines may allow a simultaneous flip of two or more electron spins and a nuclear spin to be energy conserving and may enable transfer of the electron spins' polarization to the nuclear spins with the correct microwave irradiation. The color centers in diamond used may achieve a much higher electron spin polarization compared with the nitrogen spins used in previous studies.

In some embodiments, the diamond's ¹³C nuclear spin polarization may be far above thermal equilibrium conditions. In some embodiments, the diamond's ¹³C nuclear spin polarization may be above thermal equilibrium conditions by a factor of at least 10³, at least 10⁴, or at least 10⁵. Due to such hyperpolarization, such diamonds can easily be detected in nuclear magnetic resonance (NMR) and magnetic resonance imaging (MRI), particularly in comparison to prior art methods in which only nuclear spins in ¹³C nuclei very close to the color center can be polarized, leading to a considerably lower polarization of the diamond as a whole.

In some embodiments, the ¹³C nuclear spin polarization in the diamond may be greater than about 1%. For example, a nano-diamond with 100 ¹³C spins with 51 in the preferred direction and 49 in the opposite direction may have a polarization of about 2%. In some embodiments, the ¹³C nuclear spin polarization may be greater than about 10%, greater than about 20%, greater than about 30%, greater than about 50%, or greater than about 70%.

In some embodiments, the color center, in which the electron spins are optically pumped, may be a nitrogen vacancy (NV) center. One common color center in diamond is known as an NV center, in which a nitrogen atom substitutes a carbon atom leading to a vacancy in the lattice. An NV center may be especially suited for the optical pumping of its electron spins. However, atom substitutes other than nitrogen are also possible for forming a color center, such as, for example, silicon.

In some embodiments, the optical pumping step and the transfer step may be repeated cyclically. After the optical pumping of the NV center electrons, the electron spins can be transferred to the surrounding ¹³C nuclei. By repeating the optical pumping step and the transfer step, it may be possible to polarize most, if not all ¹³C nuclear spins in close proximity to the NV center. In some embodiments, a pause after each cycle may allow for the ¹³C nuclear spin polarization to spread from ¹³C atoms adjacent to the NV center throughout the diamond. The propagation of the ¹³C nuclear spins may occur spontaneously. In other embodiments, no application of alternating electromagnetic fields may be required during the diffusion of nuclear spin from ¹³C nuclei close to the NV center to ¹³C nuclei further away. By cyclically repeating the optical pumping step, transfer step and pause, the polarization of more than about 10%, more than about 50%, more than about 80%, more than about 90%, more than about 95%, or about 100% of the ¹³C nuclei within the diamond may be achieved.

In some embodiments, the method may be carried out for less than about 10 minutes, less than about 5 minutes, less than about 1 minute, or less than about 10 seconds to achieve hyperpolarization in the entire diamond. In some embodiments, the diamond may have a volume of at least about 1 nm³, at least about 10 nm³, at least about 1000 nm³, at least about 1 μm³, at least about 10 μm, or at least about 1000 μm³. Accordingly, hyperpolarization can be achieved rapidly, even in a large diamond. Small diamonds can easily be adapted to medical purposes, for example, as medical imaging agents for MRI. Furthermore, nanoscale diamonds can be taken up into cells by endocytosis, which permits cell based imaging.

In some embodiments, the optical pumping may be performed with at least one laser pulse. A laser is the preferred light source for carrying out the electron spin polarization of the color centers. Using a laser, the optical pumping can be achieved efficiently.

In yet another embodiment, the method may be carried out at a temperature greater than about 10 K, greater than about 80 K, greater than about 200 K, greater than about 273 K, or greater than about 288 K. In some embodiments, cryogenic temperatures may not be needed to polarize a diamond. After transfer of the electron spin to the ¹³C nuclear spin, the color center electron spins can be polarized again by optical pumping. In this way, the color center electron spin can preferably serve as a near-zero temperature electron bath, allowing the bulk diamond to be kept at a higher temperature, such as room temperature.

The diamond may be a synthetic diamond. Synthetic diamonds can be enriched for ¹³C to allow for even larger polarizations to be created. Furthermore, synthetic diamond material can be synthesised inexpensively in a variety of shapes and sizes, including the deposition of diamond on the surface of other materials, for example, by CVD. At least 1% of the carbon atoms in the diamond may be ¹³C. In other embodiments, the diamond may be enriched for a ¹³C isotope concentration between about 5% and about 20% or between about 10% and about 15%, even though much higher concentrations of ¹³C isotopes are possible.

In one embodiment, the diamond may be coated with a non-diamond material. The coating can take place before or after the hyperpolarization. A coating may yield a higher biocompatibility of the diamond when injected into the bloodstream. In a method for the nuclear spin hyperpolarization of nuclear spins in a molecule, the molecule may be brought near or into contact with a diamond comprising one or more color center(s). The nuclear spins of the molecule can then be polarized. In a method of polarising the nuclear spins in a molecule, the ¹³C nuclear polarization may be allowed to propagate from the diamond to the molecule. As such, the molecule may be attached to the diamond or covalently attached to the diamond. The diamond's ¹³C nuclear spin may be hyperpolarized with the molecule already near or in contact with the diamond, the molecule may be put near or in contact with the diamond ¹³C nuclear spin already hyperpolarized, and/or the diamond and the molecule may be brought near or in contact during hyperpolarization of the diamond's ¹³C nuclear spin. The spin diffusion may be made possible by the dipolar coupling between the ¹³C nuclear spins in the diamond and the non-zero nuclear spins in the molecule. In some embodiments, for the propagation of the nuclear spin polarization from the diamond's ¹³C nuclei to the molecule's nuclei to be efficient, the diamond and the molecule may be closer than 1 nm to each other. Possibly, the molecules can then be separated from the diamond. In some embodiments, after transfer of polarization to the molecule, the molecule can be scanned in an NMR or MRI scanner. In this way, even small amounts of the molecule can be detected.

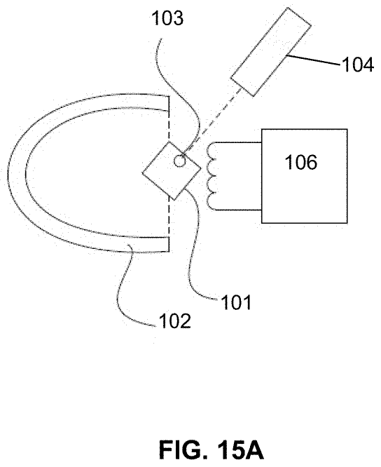

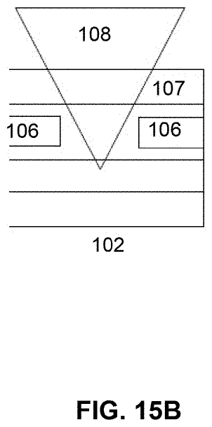

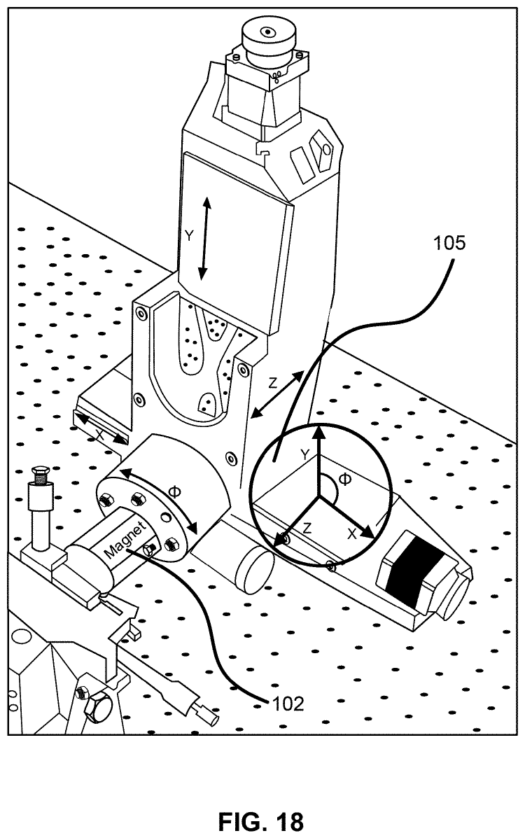

FIG. 15A illustrates the details of an exemplary experimental setup with a diamond 101 placed in the magnetic field of a permanent magnet 102. The diamond 101 may contain a color center 103, such as an NV center. A laser 104 may be configured to excite an electron of the color center 103. In order to move the diamond 101 into the focus of the laser 104, the diamond 101 may be mounted on a piezo stage (not shown). The magnet 102 may be mounted on rotation/translation stages 105 (for example, as illustrated in FIG. 18) to be able to align the magnetic field with the crystallographic axis of the color center 103. A microwave source 106 may be configured to facilitate polarization transfer from electron to ¹³C nucleus. As seen in FIG. 15B, the diamond 101 may be placed between the permanent magnet 102 and the microwave source 106, which may allow for the Hartmann-Hahn double resonance to be generated in the diamond 101. The optical path 108 of the laser 104 may be directed through a glass coverslip 107 and focussed into the diamond 101 in order to polarize the electrons in an NV center.

The following experiments were performed in a synthetic diamond layer formed by CVD doped with NV centers during growth. The sample used in these experiments possesses two layers with different properties, the substrate and a CVD grown layer. The substrate is a type IIa diamond 101 with a (111) cut and a natural abundance of ¹³C. The CVD grown layer is also a (111) cut with a natural abundance of ¹³C and a 1 ppm concentration of phosphorus donors. The donors were added to stabilise the charge state of the NV center. For some of the dynamic nuclear polarization protocols, a different donor concentration may be used.

For the direct polarization of external spins via NV centers, ultra-small nanodiamonds, such as diamonds with volume between 1 nm³ and 1000 nm³, may be used. Polarization transfer may be enabled by dipolar interactions between NV center spins and external nuclear spins. In addition, it may be possible to use other electron spins as mediators for spin polarization. Additionally or alternatively, nitrogen (P1 center) present in 100 ppm or higher concentration in synthetic high pressure high temperature diamond can be used for this purpose.

Single NV centers were detected using a confocal microscopy technique. A laser beam diode pumped solid state laser 104 operating at 532 nm was focussed onto a diffraction limited spot using a high numerical aperture microscope objective. The sample was scanned using a piezo driven stage. Fluorescence was collected by the same microscope objective and focussed on avalanche photodiodes with single photon sensitivity. By observation of photon-antibunching, it could be detected that an individual NV center was in focus. Fluorescence detection of magnetic resonance on single electron spin is based on optical contrast of spin states associated with NV centers.

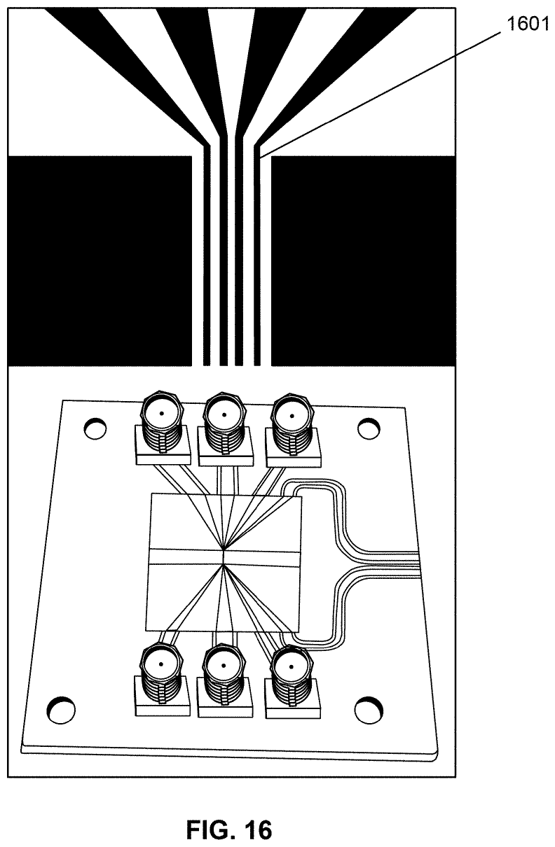

In order to excite microwave transitions of single color centers 103 in diamond 101, the sample was placed on a home built microwave strip line providing efficient excitation of the diamond 101. FIG. 16 illustrates an exemplary optical microscopic picture of the structure, which was fabricated on a glass cover slip by conventional photolithography and was used in the magnetic resonance experiments.

The width and gap of each microstrip 1601 is 20 μm. FIG. 16 also illustrates the holder with the strip line structure. The signal is applied via coaxial cables connected to SMA connectors and matched to the two coplanar microstrips.

A microwave source 106 was used in the experiments. In order to achieve Rabi frequencies of a few MHz, the source was amplified using a high power microwave amplifier. Phase control of microwave fields was achieved using phase shifters. Microwave pulses were formed using microwave switches. The strength of the microwave drive was controlled by the output level of the microwave source 106.

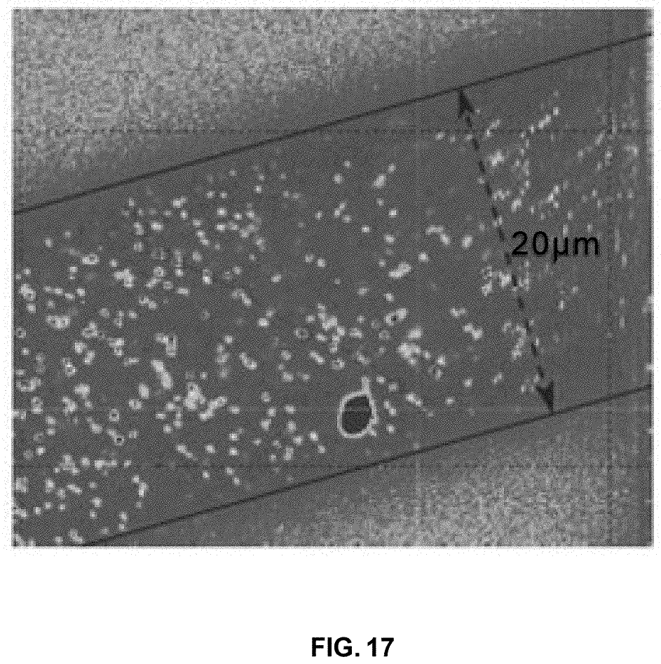

FIG. 17 illustrates a fluorescence image of a diamond 101 sample on top of the 4-strip microstructure. On the top and the bottom of the image, one strip is displayed each. Between the strips, the diamond area can be seen. Bright spots correspond to the fluorescence emissions of NV centers. Experiments were performed in a magnetic field on the order of 0.4 T generated by a permanent magnet 102 located about 100 μm from the diamond face. In order to align the magnetic field with the crystallographic axis (z-axis) of the NV defect, the magnet 102 was moved using rotation and translation stages 105, as shown in FIG. 18. For ensemble experiments aiming to polarize large samples, the magnetic field may need to be homogeneous enough to fulfil resonance conditions for the whole sample. Permanent magnet arrangements or electromagnets can be used for this purpose.

Optical pulses for optical spin polarization and time resolved detection of magnetic resonance were produced using acousto-optical modulators. Microwave, optical pulses, sample scanning and data acquisition were synchronised by a computer controlled pulse generator connected to drivers of acousto-optical modulators, microwave switches and a fast photon counter. The optical detection of magnetic resonance was carried out in accordance with the scientific publications Jelezko, F. et al., “Single defect centers in diamond: A review.” Physica Status Solidi (a) Applications and Materials Science, 2006. 203(13): pages 3207 to 3225, Jelezko, F. et al., “Read-out of single spins by optical spectroscopy.”, Journal of Physics-Condensed Matter, 2004. 16(30): pages R1089 to R1104 and Jelezko, F., et al., “Observation of coherent oscillations in a single electron spin”, Physical Review Letters, 2004. 92(7), the subject matter of which is incorporated into the present disclosure by way of reference.

Electron spins associated with NV centers were polarized by the application of a short (300 ns) laser pulses from laser 104. Optical pumping was achieved by excitation of the NV center into an excited electronic state. The decay of this state occurs predominantly into one of the spin sublevels of the ground state.

Exchange of polarization between optically pumped electron spin of NV center and nuclear spins can be performed using several established dynamic nuclear polarization protocols, including, but not limited to, the solid effect, the cross effect, thermal mixing, and the NOVEL sequence. Most of these protocols may either involve interactions between electron spins or may be based on two underlying physical mechanisms: fulfilling the Hartmann-Hahn condition and excitation of selective transitions. The DNP protocols differ in the configurations for achieving these conditions and by the usage of pulses or continuous waves.

For the above DNP protocols, the experimental setup is similar, with the difference in the microwave frequency, pulse sequence and/or magnetic field strength. The solid effect (excitation of forbidden transition involving double, electron nuclear spin flips using microwave driving) followed by electron spin relaxation is known to induce efficient polarization transfer. Notably, the weak electron spin relaxation process can be significantly enhanced by optical pumping of NV center.

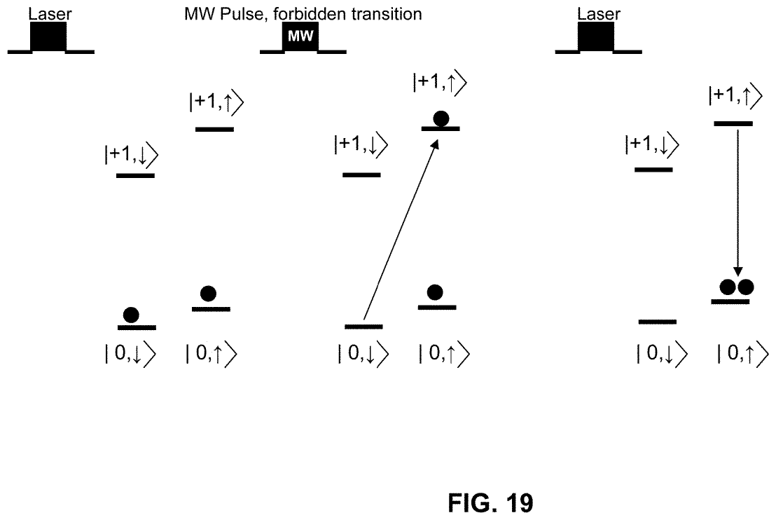

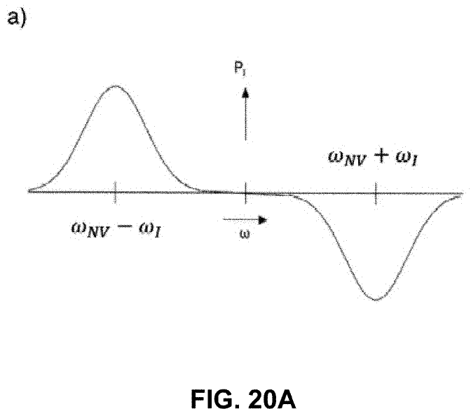

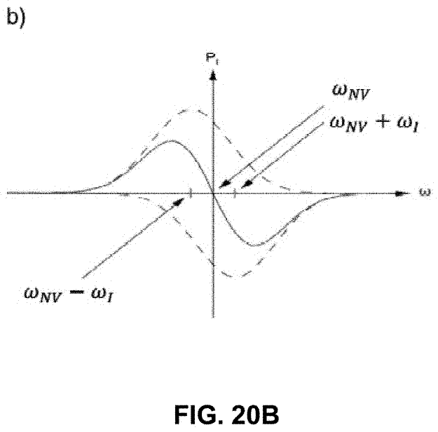

A rigorous theoretical treatment of the solid effect has been performed in numerous papers, e.g. Abragam A, Goldman M. Rep Prog Phys 1978; 41:395, W. T. Wenckebach Applied Magnetic Resonance 2008, 34, 227-235. A graphical representation of the polarization transfer protocol using the solid state effect is shown in FIG. 19. As seen in FIG. 19, at the first stage, the laser may polarize the NV center by optical pumping. Next, via the forbidden transition, a microwave excitation may excite simultaneously the NV spin and the nuclear spin which may result in nuclear polarization. The NV spin may then be re-polarized via optical pumping. The rate of polarization transfer may be maximal for microwave frequencies corresponding to the energy levels of the forbidden transitions ω₊≈ω_{NV}−ω_{I} for positive nuclear polarization and ω_≈ω_{NV}+ω_{I} for negative nuclear polarization, where ω₀ₛ denotes the NV spin Rabi frequency and ω_{I} the nuclear spin Larmor frequency in the lab frame. As the polarization rate is a function of the NV center spin ESR line shape, effective polarization transfer may be achieved when the ESR line is narrow compared with the nuclear spins Larmor frequency (or the longitudinal hyperfine component of the interaction with the NV center spin). The difference in nuclear polarization build-up depending in the ESR line width compared to the Larmor frequency is illustrated in FIGS. 20A-20B. FIG. 20A illustrates the nuclear polarization as a function of the microwave frequency for the case where the nuclear Larmor frequency (ω_{I}) is larger than the NV center ESR line, which is known as the “well resolved solid effect”. FIG. 20B illustrates the nuclear polarization for the case where the ESR line is not narrow compared to the nuclear Larmor frequency, which is known as the “differential solid effect”. In this case, the effects for positive nuclear polarization and negative nuclear polarization—depicted in dashed lines—overlap, thereby reducing the overall polarization reached (solid line).

Larmor frequencies of ¹³C nuclear spins were approximately 5 MHz for magnetic fields used in our experiments, though stronger magnetic fields can be used for larger Larmor frequencies. For narrow NV center ESR lines, diamonds with a small concentration of P1 (Nitrogen) donors (less than 10 ppm) may be used. For instance, CVD grown diamonds with 10 ppm P1 donor may result in NV center ESR line width which is only limited by ¹³C, thus enabling efficient polarization. Polarization transfer may then be enabled by continuous laser 104 optical pumping combined by resonant microwave 6 irradiation.

In other embodiments, cross polarization effect may be used to transfer the NV center spin polarization to the nuclear spins, which involves two electron spins and one nuclear spin. The cross polarization effect may be particularly interesting for samples having high concentration of NV centers with strongly dipolar coupled electron spins. The basis for the cross effect are two dipolar coupled electron spins under the condition that the resonance frequency the electrons is separated by the nuclear Larmor frequency. Thus, the cross-effect can only occur if the inhomogeneously broadened ESR line shape has a linewidth broader than the nuclear Larmor frequency, contrary to the condition for effective polarization via the solid effect. An additional condition for the cross effect is that the homogeneously broadened ESR linewidth is narrower than the nuclear Larmor frequency.

The cross effect was first discovered in the 1960s by Kessenikh et al. In Kessenikh et al. Phys Solid State 1963; 5:321, and later by Wollan D S. Phys Rev B 1976; 13:3671. In the last few years, it has again aroused interest after experiments which have shown a large DNP enhancement to the NMR signal in high magnetic fields (e.g. Hall et al. Science 1997; 276:930, Song et al. J Am Chem Soc 2006; 128:11385). The cross effect is based on a three spin interaction (two electron spins and a nuclear spin) satisfying the relation:

ωₛ₂−ωₛ₁=ω_{I}, (1)

with ωₛ₁₍₂₎ denoting the EPR frequency of electron 1(2) and ω_{I} denoting again the Larmor frequency of the nuclear spin.

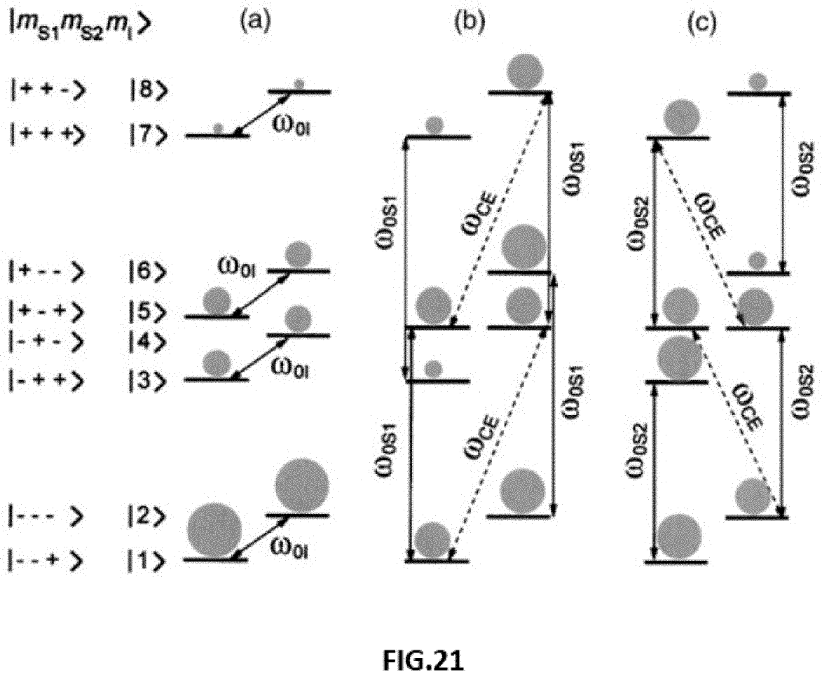

For driving the polarization transfer, a microwave irradiation may be added of frequency ωₛ₁₍₂₎, leading to a negative(positive) nuclear polarization. FIG. 21 illustrates an exemplary polarization process. In section a, FIG. 21 illustrates the population distribution at thermal equilibrium for a general three spin system (two electron spins and a nuclear spin) in an external magnetic field. In sections b and c, FIG. 21 illustrates the energy level have been set such that condition 1 above is met. In section b, FIG. 21 illustrates the new population distribution under microwave irradiation of frequency ωₛ₁, which may lead to a saturation of the allowed EPR transitions. As can be seen in FIG. 21, this may correspond to negative nuclear polarization. Microwave irradiation of frequency ωₛ₂ may lead to positive nuclear polarization (for example, as seen in section c of FIG. 21).

For a typical diamond with 100 ppm P1 donors, the homogeneus broadening could be −100 KHz, and the inhomogeneus broadening may typically be in the MHz range, but can be made larger by growing the diamond with intrinsic strain along some axis, or by increasing the ¹³C concentration in the diamond. Additionally or alternatively, the P1 donors' electron spin can be used as a pair for the dipolar coupling in the cross effect with the NV center spins.

Another proposed experimental realization of a DNP protocol for the polarization transfer may be achieved by establishing a Hartmann-Hahn condition between the electron and nuclear spin. This may be achieved by driving the electron spin transitions between mₛ=0 and mₛ=−1 state by means of a microwave field whose intensity may be chosen to match the energy difference between dressed electronic spin eigenstates and the nuclear spins in an external magnetic field.

The dynamics of the NV electronic spin and an additional nuclear spin, in the presence of a continuous driving microwave field have been theoretically analyzed in Cai, J. M. et al., “Diamond based single molecule magnetic resonance spectroscopy”, New Journal of Physics, 2013, 15, 013020, http://arxiv.org/abs/arXiv: 1112.5502 and the article's supplementary information; the subject matter of which is incorporated into the present disclosure by way of reference. The Hamiltonian describing the NV center electronic mₛ=0, −1 states and an additional ¹³C nuclear spin, in the presence of an external magnetic field B and a resonant microwave field is

H=Ωσ_{z}⊗1+γ_{N}1⊗|B_{eff}|σ_{z}+γ_{N}A_{hyp}σₓ⊗(sin θσₓ+cos θσ_{z}) (5)

where Ω is the Rabi frequency of the driving field and a are the spin-½ operators, defined in the microwave-dressed basis

$$\vert \pm 〉 = \frac{1}{\sqrt{2}} ( \vert 0 〉 \pm \vert + 1 〉 )$$

for the electronic basis, and in the (|↑_{z′} [symbol] , |↓_{z′} [symbol] basis for the nuclear spins, where z′ is defined along the direction of B_{eff}. B_{eff} is an effective magnetic field and is given by B_{eff}=B−(½) A_{hyp}, where A_{hyp} is the hyperfine vector which characterises the coupling between the two spins. In equation (5), γ_{N} is the gyromagnetic ratio of the nuclear spin and cos θ=ĥ·\hat{b}, where ĥ and \hat{b} are the directions of the hyperfine vector A_{hyp} and the effective magnetic field B_{eff}, respectively. The first two terms in the Hamiltonian form the energy ladder of the system (Ω for the dressed NV spin, and γ_{N}|B_{eff}| for the Larmor frequency of the nuclear spin), whereas the last two terms are responsible for electron-nuclear spin interaction.

Here, the former represents mutual spin-flips, or coherent evolution of the electron-nuclear pair, and the latter is the nuclear spin dephasing caused by electron flips. When the driving field is adjusted properly, an energy matching condition (known as the “Hartmann-Hahn condition”) given by

Ωγ_{N}|B_{eff}|=γ_{N}|B−(½)A_{hyp}|, (6)

can be engineered, equalising the first two terms in Hamiltonian (5). Then, the coupling term in the Hamiltonian becomes dominant, and the time evolution of the system is a coherent joint evolution of the electron nuclear pair. For instance, starting in the |+,↓ [symbol] state, the system evolves according to |Ψ [symbol] =|+,↓ [symbol] cos (Jt)⁺|−,↑ [symbol] sin (Jt), with J given by

J=¼γ_{N}|A_{hyp}| sin θ. (7)

Thus, at time t=π/2J, the two spins become maximally entangled, and after a t=π/J, a full population transfer occurs and the states of the two spins are in effect ‘swapped’.

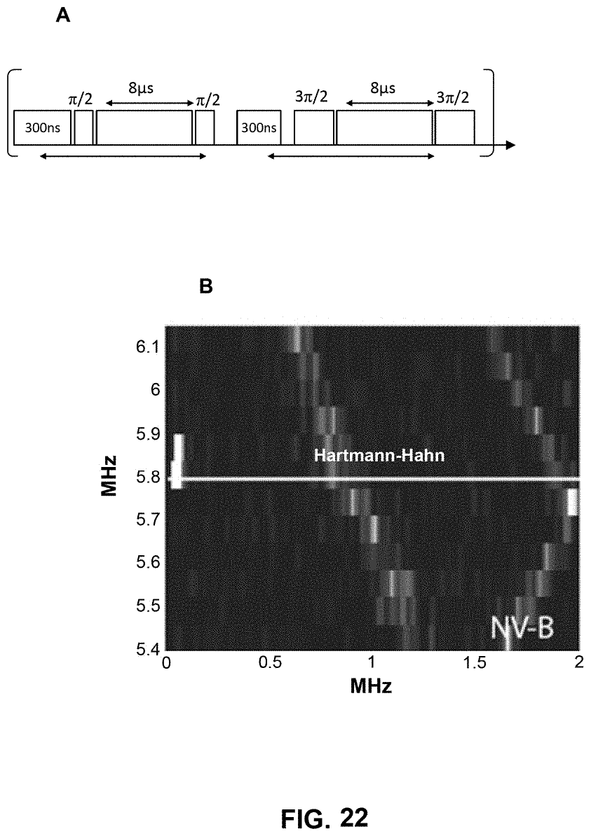

Larmor frequencies of ¹³C nuclear spins were approximately 5 MHz for magnetic fields used in our experiments. In order to transfer the electron spin to the nuclei, we applied a sequence, in which a short laser 4 pulse (300 ns) is used for the polarization of the electron spin in the ground state of the NV center and for readout of the population via spin-dependent fluorescence. The microwave manipulation is the alternating spin locking sequence for 8 ρs as shown in FIG. 22 on the top (section “A”). A sweep of the source power through the Hartmann-Hahn double resonance while counting all the photons yielded the trace shown in FIG. 22 on the bottom (section “B”). The low frequency components in the spin-locking signal for various microwave driving fields is shown on the x-axis, the corresponding Rabi frequency is shown on the y-axis. The oscillations appearing in the spectrum at the Hartmann-Hahn condition (when the Rabi frequency of electron spin matches the nuclear spin Larmor frequency) indicate flip-flops between electron spins and nuclear spins.

In accordance with another embodiment of the present disclosure, a method for producing a semiconductor structure, in particular for hyperpolarization and/or nuclear magnetic resonance applications, is provided. The embodiments of the present disclosure further relate to a semiconductor structure for nuclear magnetic resonance applications for a fluid material sample. A semiconductor structure may comprise a polarization structure, a solid catalyst, a hyperpolarizing catalyst, or a diamond catalyst.

Conventionally, inductive methods are used to detect nuclear magnetic resonance signals. To that end, an induction coil extending around the sample is used, for example, where the processing nuclear spin moments generate alternating magnetic fields that induce an electrical voltage as nuclear magnetic resonance signal in the turns of the induction coil.

Such inductive methods for generating nuclear magnetic resonance spectra are suitable in particular for detecting a large magnetic moment (magnetization), such as is generated in particular by a large number of nuclear spin moments aligned (polarized) in the same way. The induced voltage, i.e. the nuclear magnetic resonance signal, is proportional to the changeover time in a magnetic flux permeating the induction coil. In this case, the magnetic flux is substantially proportional to the number of magnetic flux lines which pass through the interior of the induction coil. Therefore, if the diameter of the induction coil is reduced, the number of flux lines passing through and hence the amplitude of the induced voltage are reduced. In this case, the minimum diameter of the induction coil is restricted to a few micrometres (μm) in order to avoid self-induction effects. As a result, the spatial resolution of such inductive methods is restricted to comparatively large samples, and the spatial resolution in a nuclear magnetic resonance examination is disadvantageously limited.

In order to improve the spatial resolution for generating nuclear magnetic resonance spectra individual detection spin moments may be used as local magnetic field sensors having a high spatial resolution. As such, by way of example, individual electron spin moments of color centers in semiconductor materials, for example, NV centers in diamond, may be used as detection spin moments. In this case, the detection spin moments may have a detection region or a detection volume. A detection region may refer to a spatial interaction region which permeates the sample and in which nuclear spin moments present bring about a sufficient influencing of the detection spin moment by means of dipolar interactions. The influencing may be detectable or measurable. Since the interaction strength of the dipolar interactions scales with the inverse cubic distance (r⁻³), small detection regions of a few cubic nanometres (nm³) and hence high spatial resolutions can be realized.

The detection spin moments may be expediently arranged a few nanometres below the surface of the semiconductor material. In this case, it may be possible for a multiplicity of detection spin moments to be arranged in a manner distributed at the surface in an area-covering manner, uniformly or non-uniformly, such that the detection spin moments can be detected and evaluated for example jointly by means of a far field detection. In particular, in the case of gaseous or liquid material samples, a particularly large-area surface of the semiconductor material may be desirable, such that as many detection spin moments as possible may be in contact with the material sample. In this case, it may be possible, for example, to introduce quasi two-dimensional nanostructurings into the surface. In this case, such nanostructurings may have a plurality of individual structures arranged closely alongside one another. In particular, the nanostructurings may comprise pillar-type nanostructurings, such as nanopillars, wall- or channel-type nanostructurings, such as nanoslits or nanochannels, and pot-like nanostructuring such as inverse pillars or nano-pots. Such nanostructurings may be referred to as quasi two-dimensional, since the dimensions of the transverse surface are greater by at least one order of magnitude (˜μm-mm) than the height of the structuring (˜nm-μm) oriented perpendicularly thereto.

The introduction of nanostructuring to the surface can additionally improve the optical properties of the semiconductor material, thereby enabling easier detection and manipulation of said detection spin moments. In particular, nanostructures or nanostructurings can enhance or improve the emission and excitation of the detection spin moments and/or can be designed to act as optical lattices. Furthermore, the increased surface to volume ratio of the semiconductor material may be advantageous for other nuclear magnetic resonance applications, such as hyperpolarization. For example, the increased surface to volume ratio of the semiconductor material may be advantageous to polarize the individual detection spin moments and then transfer their spin polarization to the nuclear spins of the fluid material sample. In particular, the enlarged surface area caused by nanostructuring of the semiconductor material may be beneficial for improving such a polarization transfer, regardless of whether the target material is in a liquid phase, or in a solid or glassy phase. The hyperpolarized material can subsequently be examined via induction-based NMR or MRI systems. Throughout the embodiments of the disclosure, the terms “nanoscopic three-dimensional structure” and “quasi two dimensional nanostructures” may be used interchangeably.

In some embodiments, the nanostructuring may assist in confining the target fluid to a sub-micrometric volume, thereby significantly improving the detection of the nuclear spins in the fluid by the detection spin moments. Fast-diffusing molecules typically have a long spin coherence time which can be utilized for high resolution spectroscopic detection or efficient polarization by the detection spin moments. However, the fast diffusion reduces the interaction time of the detection spins and the nuclear spins, thereby negating the advantage of the long coherence time. Using nanostructuring to confine the fluid to a volume under 10⁶ nm³, under 10⁴ nm³, or under 10³ nm³, may significantly prolong the interaction time between the detection spins and the nuclear spins, thereby enabling high-resolution spectroscopic detection or efficient polarization transfer. In some embodiments, the nanostructuring may be provided in the form of pots or inversed pillars, thereby confining the fluid in two directions. In some embodiments, the fluid may be confined in three directions, for example, by adding a capping layer after the liquid is introduced to the nanostructures. The liquid may be introduced inside the nanostructures, for example, by altering the surface termination between the inside of the nanostructures and the outside of the nanostructures.

In order to produce such nanostructurings, the surface may be structured by means of a chemical or plasma-driven etching process. However, especially for diamonds, such production processes may enable only a structuring height or structuring depth of approximately 10 μm, thereby restricting the surface area enlargement. In some embodiments, there is a need for an improved method for producing a semiconductor structure. In particular, there is a need for an improved method for producing a three-dimensional semiconductor structure having a particularly large surface area for nuclear magnetic resonance spectroscopy of fluid material samples.

In some embodiments of the present disclosure, a number of separate semiconductor layers may be provided. In some embodiments, in one or more end-side, surface (plane side) of each semiconductor layer, a nanostructuring directed along a respective layer thickness may be provided. The structured semiconductor layers may subsequently be arranged in a manner stacked one above another along a stacking direction. In some embodiments, the plate-like or plate-shaped semiconductor layers may be thin. For example, a semiconductor layer may have a layer thickness that is significantly smaller than its transverse dimensions. By way of example, an approximately square semiconductor layer may have transverse side dimensions in the range of a few hundred micrometres (μm) to centimeters (cm) and a layer thickness of approximately 1-10 μm. The nanostructuring may be a quasi two-dimensional structuring of the surface of the respective semiconductor layer. In some embodiments, the nanostructuring may have a dense, adjacent arrangement of a plurality of individual structures.

The stacking of the nanostructured semiconductor layers may form an effective three-dimensional semiconductor structure whose stack height along the stacking direction may be comparable with its transverse dimensions. In some embodiments, each individual, separate semiconductor layer may have a particularly large surface area, wherein the surface areas of the individual semiconductor layers may be effectively summed as a result of the microscopic stacking. As a result, the resulting semiconductor structure may have a particularly large total surface area.

In some embodiments, a number of fluid channels for guiding the fluid material sample may be formed by the nanostructurings of the stacked semiconductor layers. For example, fluid channels may be provided such that the flow direction of the material sample may be oriented parallel to the stacking direction and to allow fluid flow through the semiconductor structure axially. In other embodiments, fluid channels may be provided such that the flow direction of the fluid material sample may be oriented perpendicularly to the stacking direction and to allow fluid to flow tangentially through the semiconductor structure. As a result of the stacking of nanostructured semiconductor layers, the semiconductor structure may have a particularly large surface area for nuclear magnetic resonance applications. This may increase the interaction area between the fluid material sample and the semiconductor material, which may be advantageous for both hyperpolarization and nuclear magnetic resonance spectroscopy of the fluid material sample.

In one embodiment, the stacked semiconductor layers may be joined to one another, for example, by adhesively bonding the layers to one another at their circumferential edge regions. By way of example, the semiconductor layers in this case may be joined to one another by means of a CVD method (chemical vapour deposition). In some embodiments, the nanostructurings may be introduced into the respective surface by means of a chemical etching process. In an alternative embodiment, the nanostructurings may be introduced into the surface by means of a plasma etching method or by means of a laser cutting method. In yet another embodiment, the nanostructurings may be grown by a growth process on the surface along the stacking direction. As such, the nanostructurings may project above the surface of the respective semiconductor layer.

In one embodiment, one or more semiconductor layers may be completely pervaded by the respective nanostructuring along the layer thickness, thereby providing a large surface area for each individual semiconductor layer. In some embodiments, the semiconductor layers may be stacked, such that the layers are offset with respect to one another along a transverse direction oriented perpendicularly to the stacking direction. Additionally or alternatively, the semiconductor layers may be stacked in a manner, such that the layers are turned relative to one another about the stacking direction. For example, the semiconductor layers may be rotated with respect to one another about the stacking direction. In some embodiments, the semiconductor layers may be stacked, such that the layers are randomly offset and/or randomly rotated with respect to one another. This may ensure that the nanostructurings of the individual semiconductor layers are not arranged in alignment with one another along the stacking direction, and thus, provide a particularly large surface area of the semiconductor structure because the nanostructurings would completely pervade the respective semiconductor layer along the layer thickness.

In one embodiment, a lattice pattern may be introduced into the surface of the respective semiconductor layer as nanostructuring. In some embodiments, a rectangular, square lattice pattern or a honeycomb-shaped lattice pattern having uniform hexagons may be introduced as nanostructuring into the surface. This may ensure the largest possible surface area and the highest possible pressure stability vis a vis acting axial forces along the stacking direction.

In one embodiment, the lattice pattern nanostructuring may be introduced into the surface as a plurality of passage openings pervading the semiconductor layer. The passage openings may be circumferentially enclosed by lattice walls, either partially or completely. The lattice walls may have a wall thickness which may be less than half the clear diameter of the respectively enclosed passage opening. The passage openings may have, for example, a clear diameter of about 20 nm to about 10 μm, and the lattice walls forming the opening edges may have, for example, wall thicknesses of about 50 nm to about 5 μm. The wall thicknesses may be less than the opening diameters of the passage openings. This may ensure that, for mutually offset and/or rotated stacking of the semiconductor layers, a (fluid) channel running along the stacking direction may be formed for guiding the fluid material sample along the passage openings, which may be arranged at least partly in alignment with one another.

In one embodiment, the nanostructuring may have a number of spacer elements which may protrude from the structured surface along the stacking direction and introduce a gap between adjacent stacked layers. Accordingly, the nanostructuring may be introduced via a two-layer etching process, thereby generating the spacer elements as a top layer for introducing a gap between the stacked layers. The spacer elements may allow a small space to be left between the nanostructured layers, such that the passage openings or through holes may never be blocked. The spacer elements, i.e. the top layer, may have a comparatively small height along the stacking direction, for example, a height of about 1 μm for a layer thickness of about 20 μm.

In some embodiments, an intermediate layer composed of a porous material may be arranged between two semiconductor layers arranged adjacently along the stacking direction. The pores of the intermediate layer may be suitably large enough such that the fluid material sample can substantially flow through without being impeded. The intermediate layer may have a layer thickness of about 100 nm to about 10 μm and may be applied to the semiconductor layers in the course of the stacking thereof. As such, the intermediate layer may ensure a reliable fluid transport of the fluid material sample.

In some embodiments, the semiconductor layers may be provided with a lattice-like or lattice-shaped nanostructuring whose wall thicknesses may not significantly be smaller than its passage openings. In such semiconductor layers, the porous intermediate layer may ensure that the passage openings are not closed in the stacked state. This may also ensure that the material sample can flow through the semiconductor structure substantially without being impeded. As a result, the manufacturing tolerances in the production of the semiconductor structure may be reduced. Furthermore, it may be possible to use thicker wall thicknesses, as a result of which the stability of the semiconductor layers and of the semiconductor structure is improved. Furthermore, the intermediate layer may act as a spacer or compensation element between the semiconductor layers in the case of axial pressures and loadings along the stacking direction.

In some embodiments, the separate semiconductor layers may be produced from a common semiconductor material. In other words, the semiconductor layers may be in particular parts or pieces of the semiconductor material, which may be separated from the semiconductor material, for example, by means of a laser cutting method. The separated semiconductor layers may be subsequently reduced to a desired layer thickness, for example, of a few micrometres. The separated semiconductor layers may be reduced, for example, by means of a polishing and/or etching process.

In some embodiments, the surface of the semiconductor material may be provided with the nanostructuring. Then, the semiconductor layer provided with the nanostructuring may be separated from the semiconductor material. In one embodiment, the semiconductor material may comprise a wafer, such as a mono- or polycrystalline (semiconductor) blank. The semiconductor material may be grown on the wafer with the desired, for example isotropic, properties. The semiconductor material grown may be subsequently provided with the nanostructuring and subsequently separated as a semiconductor layer from the wafer. This process may then be successively repeated.

The semiconductor structure according to the embodiments of the present disclosure may be suitable and designed for nuclear magnetic resonance applications for fluid material samples, such as hyperpolarization and/or nuclear magnetic resonance spectroscopy of fluid material samples.

In some embodiments, the semiconductor layer of the semiconductor structure may be produced from a diamond. The (111) lattice direction of the respective diamond lattice may be oriented along the stacking direction. As a result, the semiconductor layers may be arranged such that they are uniform with regard to the lattice orientation in the course of a stacking. In some embodiments, the diamond material may be a so-called electronic grade diamond material, which may improve the optical properties of the semiconductor structure. In other embodiments, it may be possible to use heteroepitacial diamond or diamonds produced by HPHT (high pressure high temperature) methods in order to reduce costs. In an embodiment, it may be possible to use a low quality diamond material, such as so-called optical grade diamond material, and overgrow it with a thin film or layer of electronic grade diamond. Afterwards, the low quality diamond material may be etched away, thereby leaving only the overgrown electronic grade diamond material as semiconductor layer. This process may be analogously applied to other semiconductor materials.

In some embodiments, the semiconductor layer may have a plurality of color centers, such as NV centers. As a result, a particularly large number of color centers may be brought into contact with the fluid material sample to be examined. Accordingly, a color center may comprise a point or lattice defect in the solid lattice of the semiconductor material which may absorb optically visible light. Such color centers may have electron spins which can be used as detection spin moments for the purpose of nuclear magnetic resonance spectroscopy. The NV center may have a spin-1 electron spin moment with a ground state with zero field splitting of 2.87 GHz between a non-magnetic state (“0”) and the associated magnetic states (“+1”, “−1”), such that simple manipulation by means of irradiation by radio-frequency pulses in the microwave range may be possible.

Upon illumination or irradiation with a green (laser) light, the electron spin moment of the NV center may be, on the one hand, substantially polarized into the non-magnetized ground state (“0”). On the other hand, upon excitation, the NV center may emit light in the red wavelength range, wherein the number of photons is dependent on the spin state of the electron spin moment before the irradiation. In other words, the state of the electron spin moment of the NV center can be read out optically by detection of the emitted photons. In this case, the NV centers may be arranged suitably near the diamond surface, for example, at a distance of a few nanometres to micrometres. The NV centers may be introduced into the semiconductor layers, for example, by means of ion implantation or by means of doping, and may thus be arranged at least partly in the nanostructuring.

In another embodiment, the NV centers may be arranged throughout the diamond, or at least throughout the nanostructures, thereby enabling the buildup of polarization in the diamond nuclear spins. In some embodiments, the nitrogen in the diamond may be introduced via nitrogen-rich growth by chemical vapour deposition (CVD), in a concentration of at least 1 ppm, or at least 10 ppm. In one embodiment, this nitrogen rich layer can be grown in a thick layer on top of a diamond substrate and may subsequently be nanostructured, thus resulting in nitrogen incorporated throughout the nanostructures. In another embodiment, the diamond may be first nanostructured and then the nitrogen may be incorporated by a CVD overgrowth of the nanostructures. This overgrowth may have a preferential orientation (e.g. 111 or 100) to generate nicely faceted structure side-walls. In yet another embodiment, the starting diamond material may already have a high nitrogen concentration in a concentration of at least 1 ppm, or at least 10 ppm, which may be typical of HPHT diamond growth and many methods of CVD growth as well. The NVs can be activated by electron irradiation or implantation of atoms generating vacancies, such as helium, hydrogen, carbon, and then followed by annealing of the diamond.

In a configuration in which the (111) lattice direction of the diamond lattices of the semiconductor layers is oriented parallel to the stacking direction, at least a number of NV centers may thus be oriented parallel to the stacking direction. The alignment of an external magnetic field in the course of nuclear magnetic resonance spectroscopy may be significantly simplified as a result. In one embodiment, the semiconductor structure described above may be used for nuclear magnetic resonance spectroscopy of fluid material samples. In this case, the fluid material sample may be guided by flow engineering along the axial or stacking direction through the semiconductor structure. As such, the fluid material sample may be examined with a particularly high spectral and spatial resolution in an effective and cost-effective way.

In another embodiment, the semiconductor structure may be used in particular for hyperpolarizing of fluid material samples. For example, the fluid material sample may be guided in terms of flow engineering in particular along the axial or stacking direction through the semiconductor structure and may then be polarized via a polarization transfer from the NV-centers to the nuclear spins of the fluid material sample. In order to improve the polarization transfer, the fluid material sample may be frozen or glassified during the polarization transfer.

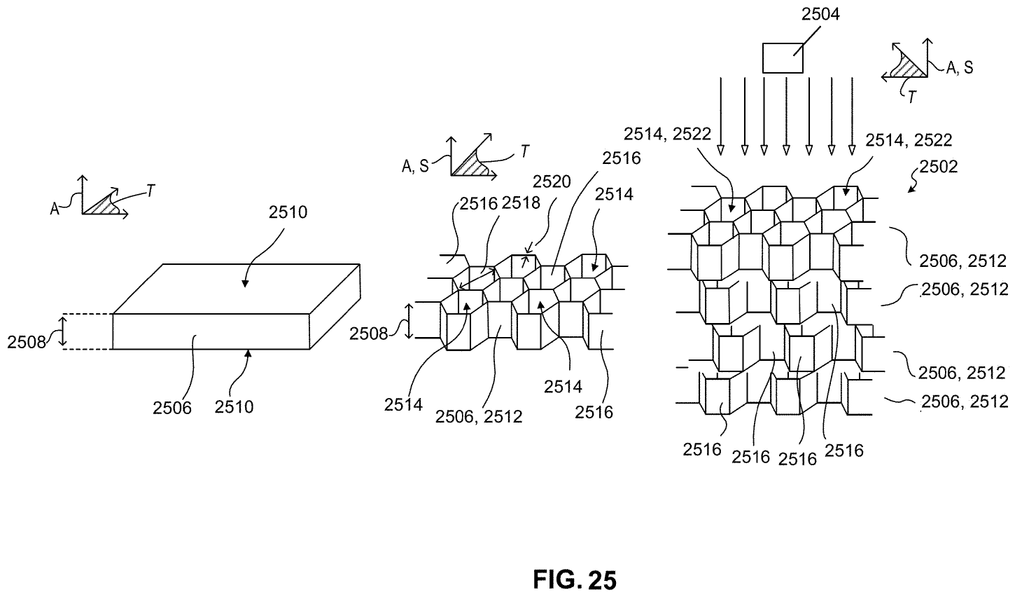

FIGS. 25-27 and 29 illustrate schematic diagrams of exemplary methods for producing a semiconductor structure for nuclear magnetic resonance spectroscopy of a fluid material sample. As seen in FIG. 25, the semiconductor structure 2502 may be formed from a number of individual, separate semiconductor layers 2506. The semiconductor layers 2506 may comprise one or more membranes. The semiconductor layers 2506 may be formed, for example, from diamond. The thin semiconductor layers 2506 may be plate-shaped or plate-like. In other words, the semiconductor layers 2506 may each have comparatively large dimensions in a transverse plane T and a comparatively small dimension along an axial direction A oriented perpendicularly thereto. The dimension or dimensioning of the semiconductor layers 6 along the axial direction A may also be referred to hereinafter as layer thickness 2508 of the semiconductor layer 2506. The end or plane sides of the semiconductor layer 2506 that are oriented parallel to the transverse plane T may be referred to hereinafter as surfaces 2510.

As seen in the middle of FIG. 25, one of the surfaces 2510 may be provided with a nanostructuring 2512. In this case, the nanostructuring 2512 may be introduced into the diamond lattice of the semiconductor layer 2506 by means of a chemical etching process or by means of a reactive plasma etching process. The nanostructuring 2512 may have a honeycomb-shaped lattice pattern having a number of regular hexagons lined up adjacent to one another. Each of the hexagons or each of the honeycombs may have a central, hexagonal passage opening or through hole 2514. In this case, the passage openings 2514 may each be completely enclosed by six lattice walls 2516 along their respective outer circumference.

The passage opening 2514 may substantially completely pervade the semiconductor layer 2506. This means that the passage opening 2514 may extend between the surfaces 2510 along the entire layer thickness 2508. The passage openings 2514 may each have an internal diameter or clear diameter 2518. In this case, the surrounding lattice walls 2516 may each have a significantly smaller wall thickness 2520 in comparison to the diameter 2518. The wall thickness 2520 may be less than or equal to half of the diameter 2518. The structured semiconductor layers 2506 may subsequently be stacked one above another along a stacking direction S oriented parallel to the axial direction A. In this case, the semiconductor layers 2506 may be stacked in a manner randomly offset relative to one another along a transverse direction oriented perpendicularly to the stacking direction S. Since the wall thicknesses 2520 of the lattice walls 2516 are smaller than the clear diameters 2520 of the passage openings 2514, the passage openings 2514 of a semiconductor layer 2506 of such a stacked arrangement may not be completely covered by the lattice walls 2516 of the adjacently arranged semiconductor layers 2506 in any relative position of the semiconductor layers 2506. In other words, the passage openings 2514 of the stacked semiconductor layers 2506 may at least partly lead into one another. This means that the passage openings 2514 leading into one another may form fluid channels 2522 branching into one another along the stacking direction S and axially completely pervading the semiconductor structure 2502.

The fluid material sample 2504, illustrated by means of arrows in FIG. 25, may be guided through the semiconductor structure 2502 through the fluid channels 2522. In this case, a plurality of magnetically active color centers, such as NV centers, may suitably be introduced into the diamond lattices of the semiconductor layers 2506. As such, nuclear magnetic resonance spectroscopy of the material sample 2504 flowing through can be carried out. The diamond lattices of the semiconductor layers 2506 may be oriented with their (111) lattice or crystal direction parallel to the stacking direction S. This means that at least some of the plurality of color centers may be oriented along the stacking direction S of the semiconductor structure 2502 or along the flow direction of the material sample 2504.

The semiconductor layers 2506 may have, for example, a layer thickness 2508 of approximately 10-100 μm. In this case, the passage openings 2514 of the nanostructuring 2512 may have clear diameters 2518 of between 100 nm and 100 μm. In particular, the diameters 2518 may thus be comparable in dimension to the layer thickness 2508. The wall thicknesses 2520 may be approximately 50 nm to 5 μm.

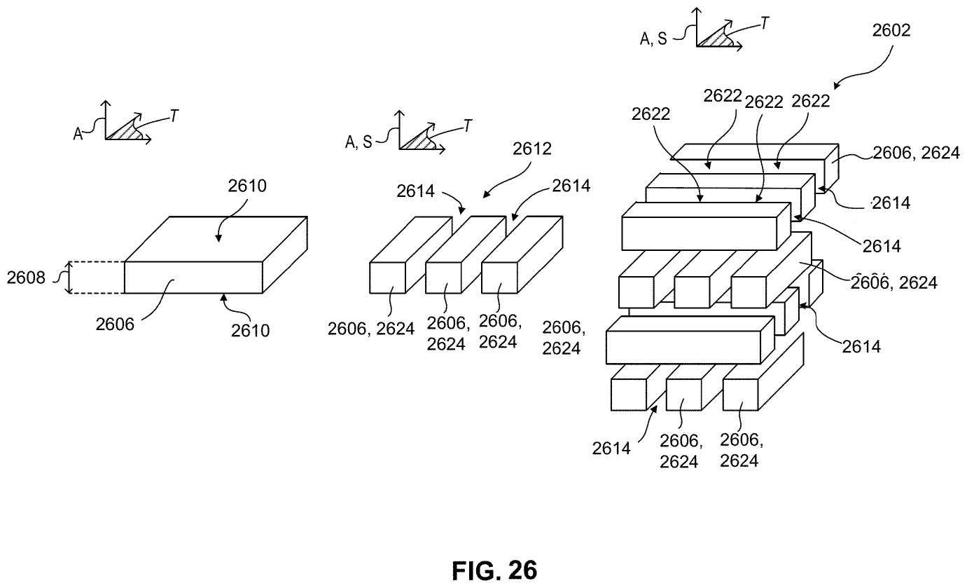

FIG. 26 illustrates another embodiment of a semiconductor structure 2602 with nanostructuring 2612 that is different from the nanostructuring 2512 in FIG. 25. As seen in FIG. 26, the nanostructuring 2612 of the semiconductor layers 2606 may comprise longitudinal-lattice-like nanochannels or nanoslits. In this case, the passage openings 2614 may comprise rectilinear, parallel slits that may pervade the semiconductor layer 2606. In some embodiments, the bar- or strut-shaped (channel) walls 2624 may be mechanically coupled to one another in sections by means of transversely directed connecting webs. In this case, the connecting webs may be arranged for example at a distance of 100 μm from one another. As a result, the channel walls 2624 may not be completely free-standing.

As seen on the right in FIG. 26, the semiconductor layers 2606 in this case may be stacked in a manner turned relative to one another about the stacking direction S, such that the semiconductor layers 2606 are rotated with respect to one another about the stacking direction S, to form the semiconductor structure 2602. In particular, the semiconductor layers 2606 of successive stack layers may be turned by 90° relative to one another, such that the channel walls 2624 of the semiconductor layers 2606 cross one another approximately perpendicularly. Along the axial stacking direction S, the semiconductor structure 2602 may thus have an approximately rectangular lattice structure for guiding the fluid material sample 2604.

In comparison with the lattice walls 2616, the channel walls 2624 may have a comparatively large wall thickness. For example, the channel walls 2624 may be dimensioned in such a way that the wall thickness is approximately equal to the layer thickness 2608, for example 10 μm.

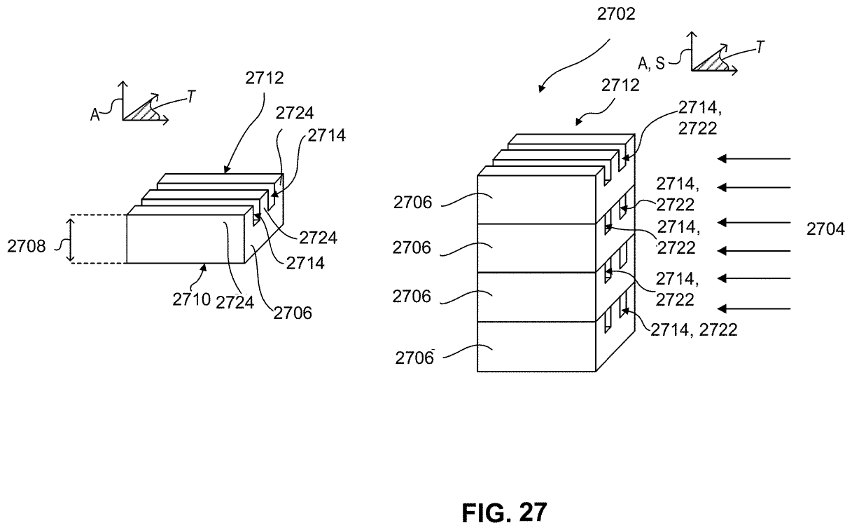

FIG. 27 illustrates another embodiment of the semiconductor structure 2702 through which the fluid material sample 2704 may be guided transversely, for example, in a manner oriented parallel to the transverse plane T and perpendicular to the axial direction A or stacking direction S. To that end, the semiconductor layers 2706 may have transversely directed channel walls 2724 made available by passage openings 2714. In contrast to the exemplary embodiment in FIG. 26 however, the passage openings 2714 of the exemplary embodiment in FIG. 27 may not completely pervade the semiconductor layer 2706 along the layer thickness 2708. Along the transverse direction, however, the semiconductor layers 2706 may be substantially completely pervaded by the passage openings 2714 running parallel. In other words, the passage openings 2714 in this exemplary embodiment may comprise grooved depressions in the surface 2710.

The semiconductor layers 2706 in FIG. 27, for example, may be grown on a semiconductor material, in particular on a wafer, and subsequently may be provided with the channel-like nanostructuring 2712. The semiconductor layers 2706 may be subsequently separated from the semiconductor material and stacked one on top of another. As seen on the right in FIG. 27, the semiconductor layers 2706 may be arranged one above another in a substantially identically directed manner along the stacking direction S. In other words, the channel walls 2724 and passage openings 2714 of the stacked semiconductor layers 2706 may be arranged in a manner running parallel to one another. As a result, the passage openings 2714 may substantially form the fluid channels 2722 of the semiconductor structure 2702.

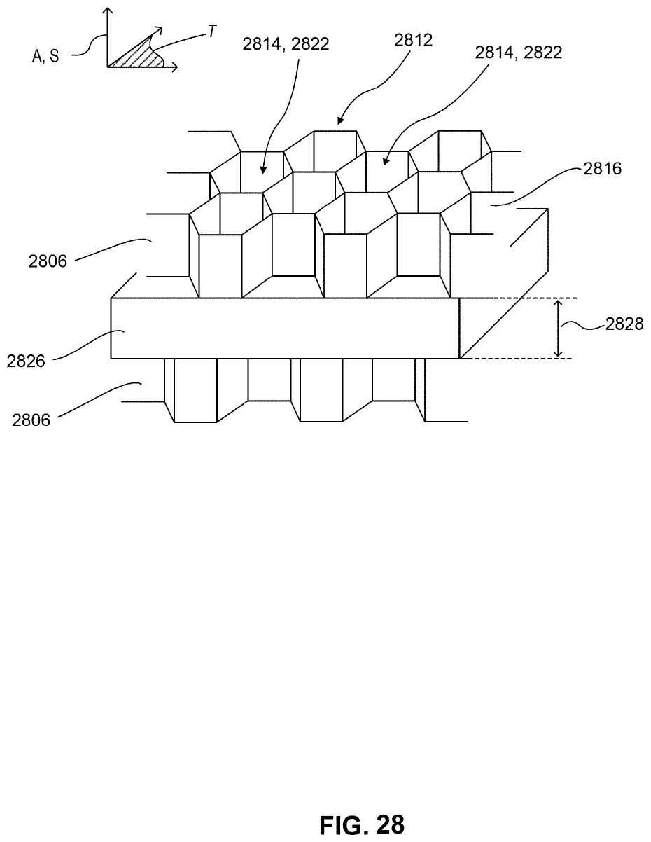

Referring to FIG. 28, an intermediate layer 2826 composed of a porous material may be arranged in a sandwich-like manner between two semiconductor layers 2806 stacked along the stacking direction S. In some embodiments, the semiconductor layers 2806 may include one or more membranes. Additionally or alternatively, the intermediate layers 2826 may include one or more membranes. In this case, the intermediate layer 2826 may have a layer thickness 2828 that is approximately equal to the layer thickness 2808 of the semiconductor layers 2806. In this case, the pores of the intermediate layer 2826 may be large enough such that the fluid material sample 2804 can flow through substantially without being impeded. The porous intermediate layer 2826 may ensure that the passage openings 2814 or the fluid channels 2822 are not closed in the stacked composite assembly of the semiconductor structure 2802.

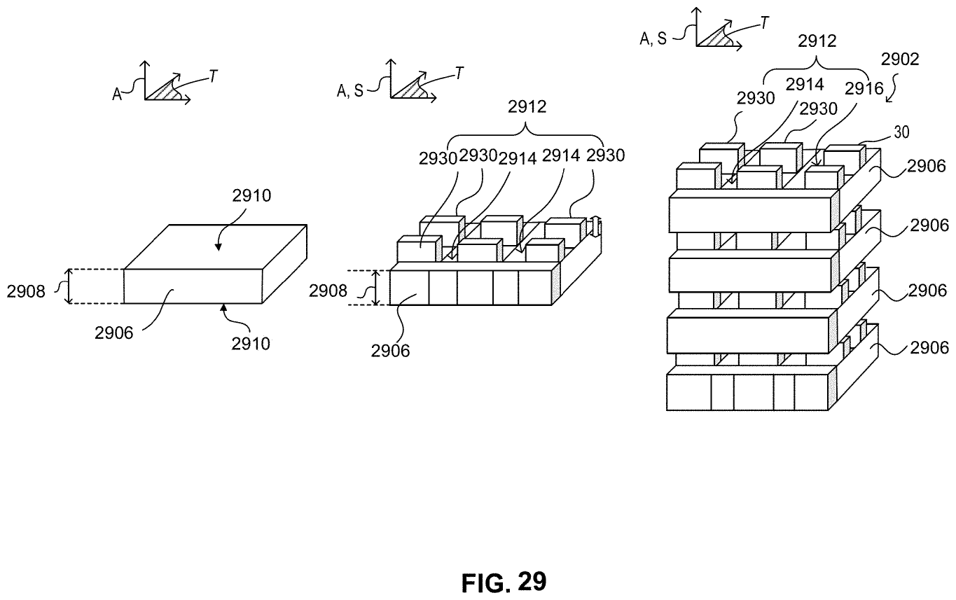

Referring to FIG. 29, the nanostructurings 2912 may include a number of slit- or slot-like passage openings 2914, which may pervade the respective semiconductor layer 2906. The nanostructurings 2912 may further include a number of spacer elements 2930, which may protrude from the structured surface 2910 along the axial or stacking direction A, S. In this embodiment, the nanostructuring 2912 may be generated via a two-layer etching method. In particular, the spacer elements 2930 may be generated as a top layer and the passage openings 2914 may be generated as a bottom layer during the two-layer etching.

The spacer elements 2930 may create a gap between adjacent semiconductor layers 2906 in the semiconductor structure 2902. In other words, a small space between the semiconductor layers 2906 may be provided, thereby ensuring that the material of one semiconductor layer 2906 does not block the passage openings 2914 of the adjacent one. The semiconductor layers 2906 may have a layer thickness 2908 of approximately 20 μm, while the spacer elements 2930 may have a height along the axial direction A of about 1 μm.

In some embodiments, the semiconductor structure may include a plurality of nanostructured diamond substrates with nanoscopic three-dimensional structures across a surface thereof, each substrate hosting defects with optically polarizable electron spins. In other embodiments, the semiconductor structure may include a plurality of microstructured diamond substrates with microscopic three-dimensional structures across a surface thereof. The plurality of nanostructured substrates may be arranged in a stack, and the stack may have a plurality of channels therethrough. The channels may be configured to permit a polarizable fluidic agent to flow through the nanoscopic three-dimensional structures of the plurality of nanostructured diamond substrates in the stack. In some embodiments, each substrate may be associated with its own holder. In some embodiments, the nanoscopic three-dimensional structures may each have a size range of about 50 nm to about 5000 nm. In other embodiments, the channels may include pathways through at least one membrane surface, pathways between adjacent membranes, or both. In yet another embodiment, the plurality of nanostructured substrates may include at least 10 stacked nanostructured diamond substrates, at least 50 stacked nanostructured diamond substrates, or at least 100 stacked nanostructured diamond substrates. In some embodiments, the plurality of nanostructured diamond substrates may be coated with endogenous molecules having polarizable nuclear spin. In other embodiments, each substrate may have a thickness between about 1 μm and about 100 μm. In other embodiments, each substrate may include at least one honeycomb-shaped cut. In accordance with another embodiment of the present disclosure, a system of hyperpolarizing metabolic molecules, such as pyruvate, at temperatures close to room temperature is provided. Positron Emission Tomography/Computer Tomography (PET/CT) is currently the global standard of care for diagnosis and staging of cancer with more than 4000 units and over $7 billion market worldwide. PET/CT enables the imaging of specific metabolic molecules, such as injected radioactive Fludeoxyglucose, thus providing insight as to high-metabolism regions typical of cancerous tumors. However, PET/CT has several significant disadvantages. For example, the radioactive isotopes and CT scans may present harmful radiation to patients and may not be suitable for women who are pregnant or breastfeeding. In addition, PET images may not provide information about the chemical state of the tissue at a molecular level. As such, the link between images of radiotracers and specific metabolic information may be inherently limited. Accordingly, PET may not provide information related to the level of tumor stage or aggressivenss and may not allow early assessment of treatment efficacy. Moreover, the use of PET/CT may be limited by the exorbitant price of scanners, cyclotrons for preparation of radioactive isotopes, and consumables.

In the recent decade, a new disruptive technology has developed, called the hyperpolarized MRI, which provides the first viable, nonradioactive alternative to PET/CT for non-invasive diagnosis and staging of cancer through standard MRI machines, turning MRI from an anatomical to a molecular imaging modality similar to PET/CT. In hyperpolarized MRI, metabolic molecules, such as pyruvate endogenous to the body, are placed in a polarizer that enhances the ¹³C spin polarization, and thus, their magnetic resonance (MR) signal. Polarized molecules may then be injected to patients before undergoing imaging by standard MRI, which can detect and track the hyperpolarized molecules in the patient. Research of clinical applications for hyperpolarized metabolites has been growing. For example, researchers have demonstrated that hyperpolarized MRI is comparable to and sometimes higher in accuracy than conventional PET/CTs and standard MRIs. In addition, researchers have demonstrated that hyperpolarized MRI may provide additional vital metabolic information that enables characterization of tumors, including stage and malignancy of the tumors, which was previously not available through conventional PET/CTs. Moreover, hyperpolarized MRI can provide extremely early assessment of treatment efficacy, generally within hours or days, compared to PET/CTs that provide assessment of treatment efficacy within weeks or months.

To date, many patients have completed and are enrolled in clinical trials for prostate, brain, and soft tissue cancers diagnosis sponsored mainly by the National Institute of Health (NIH). Other solid tumors are being tested as well. The central ingredient in hyperpolarized MRI that goes beyond conventional MRI technology are devices that can reliably generate hyperpolarized metabolic molecules.

In 2013, General Electric (GE) announced a new disruptive standalone external polarizer, which utilizes Dissolution Dynamical Nuclear Polarization (DNP) to hyperpolarize molecules for MRI imaging. Even though the device enabled breakthrough clinical findings to date, it has significant disadvantages that limit the potential impact and clinical scalability of hyperpolarized MRI technology. For example, the standalone external polarizer requires a long time to achieve hyperpolarization, for example, about 90-180 minutes per dosage. In addition, the standalone external polarizer is extremely costly to make and to operate, especially because temperatures colder than −457° F. is required. Moreover, the standalone external polarizer is a large equipment that cannot fit into most MRI rooms, and thus, may be cumbersome. Furthermore, the standalone external polarizer provides a restriction in the type of molecules that can be polarized and limits the type to only a single molecule type at a time. Therefore, there is a need for an improved system for hyperpolarizing molecules that can be used anywhere from highly specialized research institutions to any local hospitals and research institutes.

The embodiments of the present disclosure overcome the aforementioned disadvantages by providing a system of hyperpolarizing metabolic molecules, such as pyruvate, at temperatures close to room temperature. The system may provide higher efficiency compared to conventional polarizers in the market and may provide the flexibility to polarize new types of molecules and multiple molecules simultaneously. In addition, the embodiments of the present disclosure provide a system for hyperpolarizing molecules that is cost-effective, is non-radioactive, and provides an informative tool for tumor characterization, e.g., stage/aggressiveness level, and early assessment of treatment efficacy within hours or days. Moreover, the results of the hyperpolarized MRI may be purely quantitative, thereby providing the ability to fully centralize and automate the reading process.

As discussed previously, the NV center in a diamond comprises a substitutional nitrogen atom (N) that may replace a carbon atom and may be associated with a vacancy (V) in an adjacent lattice site of the diamond. At room temperature, the electron spin native to the NV center can be initialized to a highly polarized quantum state by green laser irradiation. This polarization can then be transferred to surrounding nuclear spins outside the diamond with the support of microwave radiation. Accordingly, the nuclear spins in molecules near the diamond surface may be polarized at room temperature, thereby allowing for greater than about 95% optical polarization of NV centers at room temperatures and low magnetic field which can be transferred to nuclear spins. In addition, the NV centers may be repolarized rapidly using optical irradiation, thus turning the NV center into an infinite polarization bath regardless of the temperature.

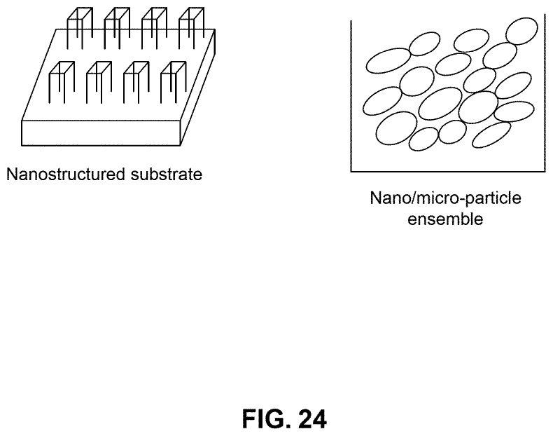

In some embodiments, the diamond core may provide the NV centers for polarization, which the polarizer may use to polarize the metabolic molecules. The metabolic molecules may be in contact with the diamond or be arranged proximate to the diamond such that the polarizer may use the NV centers to polarize the metabolic molecules. As seen in FIG. 24, the diamond may comprise, for example, one or more nanostructure diamonds or ensembles of micro- or nano-diamond particles. In other embodiments, the solid catalyst with optically polarizable electron spins may not comprise a diamond. For example, the solid catalyst may comprise silicon carbide, such as 4H—SiC or 6H—SiC. Electron spins in silicon carbide that may be suitable for polarization and polarization transfer may compise di-vacancies. In yet another embodiment, lattice defects in silicon carbide may be suitable, such as silicon vacancies (SV) or carbon vacancies (VC). In some embodiments, the electron spins to be polarized in the silicon carbide may comprise silicon oxide vacancy centers. In another embodiment, the polarization structure may comprise zinc oxide (ZnO), and the electron spins in zinc oxide that may be suitable for polarization and polarization transfer may comprise oxygen vacancies. Other materials with suitable color centers for hyperpolarization may comprise crystalline quartz and silicon oxide.

In accordance with some embodiments of the present disclosure, the nuclear spins may be polarized inside the solid catalyst at a predetermined magnetic field or temperature. Then, the polarization may be transferred to an external target material at a different magnetic field and/or temperature. The magnetic field and/or temperature needed for efficient polarization of the nuclear spins of the solid catalyst may be different from the optimal magnetic field and/or temperature for efficient polarization transfer and buildup in the external target material. In some embodiments, the external target material, such as a sample, may need to be in contact with the solid catalyst for polarization transfer. In some embodiments, the target material may already be in contact with the solid catalyst when the catalyst is being polarized, and the target material may be brought into contact with the solid catalyst at a later time before the polarization transfer to the target material occurs.

The solid catalyst may be of any shape that enables the target material to come into proximity of the solid catalyst, such that the polarization may be transferred to the target material. The solid catalyst may comprise a high surface ratio. For example, the solid catalyst may comprise nano- or micro-structured substrates, micro- or nano-particles or ensembles of such. By way of example, walls of the solid catalyst may comprise interfaces, at which polarization transfer may occur. In some embodiments, the solid catalyst may be coated with a different material in order to prevent the solid catalyst from reacting chemically with the particles or a solvent or suspension agent, in which the target material is suspended or dissolved. In some embodiments, the solid catalyst may comprise an ensemble of micro- or nano-particles, and the particles may be in a powder form, suspended in a solution, arrayed in a packed-bed-type geometry, or inside another material, such as a hydrogel or porous silica. As such, the target material may come into contact with the solid catalyst.

The target material may comprise solid molecules, such as crystals or amorphous solids, molecules in a glassy state or in a solution, particles in a solvent or powder, or any other type of liquid or solid compositions that allow the target material to come into proximity with the solid catalyst. The polarization of the nuclear spins in the solid catalyst may be performed by optically polarizable electron spins, such as NV center spins in a diamond. Moreover, the polarization structure may allow laser, radio frequency (RF), and/or microwave (MW) irradiation of the electron spins in order to polarize them and transfer the polarization to nuclear spins in the solid catalyst.

According to an embodiment of the present disclosure, a method for dual stage polarization and transfer of nuclear spin may be provided. The method may comprise exposing a hyperpolarizable material, such as a solid catalyst, a polarization structure, a semiconductor structure, a diamond material, or a catalyst material, to optical energy in order to optically hyperpolarize polarizable electron spins of the hyperpolarizable material. An optical light source, such as one or more lasers or one or more LEDs, may be used to expose the hyperpolarizable material to optical energy. For example, the optical light source may optically hyperpolarize polarizable electron spins of the hyperpolarizable material by emitting non-collimated light toward the hyperpolarizable material. The optical light source may also emit green light toward the hyperpolarizable material to optically hyperpolarize polarizable electron spins of the hyperpolarizable material. The hyperpolarizable material may host defects, such as color centers, with polarizable electron spins. For example, the hyperpolarizable material may comprise NV centers. The hosted defects may be located on at least one surface of the hyperpolarizable material.

The method may further comprise transferring polarization of the electron spins to nuclear spins in the hyperpolarizable material. The method may comprise maintaining a temperature of the hyperpolarizable material in a first temperature range during both the hyperpolarization and the transfer and maintaining a magnetic field about the hyperpolarizable material in a first magnetic field range during both the hyperpolarization and the transfer. For example, the temperature of the hyperpolarizable material may be maintained between a range of about 70K and about 250K during both the hyperpolarization and the transfer. The magnetic field about the hyperpolarizable material may be maintained at a magnetic field of above about 0.1 T.

The method may further comprise exposing the hyperpolarized material to a target material in order to convey the nuclear spin polarization of the hyperpolarized material to the target material. The target material may comprise, for example, a sample. For example, the target material may comprise a flowable material, such as a flowable, liquid sample. In some embodiments, the target material may include particles. The target material may also comprise a solid sample, or a liquid sample including solid particles. In some embodiments, the target material may be arranged to be in contact with the hyperpolarized material in order to convey the nuclear spin polarization of the hyperpolarized material to the target material.

The method may further comprise maintaining a temperature of the hyperpolarized material in a second temperature range different from the first temperature range during conveying. The method may further comprise maintaining a magnetic field about the hyperpolarized material in a second magnetic field range different from the first magnetic field range during conveying. The second temperature range may be greater than the first temperature range. In other embodiments, the second temperature range may be lower than the first temperature range. The second temperature range may be in a range of about 70K and about 250K during the conveying. The second magnetic field range may be greater than the first magnetic field range. In some embodiments, the second magnetic field range may be lower than the first magnetic field range. The second magnetic field range may be above 0.1 T.

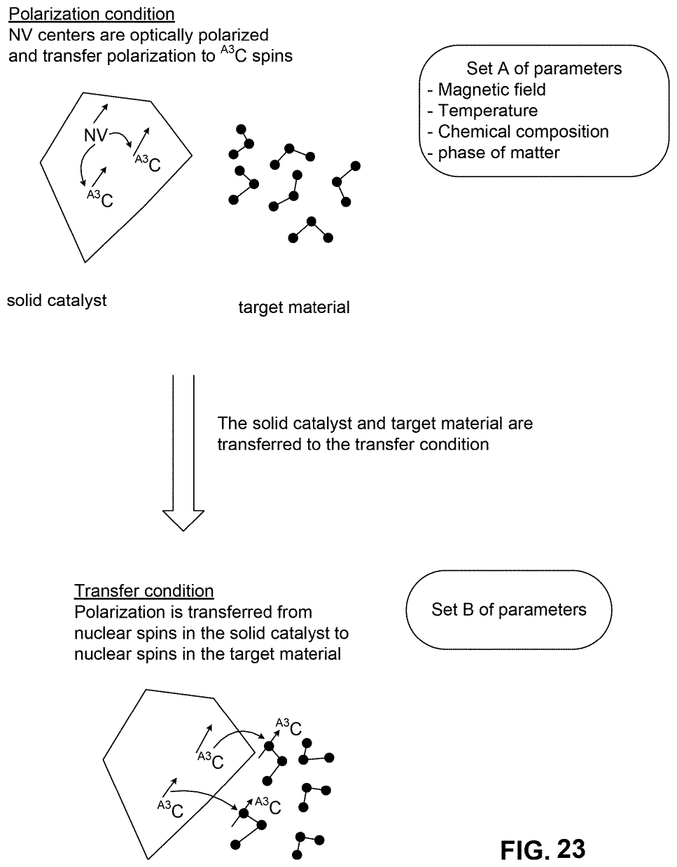

In some embodiments, the polarization of the solid catalyst may be performed at a temperature and magnetic field that is optimal for reaching a high total polarization of the solid catalyst. As seen in FIG. 23, polarization conditions for optically polarizing NV centers and transferring polarization to ¹³C spins may include, but are not limited to, magnetic field, temperature, chemical composition, and phase of matter. The polarization conditions may be adjusted in order to optimize polarization and polarization transfer to a target material. For example, for NV centers in a diamond, polarization may be performed at high magnetic field above 1 T, such that the nuclear spin relaxation may be long. In some embodiments, polarization may be performed at medium-strength magnetic field between about 0.1-1 T, such that a high-power microwave equipment may be used and nuclear relaxation may still be long. In other embodiments, polarization may be performed at magnetic fields around 0.1 T, or around 0.5 T, where the energy level of the NV centers in the ground or excited state may be matched with the nuclear Larmor frequency, thereby producing an efficient polarization transfer. In yet another embodiment, polarization may be performed at magnetic field below 0.1 T, where the NV orientation may produce less of an issue. For example, in polycrystalline samples or micro- or nano-crystal diamond ensembles, the orientation of the diamond lattice axis relative to the magnetic field may determine the NV center energy splitting and the MW driving frequency, which may cause a large dispersion for randomly oriented samples. In some embodiments, microwave or magnetic field sweeps may overcome the large dispersion. Moreover, at magnetic fields above 0.1 T, the optical polarization of NV centers may work well only for NV centers within −30° from the magnetic field axis or from the plane perpendicular to the magnetic field. At magnetic fields below 0.1 T, however, the optical polarization may work for any axis orientation, and the spread of the Larmor frequency of randomly oriented NV centers may be narrower. Therefore, at magnetic fields below 0.1 T, many more NV orientations may be utilized in the polarization transfer by frequency or magnetic field sweeps.

In some embodiments, the temperature for the polarization of the solid catalyst may be any temperature, at which the nuclear spin relaxation of the nuclear spins in the solid catalyst has a sufficiently long relaxation time for the building up a high polarization, for example, more than about 1 second, more than about 10 seconds, or more than about 100 seconds. As seen in FIG. 23, after the polarization of the solid catalyst, the conditions under which the polarization may be transferred from the solid catalyst to surrounding nuclear spins, called the transfer conditions, may be adjusted. The conditions that may be changed include, but are not limited to, the magnetic field, temperature, chemical composition (e.g. dissolution or adding another molecule or solvent), phase of matter, and/or microwave or radiofrequency irradiation. By way of example, many crystals have significantly longer relaxation time at higher magnetic fields and colder temperatures. Thus, for polarizing crystals, if the magnetic field used during the polarization was relatively small, where the relaxation time of the crystal is short, transferring the hyperpolarized solid catalyst and the crystal in contact to a higher magnetic field may allow for more time for the transfer of the polarization from the solid catalyst to the crystal while limiting loss of polarization due to relaxation effect.

The change of conditions between the polarization of the solid catalyst and the transfer to the target particle can be done in several ways. For example, the change of conditions can be done by shuttling or transporting the solid catalyst from the polarization condition to the transfer condition, either with the target material or adding the target material to the solid catalyst in the transfer condition. In some embodiments, the magnetic field between the polarization condition and transfer condition may be kept above a minimum value, such as above about 0.005 T, above about 0.05 T, or above about 0.5 T. In other embodiments, the change of conditions may be achieved by keeping the solid catalyst in place and varying the parameters from the polarization condition to the transfer condition (for example, by field cycling, adding a cooling reservoir, etc.).

The polarization transfer from the solid catalyst to the target material may be done by spin diffusion, where the polarization of the solid catalyst nuclear spins may diffuse to the nuclear spins in the target material, thus achieving hyperpolarization. In another embodiment, the polarization transfer may be mediated by cross polarization (CP) between the nuclear spins of the solid catalyst and the nuclear spins of the target material. In another embodiment, the polarization from the solid catalyst may be transferred to another spin species in the target material which may then be transferred to the target nuclear spins by CP. For example, the polarization may first be transferred to hydrogen spins in the target material and from them to ¹³C spins in the target material.

In some embodiments, the electron spins on the surface of the diamond may be actively decoupled from the nuclear spins, thus reducing their induced relaxation. This can be done by driving the electron spins with a microwave or rf irradiation at their Larmor frequency or energy transition frequencies (in the case there is a strong hyperfine splitting or spin 1 electron spin). In other embodiments, the polarization in the target particle may be built up over several cycles of catalyst nuclear polarization and transfer to the target material. This solution may be particularly enticing when the polarization transfer in the transfer condition is not optimal, and the average polarization of the target material spins is still substantially lower than the average polarization of the solid catalyst at the end of the polarization transfer.

In some embodiments, the target material may be in contact with the solid catalyst in the transfer between the polarization condition and the transfer condition. In this case, the target material relaxation time in the polarization condition may be sufficiently long not to lose most of its polarization while the solid catalyst nuclear spins are being polarized. Under this condition, multiple repetitions of the polarization and transfer steps may result in a higher build-up of polarization in the target material. In another embodiment, the target material may be kept at the transfer condition while the solid catalyst is transferred back to the polarization condition. As such, the target material may not experience adverse effects such as heightened relaxation from being transferred to the polarization condition.

When the solid catalyst comprises a diamond, several methods may be used to incorporate NV centers in a high concentration into the diamond. In one embodiment, nitrogen ions may be implanted into the diamond, with the depth of the NV controlled by the energy of the ions in the implantation. In another embodiment, the NV centers may be arranged throughout the diamond, or at least throughout the nanostructures, enabling the buildup of polarization in the diamond nuclear spins. In another embodiment, the nitrogen in the diamond may be introduced via nitrogen-rich growth by chemical vapor deposition (CVD), in a concentration of at least 1 ppm or at least 10 ppm. In one embodiment, this nitrogen rich layer can be grown in a thick layer on top of a diamond substrate and subsequently nanostructured, thus resulting in nitrogen incorporated throughout the nanostructures. In another preferred embodiment, the diamond may first be nanostructured and then the nitrogen may be incorporated by a CVD overgrowth of the nanostructures. This overgrowth may have a particular orientation (e.g. 111 or 100) to generate nicely faceted structure side-walls. In another embodiment, the starting diamond material may already have a high nitrogen concentration in a concentration of at least 1 ppm or at least 10 ppm. In some embodiments, the NVs can then be activated by electron irradiation or implantation of atoms generating vacancies, such as helium, hydrogen, carbon, and can be followed by annealing of the diamond.

In order to prepare the diamond for hyperpolarization, the diamond may be produced by high temperature (HPHT) growth with a high concentration of nitrogen (e.g. 50 ppm, standard for this type of growth). The diamond may then be irradiated with about 2 MeV electrons to create vacancies throughout the diamond in order to activate the NV centers. Following the irradiation, the diamond may be cleaned in acid and annealed at 1200° C. For enlarging the diamond surface, the diamond may be nanostructured by placing resist and patterning nanoslits using e-beam lithography, exposing the resist, evaporating chromium, and using a lift off process. The etching may be performed with an Inductively Coupled Plasma (ICP) Etch.

The target material for hyperpolarization may comprise solid urea, which has a long relaxation time for carbon spins at room temperature. The urea may be melted in a hot plate and then deposited to solidify on the nanostructured diamond. The diamond may be polarized by using the NOVEL dynamic nuclear polarization (DNP) protocol for fast polarization, which may build up polarization within about 1 minute under predetermined conditions. The predetermined conditions may comprise, for example, a magnetic field of about 0.4 T and a temperature around room temperature. The nanostructured diamond together with the solid urea may then be shuttled with a shuttle within about 0.5 seconds to the transfer condition. The magnetic field during the shuttling may be kept higher than 0.2 T. During the transfer of polarization, the nanostructured diamond together with the solid urea may be kept at 1.2 T magnetic field and a temperature under −70° C. in order to prolong the relaxation time of the ¹³C nuclear spins.

Conventional dissolution DNP uses molecules with electron radicals, and thus, the molecules do not polarize efficiently when the material to be polarized is a crystalline solid because the radical molecules are expelled from the crystal instead of being uniformly distributed. Thus, when cooling to cryogenic temperatures, the sample glassifies instead of crystalizing. In contrast, when using a solid catalyst with optically polarizable electron spins, the catalyst features, such as nanostructures or micro- or nano-particles, may typically be on the order of larger than 10 nm, sometimes larger than 100 nm or 1 micrometer. The distance between the solid catalyst features may also be typically on the same order as the size of the features. Thus, when a sample crystallizes, the solid catalyst may not be automatically expelled and may still crystalize while being in contact with the solid catalyst. As such, the sample may be crystallized to a polycrystalline or a powder of nano- or micro-crystals. Both polycrystalline and powder samples can be polarized.

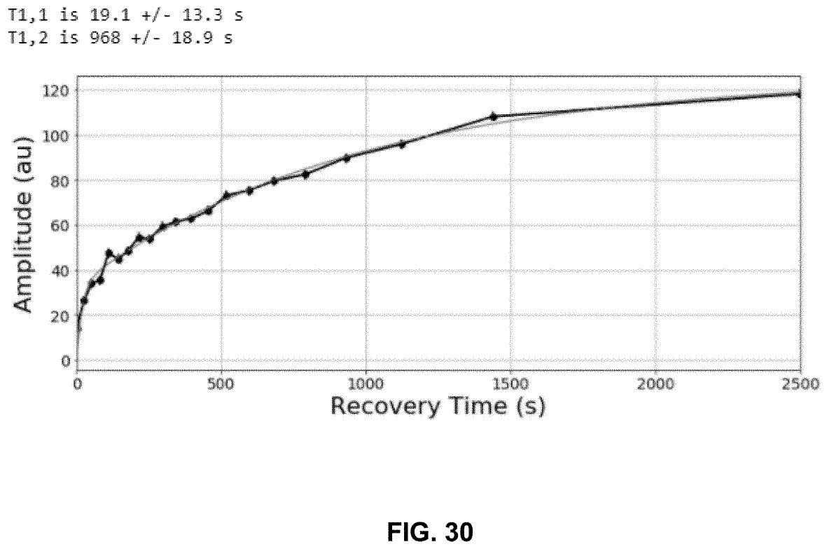

A key advantage of performing the polarization in the crystal form of the target material may be that the relaxation time of its nuclear spins is typically much longer than in the glassy state. For example, FIG. 30 illustrates the relaxation time of polycrystalline urea. As shown in FIG. 30, polycrystalline urea may have a relaxation time at 1.3 T that can be fit to a biexponential fit with the long relaxation component being longer than 900 seconds at room temperature. Urea is a key molecule of interest for hyperpolarized MRI. After the polarization in the crystal solid state it can be dissolved in water or another solvent, and injected. In other embodiments, other molecules, such as fumaric acid, which have a long nuclear spin relaxation time in the crystal state and which can be dissolved rapidly for injection may be used in hyperpolarized MRI.

The method of hyperpolarization in the present disclosure may also be used in hyperpolarized NMR. For example, water may be used as a hyperpolarization agent which can exchange protons with other molecules of interest. Water can be polarized as ice (its crystal phase) which has a significantly longer relaxation time for a large regime of temperature and magnetic field.

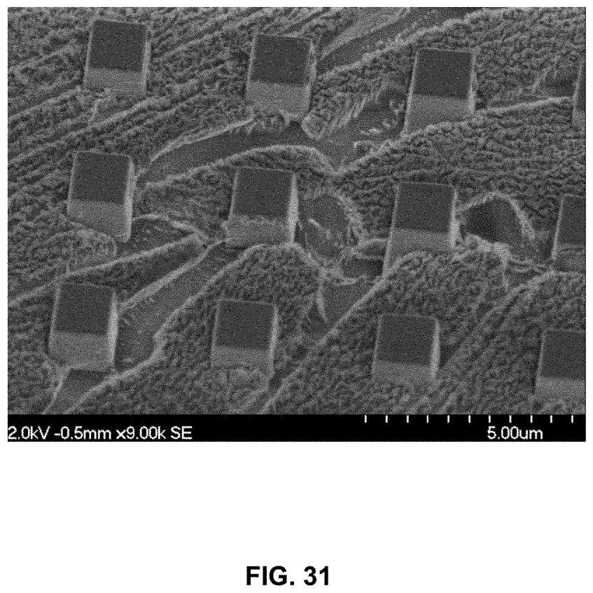

Moreover, crystalline urea may wet diamond nanostructures. FIG. 31 shows a scanning electron microscope (SEM) image of urea filling the area between micropillars. Urea was melted at 200° C., placed on a nanostructured diamond (4 micrometer pitch, average 2 micrometer pillars) and allowed to crystallize. As seen in FIG. 31, the urea filled the area between the pillars. The crystalline urea may also be in contact with the diamond even on the nanometer scale.

As this polarization process is not temperature dependent, and can be tailored to the properties of the target material, it can be performed at any temperature, for example between 0.5K and 400K. In some embodiments, the target material may crystallize at the temperature where the polarization is performed. In another embodiment, the target material may be mixed with a solvent or doped with molecules which may help produce the crystallization at the temperature used for polarization. As the magnetic field for the polarization can also be chosen in quite a large range, such as between 1 mT and 3 T), it can also be chosen in a way which may be suited to a long relaxation time for the target molecule in the crystal phase.

Another advantage of polarization via diamond or other solid catalyst with optically polarizable electron spin is the fact that due to its large features, the diamond or other solid catalysts with optically polarizable electron spins may not significantly decrease the relaxation time of the target molecule as compared to molecules with electron radicals. This may have significant implications on the possibility to transport the hyperpolarized material after the polarization and before the dissolution. In some embodiment, the hyperpolarized material may be transported while still in contact with the solid catalyst at temperatures above about 30 K, above about 70 K, above about 200 K, or at room temperature, while keeping a relaxation time above about 10 seconds, above about 100 seconds, or above about 500 seconds. The magnetic field during the transport can be chosen to optimize this relaxation time and may be below about 7 T, below about 3 T where permanent magnets are possible, or below about 1.5 T.

In some embodiments, a solid catalyst may be optically hyperpolarized, with a temperature above about 70 K, and then the hyperpolarization may be transferred to nuclei of a sample in contact with the solid catalyst. In some embodiments, the sample may include, but is not limited to, [1-¹³C]pyruvate, [2-¹³C]pyruvate, ¹³C-Enriched Bicarbonate, [1,4-¹³C₂]fumarate, [1-¹³C]lactate, [5-¹³C]glutamine, [1-¹³C]acetate, [2-¹³C]-fructose, [1-¹³C]succinate, [1-¹³C]-α-ketoisocaproate, ¹³C-choline/¹⁵N-choline and glucose derivatives ([1-¹³C]glucose and [6,6-²H₂]glucose). In certain embodiments, the sample may comprise non-metabolic molecules under investigation for hyperpolarized imaging, such as the reporter probe 3,5-Difluorobenzoyl-L-glutamic Acid, ¹³C Urea or [13C, 15N] Urea. The sample may then be extracted. For example, the sample may be dissolved in water or some other sterile fluid and used for detecting tissue characteristics. The temperature may need to be controlled in order to make sure that the temperature of the sample does not vary by too many degrees from the chosen temperature. Solid catalysts with optically hyperpolarizable electron spins may provide a high-polarization source which can be transferred to nuclear spins. This is a key advantage because the polarization source may be independent of the temperature and magnetic field. The optical irradiation of the electron spins can be achieved by several optical sources, such as lasers and LEDs, because optically polarizable electron spins can absorb a relatively wide range of optical wavelength spectrum.

In order to make the system cost effective and easy to use, temperatures reachable with liquid nitrogen may be used, but lower temperatures may also be used. In some embodiments, temperature lower than room temperature may be beneficial for prolonging the nuclear relaxation time, for reducing the diffusion coefficient of the molecules, or for changing the phase of the molecules (e.g. to solid).

In some embodiments, the polarization transfer can be performed directly, for example, by transferring the polarization from the optically polarizable electron spin directly to nuclear spins in the molecule. In other embodiments, the polarization transfer may be performed by using mediator spins, such as electron spins or nuclear spins. These mediators can be located within the solid catalyst or outside the solid catalyst. In other embodiments, the polarization transfer may be performed by building up polarization in one species, e.g. nuclear spins within the solid catalyst, which may then be transferred outside, for example, by nuclear spin diffusion or cross polarization. In some embodiments, a combination of the aforementioned methods can be used. By way of example, the polarization transfer may be performed by hyperpolarizing the nuclear spins within the solid catalyst by using mediating electron spins, and then allowing the polarization of the nuclear spins to diffuse to the nuclear spins in the surrounding molecules. The optical polarization of the electron spins in the solid catalyst and the transferring of polarization to nuclear spins can be done repeatedly, thereby building up polarization.

In some embodiments, shallow NV centers in a diamond may be used to provide fast polarization of molecules. For example, fast polarization transfer from near-surface NV centers, about 5 nm deep, to surrounding molecules, such as oil or pyruvate molecules may be performed. The NV center may be polarized, via a short laser pulse, such as laser pulse of less than 1 ρs, to over 90% polarization. Then, the polarization may be transferred through a spin-locking sequence. The spin-locking may tune the NV center spin evolution in a rotating basis such that the transition between two “dressed states” can achieve resonance with the Larmor frequency of the surrounding nuclear spins. In the case of a resonance, this may induce polarization transfer, which can be seen by reading out optically the NV spin state following the polarization transfer. The polarization transfer may be very fast, for example, taking less than 20 ρs, and coupled with a fast laser initialization, over 50,000 polarization transfer cycles can be performed in a single second. This may allow more than 10% polarization of pyruvic acid to be achieved within a few minutes when combined with nanostructuring of the diamonds.

In some embodiments, the sample may be cooled to a temperature significantly below room temperature, such as about 70 to about 250 K. By cooling the sample, the molecular motion of the sample may be greatly diminished, especially if the sample crystallizes or glassifies at the chosen temperature, thereby making the polarization transfer more efficient. In addition, by cooling the sample, the relaxation time of the nuclear spins in both the target sample and the diamond can be significantly prolonged, thus enabling higher polarization. Moreover, by cooling the sample, the NV center relaxation and coherence time may be prolonged. Furthermore, by cooling the sample, electron spins on the diamond surface, which may cause relaxation of nuclear spins and inhibit diffusion of polarization across the diamond surface, may have longer relaxation time, which may improve the decoupling of electron spins from the nuclear spins.

In some embodiments, the distance between the diamond surfaces (e.g. between the nanostructures or between the nano- or micro- particles) can be large. For example, the distance may be more than about 10 nm, more than about 100 nm, or more than about 1 micrometer. Moreover, the diamond features themselves may be very large, for example, on the hundreds of nanometer to micrometers scale. Thus, the diamond may not automatically be ejected in case the material crystallizes, compared to molecules with free radical electron spins used in standard dissolution DNP.

In order to maintain the temperature below room temperature, a cooler may be used. The cooler may be configured to lower a temperature of the sample and/or the solid catalyst to a temperature in a range of about 70K and about 250K, in a range of about 70K and about 220K, in a range of about 70K and about 200K, or in a range of about 70K and about 120K. The sample may be flowable. In other embodiments, the sample may include one or more particles. For mildly low temperatures, for example, above −80° C., the cooler may comprise chillers, ice, or dry ice. For lower temperatures, the cooler may comprise liquid nitrogen, either in liquid form or as cold nitrogen gas. In some embodiments, a cooler may comprise a cryostat. In some embodiments, a temperature sensor may be located in proximity to the sample location in order to monitor and control temperature. In order to polarize the electron spins in the solid catalyst, an optical source may be used. The optical source may comprise lasers, diode laser, or light emitting diodes (LEDs).

In order to maximize the effect of hyperpolarization during imaging or spectroscopy, the time between hyperpolarization and MR detection may be minimized. Therefore, a hyperpolarization reaction chamber may be provided that may shuttle the target material together with the solid catalyst back and forth between a hyperpolarizer and an external module for heating or dissolution. The target material may be separable from the solid catalyst.

In accordance with the embodiments of the present disclosure, a method of detecting tissue characteristics may be provided. For example, the method may comprise optically polarizing a diamond, or any other polarization structure or solid catalyst, and exposing the polarized diamond to a biocompatible material having polarizable nuclear spins to thereby transfer the nuclear spins to the biocompatible material, thereby resulting in a hyperpolarized material. The method may further comprise dissolving the hyperpolarized material in a sterile fluid to form a solution, injecting the solution into the mammal, and obtaining a magnetic image of tissue of the mammal by detecting the hyperpolarized material in the tissue.

In some embodiments, the tissue may include a blood vessel. In other embodiments, obtaining the magnetic image of the tissue may occur by detecting the hyperpolarized material metabolized by the tissue. In some embodiments, the solution may be injected into the mammal within 5 minutes of dissolving the hyperpolarizing agent in the sterile fluid. In some embodiments, the biocompatible material may be endogenous. In other embodiments, the solution may be injected into the mammal within 3 minutes, or within 1 minute, of dissolving the hyperpolarizing agent in the sterile fluid. In some embodiments, the etched diamond may host defects, and optically polarizing the etched diamond may further include optically polarizing electron spins of the defects. The hosted defects may be located on at least one surface of the etched diamond. In some embodiments, the hosted defects may comprise NV centers. In some embodiments, the diamond, or the polarization structure or the solid catalyst, may host defects on at least one surface thereof and/or include a plurality of layers.

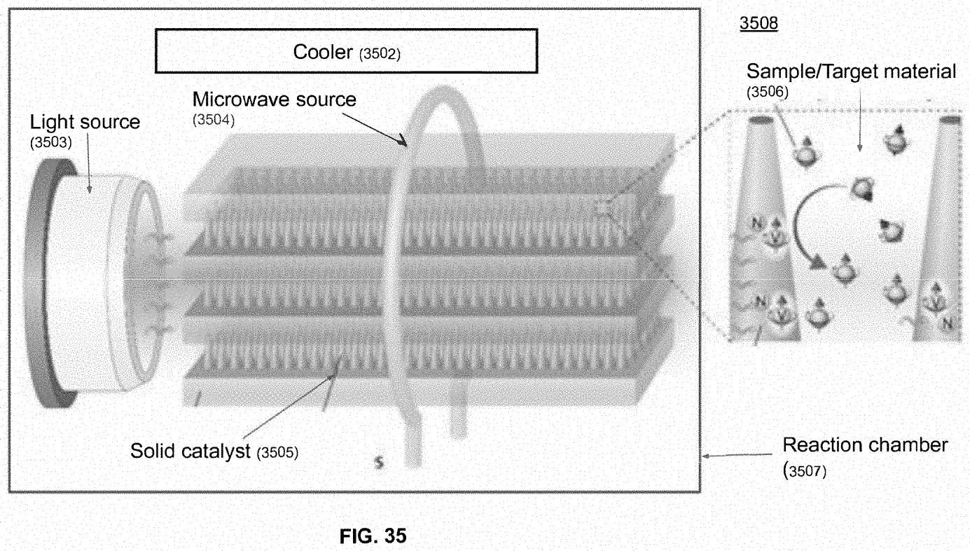

In accordance with the embodiments of the present disclosure, a hyperpolarization system may be provided, which may also be referred to herein as a hyperpolarizing system. For example, referring to FIG. 35, a hyperpolarization system 3508 may comprise a hyperpolarization reaction chamber 3507. The hyperpolarization reaction chamber 3507 may house a solid catalyst 3505 that provides the polarization source, a sample 3506 configured to be in contact with the solid catalyst 3505, and a microwave source 3504 configured to facilitate polarization transfer from the solid catalyst 3505 to the sample 3606. The solid catalyst 3505 may comprise a polarization structure, a semiconductor structure, a catalyst material, a nanoscopic three-dimensional structure, or any material comprising color centers with polarizable electron spins. In some embodiments, the hyperpolarization reaction chamber 3507 may have a location therein for supporting the solid catalyst 3505. In some embodiments, the solid catalyst 3505 may have the sample 3506 in contact therewith. In other embodiments, the sample may not be in contact with the solid catalyst in the hyperpolarization reaction chamber. The sample may be a solid sample, a flowable sample, such as a liquid sample, or a sample with particles, such as a liquid sample with particles. In addition, the hyperpolarization system 3508 may comprise an extraction chamber (not shown in FIG. 35) configured to extract the sample 3506 from the solid catalyst 3505 either in neat undiluted form or concurrently with dilution, and a tunnel, a conveyor, or a shuttle configured to connect the extraction chamber to the hyperpolarization reaction chamber 3507. The conveyor may be configured to cyclically shuttle the sample between the hyperpolarization reaction chamber 3507 and a magnetic resonance detector.

In some embodiments, the hyperpolarization reaction chamber 3507 may house an optical light source 3503 configured to irradiate the electron spins inside the solid catalyst 3505 with monochromatic light. The optical light source 3503 may include, but is not limited to, one or more lasers, such as a 538 nm laser, one or more light emitting diodes (LEDs), or other light sources with a suitable wavelength (e.g. green light for NV centers in diamond, infrared and red for silicon vacancy in silicon carbide). In some embodiments, the optical light source 3503 may be configured to generate non-collimated light. In other embodiments, the optical light source 3503 may be configured to emit green light.

In some embodiments, the hyperpolarization system 3508 may also comprise a microprocessor (not shown) configured to control an actuator to move the sample 3506 and solid catalyst 3505 from one chamber to the other in a controlled manner. Additionally, the system 3508 may further comprise a capsule (not shown) configured to support the sample 3506 in contact solid catalyst 3505 and that may be compatible with both the hyperpolarization system 3508 and the extraction system to assist in the extraction of the sample 3506 from the solid catalyst 3505.

In some embodiments, the sample 3506 may need to be in contact with the solid catalyst 3505, and the temperature of the sample 3506 may need to be maintained below a predetermined temperature. The temperature of the sample 3506 may need to be below the sample's 3506 melting point, or below the sample's 3506 glass transition temperature. In some embodiments, the temperature of the sample 3506 may need to be maintained at a low enough temperature such that the liquid is very viscous. The extraction chamber may therefore bring the temperature of the sample 3506 to its final operating temperature during the extraction process. In some embodiments, the hyperpolarization reaction chamber 3507 may further comprise a cooler 3502 configured to lower the temperature of the solid catalyst 3505 and/or the sample 3506. The cooler, for example, may comprise chillers, ice, dry ice, liquid nitrogen, either in liquid form or as cold nitrogen gas, or a cryostat. In some embodiments, the temperature in the tunnel may be at a higher temperature than the temperature of the sample 3506 to ensure sufficient heat transfer to the target during its transit to the extraction chamber. Furthermore, the optimal magnetic field strength required for polarization and that required for efficient transmission and extraction may be different. As such the system may have different magnetic fields and temperature profiles as the target is transported from the hyperpolarization reaction chamber 3507 via the tunnel to the extraction chamber.

In some embodiments, permanent magnets may be used to provide the magnetic field in the tunnel and in the extraction chamber. The distance between the hyperpolarization reaction chamber 3507 and the extraction chamber may be less than about 2000 cm, less than about 200 cm, less than about 20 cm, or less than about 10 cm. In some embodiments, the extraction chamber, hyperpolarization reaction chamber 3507, and tunnel may be parts of a single entity.

The sample 3506, once inside the extraction chamber, can be removed from the solid catalyst 3505 in the liquid state. The liquid state can be reached either by dissolving the sample 3506 in a carrier fluid or by forcing the undiluted liquid out of the capsule that houses the solid catalyst 3505 and sample 3506. In one embodiment, the sample 3506 may be extracted as a neat liquid into a collection chamber containing a carrier fluid. In another embodiment, the carrier fluid may be injected into the capsule holding the sample 3506 and the diluted target may be extracted into a vessel.

The hyperpolarized state of the sample may have a finite lifetime. Accordingly, a rapid transport of the sample to the extraction chamber may be essential. For example, the sample may need to be transported to the extraction chamber in less than about 10 s, less than about 1 s, or less than about 0.1 s.

In one embodiment, the capsule may be made of a microwave-compatible material that supports the target material and solid catalyst. The capsule may be attached onto a rigid rod that can also transmit the light needed for the polarization procedure. The rod may be attached to an actuator that is transported via a microprocessor-controller motorized linear stage. In one embodiment, the capsule can be made of a plastic such as PTFE or the capsule can be made of a ceramic or glass. In another embodiment, the capsule may assist in aligning the solid catalyst in the hyperpolarization reaction chamber for optimal hyperpolarization. In another embodiment the capsule may be attached at the end of a flexible rod that can also transmit light required for the hyperpolarization. The capsule may also be configured to align the solid catalyst within a guiding tube that may steer the sample from the hyperpolarization reaction chamber to the extraction chamber. In one embodiment, the capsule may comprise one or more ports for transport of fluid into and out of the chamber that holds the target material. Additionally or alternatively, the capsule may comprise one or more ports for transport of gas to assist in extracting the target material. The gas may also be heated to aid in melting and transport. In another embodiment, the extraction chamber may comprise corresponding ports to provide the fluid, liquid or gas, for the extraction of the target material. In another embodiment, the extraction chamber may comprise one or more needles to pierce one or more holes into the capsule to extract the target. In another embodiment, the liquid may be extracted into a vessel by a vacuum.

Additionally or alternatively, the extraction chamber may house a collection device to capture the extracted target material. Understanding that the target material may be used in clinical applications, in one embodiment, the collection device and fluid path may be sterilized. Furthermore, the capsule support the target material and solid catalyst may also be sterilized.

In another embodiment, a temperature probe may be mounted near or on the target material or solid catalyst to monitor the temperature during hyperpolarization, transport and extraction. Additionally or alternatively, the system may comprise a microprocessor to read out the temperature and adjust the rate of transit through the tunnel. Since the extraction must happen as quickly as possible, the tunnel temperature may be maintained at a temperature higher than the melting point of the target material. The temperature of the tunnel may be about 10 K higher than the melting point, about 50K higher, or about 100K higher. The microprocessor-controlled system can move the target slowly through the high-temperature tunnel until the temperature probe detects that melting has occurred. At that point, the sample can be rapidly transported for extraction. In another embodiment, a temperature gradient may exist along the tunnel. In yet another embodiment, a temperature sensor and a heater may be incorporated into the capsule to directly heat the solid catalyst and the target material.

In another embodiment, the extraction chamber may comprise a magnetic resonance detector, such as a spectrometer that can be used to assess the polarization state of the target material or the solid catalyst. In one embodiment, the spectrometer may comprise at least one microprocessor configured to assess whether the target is sufficiently polarized and return the sample to the hyperpolarization reaction chamber for additional cycles. By way of example, if the target is sufficiently polarized, the microprocessor can activate the extraction mechanism.

In another embodiment, a hyperpolarizing system may be provided, comprising a hyperpolarization reaction chamber having a location therein for supporting a solid catalyst, a cooler configured to lower a temperature in the hyperpolarization reaction chamber, and an LED source configured to direct light energy toward the solid catalyst to thereby hyperpolarize electrons in the solid catalyst and facilitate transfer of hyperpolarization of the electrons to nuclei of a flowable sample. The LED source may be configured to direct at least 1 Watt of light energy, at least 2 Watt of light energy, or at least 10 Watt of light energy. In some embodiments, the hyperpolarizing system may comprise a plurality of LED sources in differing locations for irradiating a common target.

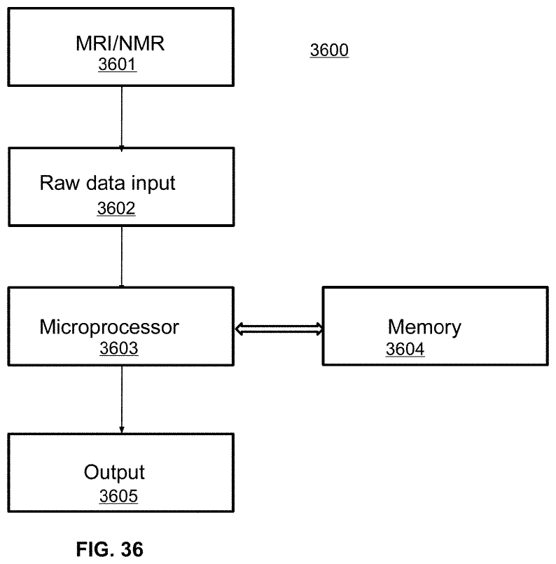

In some embodiments, the cooler may further be configured to lower the temperature to a temperature above 70K. In other embodiments, the hyperpolarizing system may comprise at least one processor for controlling at least one of the LED source or the cooler in a manner facilitating transfer of hyperpolarization to the nuclei of the flowable sample. The at least one processor may also be configured to control at least one of the LED source, the cooler, or a flow of the sample in order to achieve hyperpolarization of the sample. For example, the at least one processor may be configured to control the LED source, such that the LED source directs pulses of light energy toward the solid catalyst. The at least one processor may also be configured to control the LED source, such that the LED source directs continuous light energy toward the solid catalyst. FIG. 36 illustrates an exemplary schematic diagram of a system for providing metabolic information, in accordance with the embodiments of the present disclosure. Referring to FIG. 36, a system 3600 may be configured for interpreting noisy magnetic resonance (MR) signals. In some embodiments, system 3600 may comprise an imaging system 3601. The imaging system 3601 may comprise, for example, an MRI imaging system or an NMR spectrometer. Raw input data 3602 acquired by the imaging system 3601 may be transmitted to a processor or microprocessor 3603. The raw input data 3602 may comprise, for example, an MR signal and/or a plurality of MR measurements of a body, tissue, and/or cell acquired following introduction of a metabolic agent. For example, the raw input data 3602 may comprise an MRI image of the body or the tissue and/or a hyperpolarized MRI data. The raw input data 3602 may be acquired at a different time following the introduction of the metabolic agent. For example, a plurality of MR measurements of the tissue may be taken at a different time following the introduction of the metabolic agent. The MR signal and/or the plurality of MR measurements may comprise a signal and/or a noise. The noise in the MR signal and/or the plurality of MR measurements may mask key metabolic information in the signal.

In some embodiments, the microprocessor 3603 may receive the raw input data 3602 from the imaging system 3601 and analyse the raw input data 3602. For example, the microprocessor 3603 may access one or more information stored in memory 3604. By way of example, the microprocessor 3603 may access one or more metabolic cascade information stored in the memory 3604 to determine an expected response to the introduction of the metabolic agent. In some embodiments, memory 3604 may also store decay patterns. In some embodiments, the metabolic agent may comprise pyruvate. Memory 3604 may include one or more storage devices configured to store instructions used by the microprocessor 3603 to perform functions related to the disclosed embodiments. For example, memory 3604 may be configured with one or more software instructions, such as program(s) that may perform one or more operations when executed by the microprocessor 3603. Memory 3604 may be a volatile or non-volatile, magnetic, semiconductor, tape, optical, removable, non-removable, or other type of storage device or tangible (e.g., non-transitory) computer-readable medium.

In some embodiments, the microprocessor 3603 may use the metabolic cascade information stored in the memory 3604 and the raw input data 3602 to extract, from the raw input data 3602, the masked key metabolic information. By way of example, the microprocessor 3603 may use the metabolic cascade information stored in the memory 3604 to amplify the metabolic information masked in the raw input data 3602. In other embodiments, the microprocessor 3603 may use the metabolic cascade information stored in the memory 3604 to enhance a contrast in the raw input data 3602, such as an MRI image of the metabolic information. In some embodiments, the masked key metabolic information in the raw input data 3602 may be associated with a metabolic rate of metabolites, such as lactate, in the tissue.

In some embodiments, the microprocessor 3603 may extract the masked key metabolic information from the raw input data 3602 by applying a statistical model to the raw input data 3602, which may include prior for the conversion rates between different metabolites. The statistical model used may comprise, for example, a Bayesian inference model. In some embodiments, the microprocessor 3603 may analyze together the posterior distributions for the conversion rates from the individual voxels in a second statistical model. In other embodiments, the microprocessor 3603 may utilize data from proton MRI images as priors for the statistical model of the raw input data 3602, such as a hyperpolarized MRI data.

Once the microprocessor 3603 has acquired the masked key metabolic information from the raw input data 3602, the microprocessor 3603 may transmit the key metabolic information as an output 3605. By way of example, the microprocessor 3603 may output the key metabolic information by displaying the metabolic information in a numerical format or a graphical format, or as an image.

In accordance with another embodiment of the present disclosure, a spectroscopy system may be provided. The spectroscopy system may comprise a magnetic resonance detector configured to obtain a spectrum of a sample optically excited by a solid catalyst. In some embodiments, the spectroscopy system may comprise an exciter for optically hyperpolarizing the sample in contact with the solid catalyst. The spectroscopy system may further comprise at least one temperature regulator for altering a temperature of the sample to cause the sample to reach a first temperature between about 70K and 250K prior to hyperpolarization by the exciter, and to reach a second temperature, higher than the first temperature, after hyperpolarization and before obtaining the spectrum of the sample.

In some embodiments, the solid catalyst may be further configured to detect a magnetic resonance of the sample. The spectroscopy system may further comprise a user interface configured to allow a user to identify a hyperpolarization solvent, and a processor for automatically adjusting the first and second temperatures based on the identified solvent. The second temperature may be greater than the first temperature by at least 100 degrees, by at least 30 degrees, by at least 20 degrees, or by at least 10 degrees. In some embodiments, the spectroscopy system may further comprise a shuttle for moving the sample between the magnetic resonance detector and the exciter. The temperature regulator may be further configured to alter the temperature of the sample during shuttling.

In accordance with another embodiment of the present disclosure, a method for perform an NMR detection of a hyperpolarized sample from a solid catalyst with minimal loss of polarization is provided. Temperature plays an important role in both the polarization, which requires long nuclear spin relaxation time and a viscous or solid target material, and in the NMR readout, which typically produces narrower spectra with better signal to noise ratio (SNR) for less viscous solutions. For this reason, the temperature at time of hyperpolarization may typically be lower than the temperature at time of detection. The ability to perform several repetitions of the polarization and readout may be important for high-end hyperpolarized NMR in order to perform signal averaging and increase the SNR. Thus, the method may require no dissolution with an added solution which may dilute the sample.

While changing the temperature before hyperpolarization can be a slower process, the temperature change before NMR readout may need to be very quick, for example, within about 30 seconds, within about 3 seconds, or within about 0.3 seconds. By quickly changing the temperature of a sample hyperpolarized and in contact with the solid catalyst, one can rapidly heat up the entire target material by heating an area of the solid catalyst, particularly if the solid catalyst has a high thermal diffusion coefficient, e.g. if the solid catalyst is diamond. Moreover, for efficient polarization transfer, most of the target material to be hyperpolarized may be at most about 20 micrometers, about 2 micrometers, or less than about 200 nm from a diamond surface. Therefore, even if the target material has a much lower thermal diffusion than the solid catalyst, the diffusion distance in the target material may be very short, and thus, the target material may still be effectively heated in a short amount of time.

In one embodiment, a polarization system may comprise a solid catalyst that provides the polarization source, a target material configured to be in contact with the solid catalyst, a hyperpolarization reaction chamber configured to polarize the target material via the solid catalyst, a heating element configured to heat the catalyst and target material, and a cooling element configured to cool the catalyst and target material. Additionally or alternatively, the system may comprise a capsule configured to support the target material in contact solid catalyst and which may be compatible with both the hyperpolarization system and the NMR system, and can assist in the heating and cooling of the target material and solid catalyst.

The hyperpolarization process, described above, requires that the target material is in contact with the solid catalyst, and may require maintaining the temperature of the target material below the temperature that it will be used. This may be below its melting point, or below its glass transition temperature or at a low enough temperature that while liquid is very viscous. The heating system must therefore bring the temperature of the sample to its final operating temperature during the NMR measurement. This may require that the temperature in the tunnel is at a third, higher temperature to ensure sufficient heat transfer to the target during its transit to the extraction chamber. Furthermore, the optimal magnetic field strength required for polarization and that required for the NMR detection may be different. As such the system may have different magnetic field and temperature profiles as the target is transported from the hyperpolarization module to the NMR spectrometer.

In some embodiments, the target material may need to be in contact with the solid catalyst, and the temperature of the target material may need to be maintained below a predetermined temperature. The temperature of the target material may need to be below the target material's melting point, or below the target material's glass transition temperature. In some embodiments, the temperature of the target material may need to be maintained at a low enough temperature such that the liquid is very viscous. The heating system may therefore bring the temperature of the sample to its final operating temperature during the NMR measurement. In some embodiments, the temperature in the tunnel may be at a higher temperature than the temperature of the sample to ensure sufficient heat transfer to the target during its transit to the extraction chamber. Furthermore, the optimal magnetic field strength required for polarization and that required for NMR detection may be different. As such the system may have different magnetic fields and temperature profiles as the target is transported from the hyperpolarization system to the NMR spectrometer.

In one embodiment, permanent magnets may be used to provide the magnetic field in the transport between the polarization chamber and the NMR spectrometer. The distance between the hyperpolarization reaction chamber and the NMR spectrometer may be less than about 2000 cm, less than about 200 cm, less than about 20 cm, or less than about 10 cm.

The hyperpolarized state of the target material may have a finite lifetime. Accordingly, a rapid transport of the target material to the NMR spectrometer may be essential. For example, the target material may need to be transported to the NMR spectrometer in less than about 10 s, less than about 1 s, or less than about 0.1 s.

In one embodiment, the capsule may be made of a microwave-compatible material that supports the target material and solid catalyst. The capsule may be attached onto a rigid rod that can also transmit the light needed for the polarization procedure. The rod may be attached to an actuator that is transported via a microprocessor-controller motorized linear stage. In one embodiment, the capsule can be made of a plastic such as PTFE or the capsule can be made of a ceramic or glass. In another embodiment, the capsule may assist in aligning the solid catalyst in the hyperpolarization reaction chamber for optimal hyperpolarization. In another embodiment, the capsule may be attached at the end of a flexible rod that can also transmit light required for the hyperpolarization. The capsule may also be configured to align the solid catalyst within a guiding tube that may steer the sample from the hyperpolarization reaction chamber to the NMR spectrometer.

In another embodiment, a temperature probe may be mounted near or on the target material or solid catalyst to monitor the temperature during hyperpolarization, transport and detection. Additionally or alternatively, the system may comprise a microprocessor to read out the temperature and adjust the rate of transit through the tunnel. In another embodiment, a temperature sensor and/or a heater may be incorporated into the capsule to heat the solid catalyst and the target material. In yet another embodiment, the heating element may be in the NMR spectrometer. In some embodiments, the material and the solid catalyst may be heated during the transport between the hyperpolarization reaction chamber and the NMR spectrometer. In other embodiments, after the heating of the target material and the solid catalyst, the target material may be separated from the solid catalyst before the NMR measurement. Following the NMR measurement, the target material and the solid catalyst may be transferred back into the hyperpolarization reaction chamber and cooled to a hyperpolarization temperature for repeated hyperpolarization.

In some embodiments, the NMR measurement may be performed by solid state spins. As such, electron spins in the solid catalyst may be used for both the hyperpolarization and the NMR measurement (some for polarization and other for detection). Additionally or alternatively, a different diamond or diamonds, or different areas in the same diamond could be used for the NMR measurement. As such, transfer may not be needed between the polarization and NMR measurement, and if needed, the transfer may be done using microfluidics or other modes of short-distance transport. In addition, the NMR measurement may be performed at almost any magnetic field between about 1 mT and about 10 T, given that the electron spins can still be driven with MW irradiation.

In some embodiments, a diamond polarizer for diamond-based DNP may comprise an electromagnet, highly flexible microwave control with an arbitrary waveform generator, a large-bandwidth MW resonator, and an optical source configured to provide optical excitation. The optical source may comprise a 3 W fiber-coupled laser. For polarization detection, an NMR spectrometer, such as a 1.2 T NMR spectrometer, may be used with a fast shuttling system configured to shuttle the diamond and/or the target material between the NMR spectrometer and the diamond polarizer within a predetermined period of time, such as less than about 200 mₛ. The bulk diamond may be hyperpolarized using a pulsed DNP method for about 5 minutes. The nuclear spin polarization can then be diffused out to polarize nuclear spins in external molecules or external materials.

In addition, as discussed above, the diamond cores may be nanostructured based on a dense nano-pillar array with shallow NV centers. The side wall of the nanostructures may be designed using dry etching. For example, very small features, for example with 600 nm pitch and 200-300 nm between pillars, can be created while keeping the pillar height at about 2-4 micrometers. As such, the surface of the diamond core may be increased to a 10-15 fold, which may be sufficient for polarizing large volumes of target material. The nanostructures may be implanted with N₂ ions, at for example 40 keV, to produce shallow NV centers on the side walls of the structures. Accordingly, dense ensembles of NV centers may be created on the side walls with over 100 ρs coherence time with spin-locking polarization protocols. Polarization may be transferred to external molecules and/or materials with the NV ensembles on nanostructured side-walls. By way of example, NV concentration in the nanopillars of about 0.5 ppm may result in 258,000 ¹³C nuclear spins per NV center. Given the polarization transfer rate of about 50,000 per second, polarization may only be limited by nuclear relaxation time and diffusion rate in the target material. Cooling the pyruvic acid for example to −50° C. may yield long relaxation times of more than 10 seconds in the supercooled liquid state, which may be sufficient for the polarization of about 200 nm pyruvic acid distance between the pillars. The supercooled liquid state may refer to a state, in which molecular diffusion homogenizes the polarization. On the other hand, cooling the pyruvate to liquid nitrogen temperatures may result in a glassy state where the relaxation time can be over several minutes long and the diffusion propagating through ¹³C-¹³C dipolar coupling.

In certain embodiments, the hyperpolarized molecules can be added to a subject in vivo or to tissue in vitro to enhance the contrast of an MRI or NMR image and highlighting specific processes. In certain embodiments, the hyperpolarized molecules may comprise molecules which have a sufficiently long hyperpolarization time and are involved in metabolic processes, including but not limit to [1-¹³C]pyruvate, ¹³C-Enriched Bicarbonate, [1,4-¹³C₂]fumarate, [1-¹³C]lactate, [5-¹³C]glutamine, [1-¹³C]acetate, [2-¹³C]-fructose, [1-¹³C]succinate, [1-¹³C]-α-ketoisocaproate, ¹³C-choline/¹⁵N-choline and glucose derivatives ([1-¹³C]glucose and [6,6-²H₂]glucose). In certain embodiments, the hyperpolarized molecules may comprise non-metabolic molecules under investigation for hyperpolarized imaging, such as the reporter probe 3,5-Difluorobenzoyl-L-glutamic Acid or ¹³C Urea.

In some embodiments, the diamond hyperpolarizer may be coupled to an MRI scanner for in vivo use or to a specially designed NMR probe for probing tissue by assessing their NMR spectroscopy after injecting a hyperpolarized metabolic substrate. As such, the diamond hyperpolarizer, in combination with the MRI scanner, may be capable of studying metabolic dynamics in mass-limited samples, including primary cancer cells in clinical biopsies. Therefore, the diamond hyperpolarizer, in combination with the MRI scanner, may provide novel therapeutic targets and enhanced understanding of cellular metabolism. In particular, because hyperpolarized micromagnetic resonance spectrometer (HMRS) systems require small quantities of hyperpolarized material, the diamond polarizer of the present disclosure may be more useful than larger polarizers for clinical MRI. By combining the diamond-based polarizer with an HMRS platform, an automated system for a high-throughput, real-time quantitative analysis of live cell metabolism may be provided.

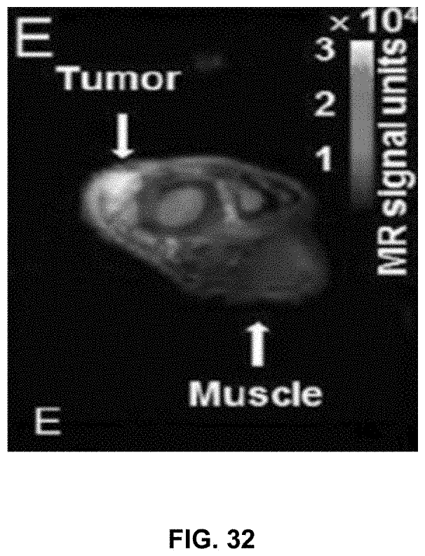

In some embodiments, after introducing a metabolic agent into a body, tissue or cells, we can use the metabolic cascade information, for example, the conversion mechanisms and rates from a metabolite to its derivatives, in order to extract relevant data from a noisy MR signal. MRI typically operates in voxels (3D pixels) which are then translated to an image. The hyperpolarized signal from the hyperpolarized metabolic molecules may provide information of areas with high metabolic activities which are overlaid on the anatomical MRI data. As such, each voxel may be assigned a number (the metabolic rate) which may be the value for the voxel in grayscale or heatmap that illustrates how metabolically active the tissue in that voxel is. For example, after delivery of hyperpolarized [1-13C] pyruvate, a hyperpolarized substrate, the molecule may be rapidly transported into cells on the monocarboxylate transporters (MCTs), where flux of ¹³C label into the endogenous lactate and alanine pools may be catalyzed by lactate dehydrogenase (LDH) and alanine aminotransferase, respectively. Measurements of hyperpolarized ¹³C label exchange between injected pyruvate and endogenous lactate may be suitable for tumor imaging since the lactate pool size is often large, due to the high levels of aerobic glycolysis displayed by tumors (the “Warburg effect”) and the high levels of expression of the MCTs and LDH. Several kinetic models have been used to analyze exchange of hyperpolarized ¹³C label between injected [1-13C]pyruvate and the endogenous lactate pool. This two-site exchange model, as well as unidirectional models, are sufficient to estimate the first-order rate constant, k_{P}, describing label flux between pyruvate and lactate. FIG. 32, for example, illustrates an anatomical image in an MRI of a canine leg, which is from Gutte, Henrik, et al. “Simultaneous hyperpolarized 13C-pyruvate MRI and 18F-FDG-PET in cancer (hyperPET): feasibility of a new imaging concept using a clinical PET/MRI scanner.” American journal of nuclear medicine and molecular imaging 5.1 (2015): 38. As seen in FIG. 32, the metabolic rate of the hyperpolarized pyruvate molecules to lactate appears to be strongest in the tumor area. Other metabolites as well have well studied models and metabolic kinetics. For example, in Keshari, Kayvan R., and David M. Wilson. “Chemistry and biochemistry of 13 C hyperpolarized magnetic resonance using dynamic nuclear polarization.” Chemical Society Reviews 43.5 (2014): 1627-1659, the metabolic cascade information of several useful hyperpolarized metabolic probes in presented in detail.

However, while the pyruvate signal is very strong, with a high signal to noise ratio (SNR), the lactate signal is typically between 10-100 fold smaller, resulting in a signal not much larger than the noise level. This noisy signal may lead to uncertainties in extracting the conversion rate and to high error rates when the signal is weak. Therefore, there is a need for an improved method of analysis as the data from the hyperpolarized signal of the pyruvate molecule is very rich, more than in standard MRI, and only a relatively small amount of it may be used to derive the metabolic rate for the voxel. In some embodiments, the semi-quantitative ratio between the lactate area under the curve (AUC) and pyruvate AUC may be used to correlate with the pyruvate to lactate conversion ratio. The underlying data may be used in order to provide the metabolic rate with higher fidelity with requiring less initial signal than currently needed. As such, the signal to noise (SNR) ratio may be improved.

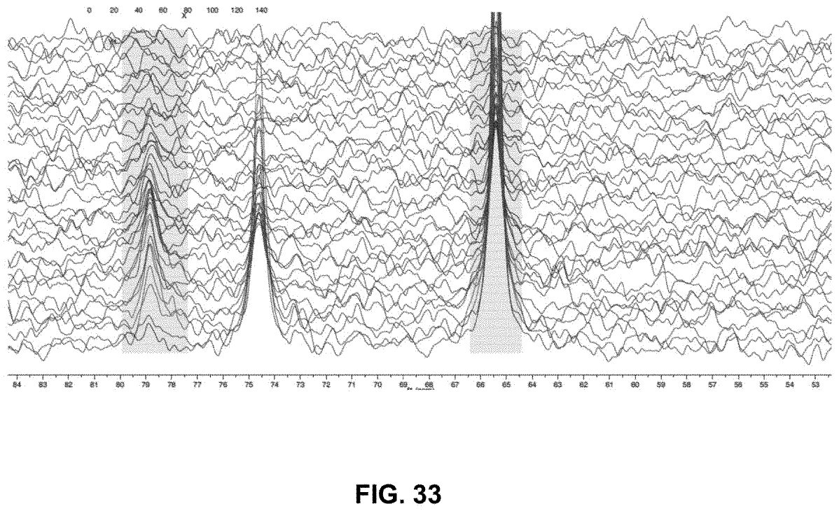

As an example, FIG. 33 illustrates an example of hyperpolarized pyruvate NMR spectroscopy, which corresponds to a single voxel in an MRI image. The x axis in FIG. 33 indicates the frequency of the magnetic resonance. When the pyruvate molecule is metabolized to a different molecule, its chemical shift may change, which may change the frequency of the peak. Thus, the x-axis location of the peak indicates which molecule is detected. The y axis in FIG. 33 indicates time—each line is a separate measurement, taken in intervals of 2 seconds between consecutive measurements. The evolution between the different measurements may provide the temporal information of the metabolic process. The z axis indicates the strength of the signal for measurement/molecule. As seen in FIG. 33, the rightmost peak that is the highest peak corresponds to pyruvate, and the leftmost peak corresponds to lactate. The middle peak corresponds to the pyruvate-hydrate artifact, which may not be involved in the metabolic dynamics. As can be seen in FIG. 33, the lactate signal (leftmost peak) is weak, and for a weaker initial pyruvate signal, the lactate peak becomes very similar to the noise level (SNR<=1). As such, the ratio of lactate AUC to pyruvate AUC may become very noisy and may not be a very good predictor of the metabolism.

Therefore, the fact that there are several temporally different measurements from a single injection of the hyperpolarized metabolite may be used to enhance the MR signal. The measurements may be analyzed together and the apriori knowledge that (1) in the 2D spectral-temporal signal there is only signal from a few molecules, making the signal sparse, and (2) as we have a model for how the metabolism behaves (see below example for hyperpolarized pyruvate) may be used. In addition, a statistical model, such as a Bayesian inference or maximum likelihood model, may be applied on the raw signal to extract the metabolic rate even for very noisy MR signals that may mask key metabolic information in the MR signals. As such, even if the signal to noise ratio on the individual measurements of the lactate peak is too low to use or even identify the signal peaks, by utilizing the information of all the measurements together and using our apriori knowledge of the metabolic cascade, the parameters may be extracted with higher fidelity. For example, using the metabolic cascade information stored in memory and/or the plurality of MR measurements, the masked key metabolic information may be extracted from the MR signals. In some embodiments, the information from many voxels together in the Bayesian inference model may be used together, instead of analyzing the voxels individually, thereby improving the data analysis further.

By way of example, on the single-voxel data set above, using the statistical model, the metabolic rate could be extracted for at least 5 times weaker signals than with the standard analysis, and can be optimized further. To model the data, the following differential equations may need to be taken into consideration.

$$\frac{{dM}_{z}^{pyt} ( t )}{dt} = - k \cdot {M}_{z}^{pyr} ( t ) - \frac{1}{{T}_{1}^{pyr}} \cdot {M}_{z}^{pyr} ( t ) - {( 1 - cos θ )}^{1 / TR} \cdot {M}_{z}^{pyr} ( t )$$

$$\frac{{dM}_{z}^{lac} ( t )}{dt} = k \cdot {M}_{z}^{pyr} ( t ) - \frac{1}{{T}_{1}^{lac}} \cdot {M}_{z}^{lac} ( t ) - {( 1 - cos θ )}^{1 / TR} \cdot {M}_{z}^{lac} ( t ) ,$$

where T₁ₛ denote the respective relaxation times of the carbonyl sites, θ is the excitation pulse angle, and TR is the repetition delay. Solving these coupled differential equations with initial conditions M_{z}^{lac}(t=0)=0 and M_{z}^{pyr}(t=0)=[Pyr]₀ yields the solutions:

$${M}_{z}^{pyr} ( t ) = {[ Pyr ]}_{0} \cdot {e}^{- ( {ρ}_{pyr} + k ) \cdot t}$$

$${M}_{z}^{lac} ( t ) = \frac{{[ Pyr ]}_{0} \cdot k}{Δ ρ} \cdot {e}^{- ρ pyr \cdot t} \cdot ( 1 - {e}^{- Δ ρ \cdot t} ) ,$$

where

$${ρ}_{pyr / lac} = \frac{1}{{T}_{1}^{pyr / lac}} + {( 1 - cos θ )}^{1 / TR}$$

is an effective longitudinal decay, and

$$Δ ρ = \frac{1}{{T}_{1}^{lac}} + \frac{1}{{T}_{1}^{pyr}} .$$

Taking into account the FID decay, the model for the signal is the following:

$${S}_{{t}_{m}} ( t ) = {e}^{i θ} ( \begin{matrix}\underbrace{{[ Pyr ]}_{0} {e}^{- ( {ρ}_{pyr} + k ) \cdot {t}_{m}}}_{{M}_{z}^{pyr} ( {t}_{m} )} \times {e}^{- \frac{t}{{T}_{2}^{pyr}}} \times {e}^{i Δ {ω}_{pyr} t} + \\ \underbrace{\frac{{[ Pyr ]}_{0} k}{Δ ρ} {e}^{- {ρ}_{pyr} {t}_{m}} \times ( 1 - {e}^{Δ ρ {t}_{m}} )}_{{M}_{z}^{lac} ( {t}_{m} )} \times {e}^{- \frac{t}{{T}_{2}^{pyr}}} \times {e}^{i Δ {ω}_{lac} t}\end{matrix} )$$

The most important parameter is k, which indicates the conversion rate between pyruvate and lactate. The parameter k may contain information about the metabolism.

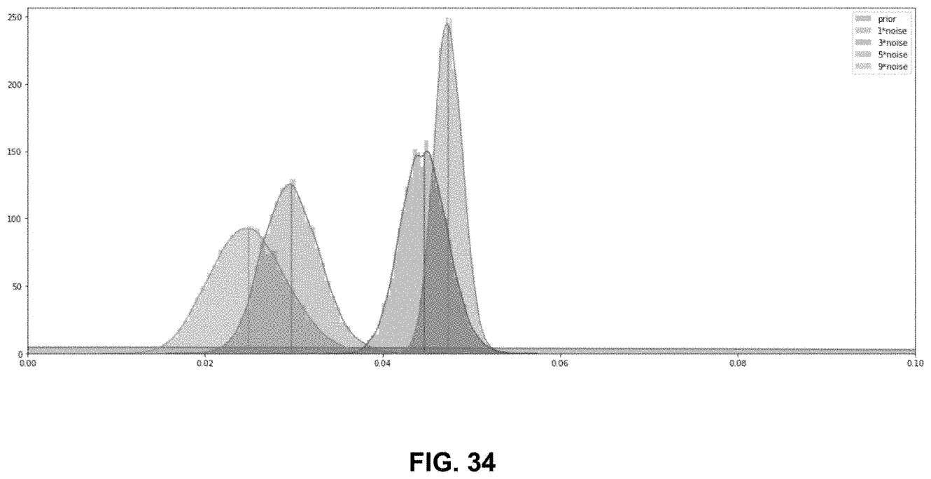

Referring to FIG. 34, the x axis indicates the value of k. The legend specifies the level of noise: 1× noise means the noise level in the real signal, 3×, 7×, 9× are with multiplications of the noise level, and correspond to signal to noise ratios (lactate peak compared to noise level) of: [1.36363636, 0.45454545, 0.27272727, 0.15151515]. As seen in FIG. 34, each of the models converge, and the width of the convergence provides the uncertainty in the fit. Therefore, by using the apriori knowledge of how underlying model for the hyperpolarized signal and all the measurements of the hyperpolarized molecules together, the signal can be detected with a higher degree of noise, even if the noise is large enough to mask the signal in the individual MR measurements.

As can be seen, in all cases the model converges. The width of the convergence provides the uncertainty in the fit (so there is not only one value, but a distribution). Accordingly, the cascade information may be used to amplify the metabolic response and to enhance a contrast in the MRI image of the actual metabolic response. However, as can be seen for high noise levels, the conversion rate k may be underestimated due to the noise level being significantly higher than the lactate signal.

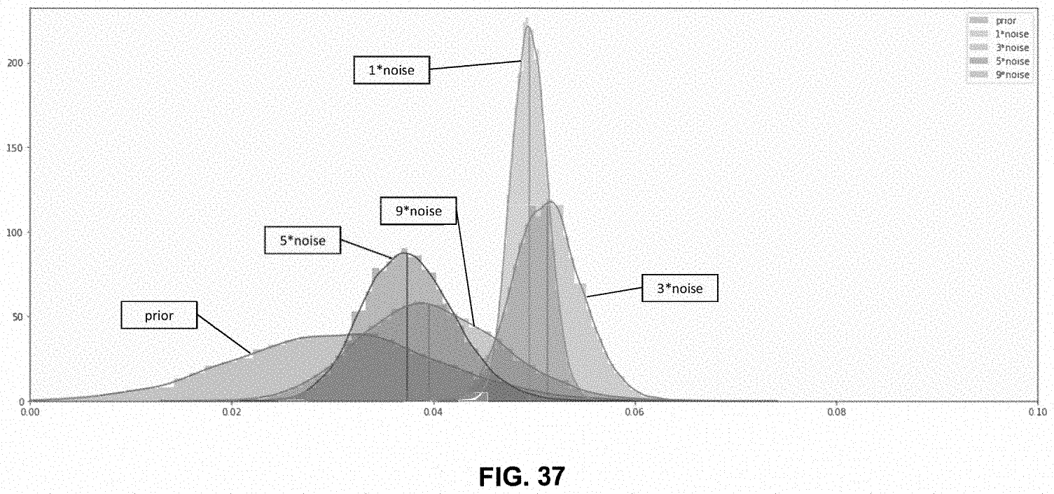

A key advantage of using a Bayesian inference model is the use of priors for the unknown parameters, such as the pyruvate to lactate conversion rate. The use of such priors provides an opportunity to leverage prior knowledge of the conversion rates and incorporate them into the model. In FIG. 37 a non-uniform distribution was used as the prior for the conversion rate. While the mean of the prior did not assume a large conversion rate, the information it added to the model enabled a much better estimation of the conversion rate even for very high noise levels.

In some embodiments, the priors may incorporate information from sources other than hyperpolarized MRI, such as information from different sequences in non-hyperpolarized proton MRI on the same patient, e.g. T₂ weighted anatomic image, T₁ weighted anatomic image, water apparent diffusion coefficient image and others. These can be acquired in the same MRI system as the hyperpolarized MRI acquisition, and, in many cases, proton MRI may be performed for the background anatomical image to be overlaid with the hyperpolarized MRI image. In some embodiments, information from other imaging modalities such as PET/CT or even other biomarkers can be incorporated.

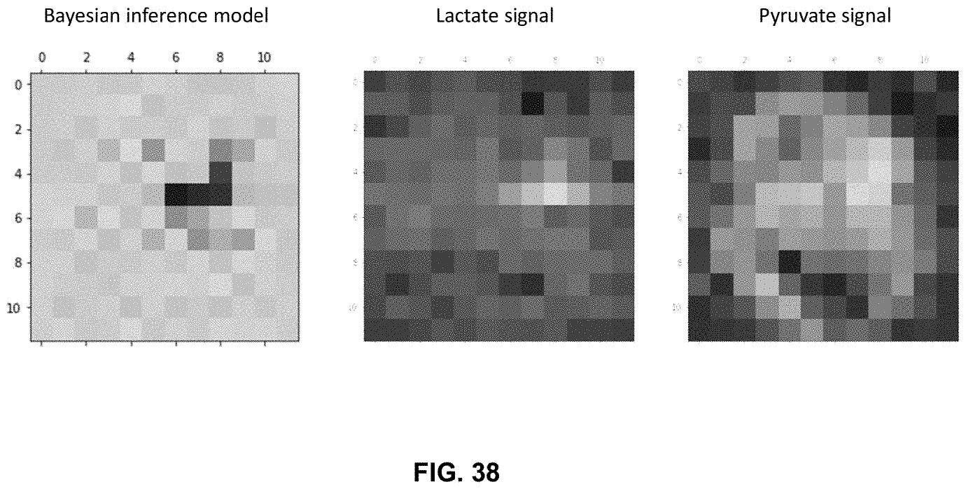

FIG. 38 shows the pyruvate and lactate signal, as well as the heatmap of the conversion rate from the Bayesian model for a 2D slice of an orthotropic tumor model in a mouse. However, a marked advantage of using Bayesian inference for the analysis of the individual voxels is that the output of the algorithm may be a distribution for the values of the conversion rate and not only the best value. In some embodiments, the probability distribution from the individual voxels may be used for a second layer of analysis, thereby incorporating the spatial information from adjacent voxels. In this way, one can leverage all the information of the two dimensions in each voxel (frequency and time), as well as the three spatial dimensions. For example, the distributions from adjacent voxels can be taken into account in identifying a cluster of voxels where a high conversion rate suggests this is a tumor region.

In some embodiments, all of the measurements of the hyperpolarized molecule together with the underlying model for the expected coherence and relaxation decay of the molecule to better extract the signal, even if no metabolic conversion has occurred. For example, after receiving a magnetic resonance signal containing noise making an actual response to an introduction of metabolic agent into a mammalian body, data stored in memory may be used to predict an actual decay in spin precession frequency over time. In addition, the predicted actual decay may be used to extract from the signal the actual response to the introduction of the metabolic agent. The data associated with normal time-based decay in nuclear spin precession frequency may include a decay curve as a function of time. In some embodiments, extracting the actual response from the signal may further include determining a signal amplitude indicative of the actual response. In some embodiments, the actual response may include a level of cell activity in response to an interaction with the metabolic agent, such as pyruvate.

In some embodiments, the polarization system may comprise an optical source configured to hyperpolarize more than 10¹² or more than 10¹³ near surface optically polarizable electron spins within a short period of time, such as 2 mₛ. This may be crucial if the polarization transfer occurs by direct transfer from the NV center to external spins, but this may also be important if the polarization occurs through polarization buildup in the diamond nuclear spins first before the transfer to external spins, as the diffusion to the surface may be much faster. As such, one or more diamond surfaces may be nanostructured with a high NV concentration or an ensemble of diamond nano- or micro-particles. For example, the polarization structure may comprise 10 stacked nano-pillared diamonds with x-y dimensions of 4 mm by 4 mm.

The nanostructures may be 2 micrometers deep with a 400 micrometer pitch (200 micrometer thick pillars), with all pillars having an NV density of 3×10¹⁷ cm⁻³ within 100 nanometers of the surface. This may result in between 10¹³-10¹⁴ near-surface NV centers.

In addition, in some embodiments, the diamond may need to be in contact with an external material of interest in order to allow the polarization transfer and build up of polarization in the material. In other embodiments, the hyperpolarization system may comprise a high-power light source or a plurality of light sources to polarize the electron spins in the catalyst, such as a diamond, within a predetermined period of time, such as about 2 mₛ. The optical light source can be a laser, LED source or other light sources with a suitable wavelength (e.g. green light for NV centers in diamond, infrared and red for silicon vacancy in silicon carbide). The optical source may be configured to emit more than about 0.5 Watt, more than about 1 Watt, or more than about 3 Watts of optical power. The optical light source may be arranged to irradiate the material in a hyperpolarization reaction chamber with sufficient energy to hyperpolarize the more than 10¹³ near surface optically polarizable electron spins within about 2 mₛ. In some embodiments, the optical light source may be configured to irradiate the catalyst material with non-collimated light. In other embodiments, the hyperpolarization system may comprise a magnet with a well-defined orientation. The magnet may comprise a permanent magnet, an electromagnet, or superconducting magnets. The electromagnet may be tuned to a magnetic field value to induce flip-flops between electron spins of the catalyst material and nuclei spins of the target material. For example, the electromagnet may be tuned to a value where an electron energy gap between spin states matches a nuclei gap of the target material. The magnetic field generated may be between about 1 mT and about 2 T. In other embodiments, the magnetic field may be greater than about 2 T. In some embodiments, the hyperpolarization system may comprise a microwave or an RF resonator configured to produce a homogeneous microwave or RF field for manipulating the optically polarizable electron spins, while enhancing the MW or RF power. Microwave resonators may comprise square and/or circular waveguide cavities, transmission line resonators, loop gap resonators, planar Omega resonators, simple loops, or coiled coils. Compared to x-band EPR resonators, the Q factor of the microwave or RF resonator can be much lower. The spin resonator may allow for homogeneous irradiation of the sample. In some embodiments, particularly when using microwave or magnetic field sweeps for the polarization transfer, the irradiation may not need to be homogeneous. In some embodiments, the MW resonator may be tuned to induce flip-flips between electron spins of the catalyst material and nuclei of the target material.

In accordance with an embodiment of the present disclosure, a hyperpolarizing system may be provided. The hyperpolarization system may comprise a hyperpolarization chamber for containing a catalyst material having more than 10¹³ near surface optically polarizable electron spins. The catalyst material may comprise, for example, a polarization structure, a semiconductor structure, a solid catalyst, a diamond, or any other material containing color centers with polarizable electron spins. The hyperpolarization system may further comprise at least one magnet configured to generate a magnetic field having a unidirectional orientation. The magnetic field may encompass an operable portion of the hyperpolarization chamber. The hyperpolarization system may also comprise at least one light source arranged to irradiate the material in the chamber with sufficient energy to hyperpolarize the more than 10¹³ near surface optically polarizable electron spins within 2 milliseconds (mₛ). The hyperpolarization system may also comprise at least one spin resonator configured to facilitate a transfer of polarization of electron spins from the catalyst material to a target material. The spin resonator may include a microwave generator configured to apply a pulse sequence. The microwave generator, for example, may be tuned to induce flip-flops between electron spins of the catalyst material and nuclei of the target material.

In some embodiments, the at least one magnet may include an electromagnet and the spin resonator may include the electromagnet tuned to a specific magnetic field value chosen to induce flip-flops between electron spins of the catalyst material and nuclei spins of the target material. The electromagnet may be tuned to a value where an electron energy gap between spin states matches a nuclei gap of the target material. In some embodiments, the at least one light source may be configured to irradiate the solid catalyst with non-collimated light.

In accordance with another embodiment of the present disclosure, a system for using decay patterns to extract masked MR spin signals may be provided. The system may comprise a memory for storing data associated with normal time-based decay in nuclear spin precession frequency. The system may also comprise at least one processor configured to receive a magnetic resonance signal containing noise masking an actual response to an introduction of a metabolic agent into a mammalian body, use the data stored in memory to predict an actual decay in spin precession frequency over time, and use the predicted actual decay to extract from the signal containing noise the actual response to the introduction of the metabolic agent.

In some embodiments, the data associated with normal time-based decay in nuclear spin precession frequency may include a decay curve as a function of time. In some embodiments, the metabolic agent may include pyruvate. In some embodiments, extracting the actual response from the signal may include determining a signal amplitude indicative of the actual response. The actual response may include a level of cell activity in response to an interaction with the metabolic agent.

In some embodiments, a method for activating thin NV-layers in a high-temperature high-pressure (HPHT) diamond as a diamond substrate for hyperpolarization or sensing may be provided. In the last decade, nitrogen-vacancy (NV) centers in diamond have been used to sense, control or hyperpolarize molecules outside of the diamond. For these applications, the NV centers have to be located near the diamond surface. Depending on the application, the distance of the NV centers to the surface may be on the micrometer to nanometer scale (e.g. smaller than about 100 micrometers). High NV concentrations deeper than the preferred surface distance may be detrimental because the NV centers may not interact with the outside molecules, thereby hindering the usability of the near-surface NV centers by absorbing some of the optical illumination and creating a background fluorescence signal if optical readout is used.

HPHT diamonds have a large concentration of nitrogen throughout the diamond (typically >10 ppm), and are therefore not used as substrates for surface-based NV applications. However, due to the growth mechanism, the number of vacancies in the diamond is exceedingly small, especially in comparison to chemical vapor deposition (CVD) diamond growth. Thus, the actual concentration of NV centers in the diamond may be in tens parts per billion or less, thereby providing an opportunity for using the HPHT sample for surface-based applications.

The Nitrogen near-surface—for example, Nitrogen 100 micrometer from the surface, or 1 micrometer from the surface, or 100 nm, or 10 nm from the surface—may be activated using electron irradiation or ion implantation. In some embodiments, the diamond may undergo electron irradiation in the range of about 100 keV to about 1 MeV in order for the electron spins not to penetrate and create vacancies through the entire diamond. As such, no non-carbon atoms may get stuck in the diamond lattice, thus creating uncontrolled defects. In another embodiment, the diamond may undergo ion implantation. The ions may be low weight ions such as helium or hydrogen, which may cause less damage to the diamond lattice and have more chance to be extracted during annealing of the diamond, or carbon irradiation, which does not add non-carbon atoms to the diamond lattice.

In another embodiment of the present disclosure, the growth of a nitrogen-rich diamond layer by chemical vapor deposition (CVD) for creating a dense NV layer and nanostructuring for forming a polarization catalyst may be combined. For example, a dense NV layer may be prepared by growing over 1 micrometer of nitrogen-rich diamond, and then the nitrogen-rich layer may be nanostructured. In another embodiment, the diamond may be nanostructured and then a nitrogen-rich layer may be grown on top of the nanostructured surface.

While the present disclosure is described herein with reference to illustrative embodiments, it should be understood that the embodiments described herein are not limited thereto. Those having ordinary skill in the art and access to the teachings provided herein will recognize additional modifications, applications, embodiments, and substitution of equivalents that all fall within the scope of the disclosed embodiments. Accordingly, the disclosed embodiments are not to be considered as limited by the foregoing or following descriptions.

The many features and advantages of the present disclosure are apparent from the detailed specification, and thus it is intended by the appended claims to cover all such features and advantages of the present disclosure that fall within the true spirit and scope of the present disclosure. Further, since numerous modifications and variations will readily occur to those skilled in the art, it is not desired to limit the present disclosure to the exact construction and operation illustrated and described and accordingly, all suitable modifications and equivalents may be resorted to, falling within the scope of the present disclosure.

Moreover, those skilled in the art will appreciate that the conception upon which this disclosure is based may readily be used as a basis for designing other structures, methods, and systems for carrying out the several purposes of the present disclosure. Accordingly, the claims are not to be considered as limited by the foregoing description.

What is claimed is:

1. A hyperpolarizing system, comprising:
a hyperpolarization reaction chamber having a location therein for supporting a solid catalyst with a sample in contact therewith;
a cooler configured to lower a temperature of the sample and the solid catalyst to a temperature in a range of about 70K and about 250K; and
an optical light source configured to direct light energy toward the solid catalyst to thereby hyperpolarize electrons in the solid catalyst and facilitate transfer of hyperpolarization to nuclei of the sample.

2. The hyperpolarizing system of claim 1, wherein the sample is frozen or in a glassy state in the temperature configured by the cooler.

3. The hyperpolarizing system of claim 1, wherein the sample is a flowable sample.

4. The hyperpolarizing system of claim 1, wherein the sample includes particles.

5. The hyperpolarizing system of claim 1, wherein the cooler is configured to lower the temperature of the sample and the solid catalyst to at least one of a temperature in a range of about 70K and about 220K, a temperature in a range of about 70K and about 200K, or a temperature in a range of about 70K and about 120K.

6. The hyperpolarizing system of claim 1, wherein the optical light source is configured to emit at least one of non-collimated light or green light.

7. The hyperpolarizing system of claim 1, wherein the optical light source includes at least one of a laser configured to direct light at about 538 nm or a light emitting diode (LED).

8. The hyperpolarizing system of claim 3, further comprising at least one processor configured to control at least one of the optical light source, the cooler, or a flow of the sample in order to facilitate the transfer of hyperpolarization to the nuclei of the flowable sample.

9. The hyperpolarizing system of claim 1, further comprising at least one microwave source.

10. The hyperpolarizing system of claim 1, wherein the solid catalyst includes a plurality of nanostructured diamond substrates with nanoscopic three-dimensional structures across a surface thereof, each substrate hosting defects with optically polarizable electron spins.

11. The hyperpolarizing system of claim 10, wherein the plurality of nanostructured diamond substrates are arranged in a stack, and wherein the stack has a plurality of channels therethrough, the channels being configured to permit a polarizable fluidic agent to flow through the nanoscopic three-dimensional structures of the plurality of nanostructured diamond substrates in the stack.

12. The hyperpolarizing system of claim 10, wherein each substrate is associated with its own holder.

13. The hyperpolarizing system of claim 10, wherein the nanoscopic three-dimensional structures each have a size range of about 50 nm to about 5000 nm.

14. The hyperpolarizing system of claim 11, wherein the channels include pathways through at least one membrane surface.

15. The hyperpolarizing system of claim 11, wherein the channels include pathways between adjacent membranes.

16. The hyperpolarizing system of claim 11, wherein the channels include pathways through at least one membrane surface and between adjacent membranes.

17. The hyperpolarizing system of claim 10, wherein the plurality of nanostructured diamond substrates includes at least 10 stacked nanostructured diamond substrates, at least 50 stacked nanostructured diamond substrates, or at least 100 stacked nanostructured diamond substrates.

18. The hyperpolarizing system of claim 10, wherein the plurality of nanostructured diamond substrates are coated with endogenous molecules having polarizable nuclear spin.

19. The hyperpolarizing system of claim 10, wherein each substrate has a thickness between about 1 μm and about 100 μm.

20. The hyperpolarizing system of claim 10, wherein each substrate includes at least one honeycomb-shaped cut.

21. A hyperpolarizing catalyst, comprising:
a plurality of nanostructured diamond substrates with nanoscopic three-dimensional structures across a surface thereof, each substrate hosting defects with optically polarizable electron spins, wherein
the plurality of nanostructured diamond substrates are arranged in a stack, and wherein the stack has a plurality of channels therethrough, the channels being configured to permit a polarizable fluidic agent to flow through the nanoscopic three-dimensional structures of the plurality of nanostructured diamond substrates in the stack.
